(19) United States
(12) Patent Application Publication
(10) Pub. No.: US 2017/0107606 A1
(43) Pub. Date: Apr. 20, 2017

(54) Film Formation Apparatus, Method for Forming Film, Method for Forming Multilayer Film or Light-Emitting Element, and Method for Cleaning Shadow Mask

(71) Applicant: Semiconductor Energy Laboratory Co., Ltd., Kanagawa-ken (JP)

(72) Inventors: Yasuhiro Jinbo, Atsugi (JP); Shingo Eguchi, Atsugi (JP); Shunpei Yamazaki, Tokyo (JP)

(73) Assignee: Semiconductor Energy Laboratory Co., Ltd., Kanagawa-ken (JP)

(21) Appl. No.: 15/395,345

(22) Filed: Dec. 30, 2016

Related U.S. Application Data
(62) Division of application No. 13/888,858, filed on May 7, 2013.

(30) Foreign Application Priority Data
May 10, 2012 (JP) 2012-108221
May 31, 2012 (JP) 2012-124594

(51) Int. Cl. C23C 14/24; H01J 37/32; C23C 14/12; C23C 14/58; H01L 51/56; C23C 14/04

(52) U.S. Cl. CPC C23C 14/24; H01L 51/56; C23C 14/042; C23C 14/12; C23C 14/5873; H01J 37/32568; H01J 37/32834; H01J 2237/332; H01J 2237/335

(57) ABSTRACT

The inventors have reached the idea of a film formation apparatus including a film formation chamber, a removal chamber, two sluice valves provided apart from each other between the film formation chamber and the removal chamber, and a shadow mask transfer mechanism. The film formation chamber includes an evaporation source, and the removal chamber includes a parallel plate plasma source and a shadow mask stage. The film formation apparatus has a film formation mode in which a shadow mask overlapped with an object is transferred by the shadow mask transfer mechanism and a film is formed on the object; and a cleaning mode in which the shadow mask is irradiated with plasma by the plasma source, the shadow mask being held between an upper electrode and a lower electrode by the shadow mask stage.

This application is a divisional of copending U.S. application Ser. No. 13/888,858, filed on May 7, 2013 which is incorporated herein by reference.

### BACKGROUND OF THE INVENTION

1. Field of the Invention

The present invention relates to a film formation apparatus, a method for forming a film and a method for forming a multilayer film or a light-emitting element which use the film formation apparatus, and a method for cleaning a shadow mask used in the film formation apparatus.

2. Description of the Related Art

An apparatus which ejects a film formation material towards a surface of an object to deposit the film formation material has been known. For example, a film formation apparatus (also referred to as an evaporation apparatus) which includes a film formation chamber provided with an evaporation source filled with a film formation material and which ejects the vaporized film formation material from the evaporation source to form a film on a surface of an object in the film formation chamber has been known.

A film formation apparatus which can efficiently utilize a film formation material is preferred. For example, a film formation apparatus in which an evaporation source having directivity in a direction in which a film formation material is ejected is kept close to an object and in which a film is formed while the object is scanned with the evaporation source has been known. With this film formation apparatus, the film formation material can be prevented from partly being unintentionally attached to a place other than the surface of the object (e.g., an inner wall of the film formation chamber or a partition plate provided near the evaporation source) and being wasted.

A film which includes a film formation material attached to a place other than the surface of the object becomes thicker every time film formation is performed, and part of the film might be separated for some reason (e.g., stress generated in the film) and be diffused in the film formation chamber as a membranous or powdery substance (also referred to as dust). Such a membranous or powdery substance is attached to the object and degrades the quality of a film formed on the object and causes generation of a defect.

In order to suppress generation of such a membranous or powdery substance, Patent Document 1 discloses an invention related to a means which removes a film formation material attached to an inner wall or the like by generating plasma in a film formation chamber or to a method for cleaning a mask.

Further, as a method for forming an island-like film on a surface of an object, a shadow mask method has been known. The shadow mask method is a method for forming a film by using a shadow mask provided with openings and placed near a surface of an object on the evaporation source side. This method enables an island-like film with a shape corresponding to the shapes of the openings to be formed on the surface of the object.

In order to clean the film formation material attached to the mask, Patent Document 2 discloses an invention related to a method in which plasma is generated in a film formation chamber with a plasma generator and thus a film formation material attached to a mask is vaporized and exhausted to the outside of the film formation chamber.

Patent Document 3 discloses a structure including vacuum dual chambers as an example of a continuous coating apparatus using a shadow mask. One of the vacuum dual chambers included in the continuous coating apparatus is a chamber in which a carrier with a substrate is transported, and the other is a chamber in which a carrier and a shadow mask are return transported and which is used for cleaning.

### REFERENCES

### Patent Documents

### [Patent Document 1] Japanese Published Patent Application No. 2003-313654

### [Patent Document 2] Japanese Published Patent Application No. 2004-047452

### [Patent Document 3] Japanese Published Patent Application No. 2006-302898

### SUMMARY OF THE INVENTION

To increase the number of films stacked with use of a continuous film formation apparatus in which an evaporation source which ejects a material for forming a film is provided for each film formation chamber or film formation region, the number of the film formation chambers or film formation regions needs to be increased. Therefore, an increase in the number of films which can be stacked with the film formation apparatus results in an increase in the size and area of the film formation apparatus.

Large-scale expensive apparatuses are required to have high rates of operation. In some cases, a small number of films are stacked with use of a film formation apparatus provided with a large number of film formation chambers or film formation regions. Even when the rate of operation of the film formation apparatus is increased using only part of the film formation chambers in such a manner, the rate of operation per film formation chamber or film formation region is low, which is not cost efficient.

Moreover, in the case where the film formation material attached to a shadow mask is removed by being vaporized by irradiation with plasma, low removal speed leads to low work efficiency and low cost efficiency. For example, when the speed of removal of the film formation material is lower than that of film formation in the film formation apparatus, accumulation of used shadow masks outpaces reproduction of the used shadow masks. Consequently, a complicated operation is needed for management of used shadow masks. Further, many spare shadow masks need to be prepared in a manufacturing process, for example.

One embodiment of the present invention is made in view of the foregoing technical background. An object is to provide a film formation apparatus in which the number of continuously stacked films can be flexibly changed while a decrease in the rate of operation of a film formation chamber or a film formation region provided in the film formation apparatus is suppressed. Another object is to provide a method for forming a multilayer film in which the number of continuously stacked films can be flexibly changed. Another object is to provide a method for manufacturing a light-emitting element.

Another object is to provide a film formation apparatus that can form a film using a shadow mask and remove a film formation material attached to the shadow mask. Another object is to provide a method for forming a film using a shadow mask and a method for removing a film formation material attached to the shadow mask.

In order to achieve at least one of the above-described objects, one embodiment of the present invention is made with a focus on a plurality of film formation chambers which is provided in a film formation apparatus capable of continuously forming a large number of films. Consequently, the inventors have reached the idea of a film formation apparatus having a structure exemplified in this specification.

A film formation apparatus of one embodiment of the present invention includes a plurality of processing units each including a connection chamber, a carrying-in chamber which supplies an object to the connection chamber, a film formation chamber with one opening connected to the connection chamber, a delivery chamber to which the other opening of the film formation chamber is connected, a carrying-out chamber which withdraws the object from the delivery chamber, and a removal chamber with one opening connected to the delivery chamber. The connection chamber of one processing unit is connected to the other opening of the removal chamber of another processing unit.

In addition, one embodiment of the present invention is made with a focus on the position of a shadow mask with respect to a plasma source at the time of removing a film formation material from the shadow mask with use of plasma.

A film formation apparatus of one embodiment of the present invention includes a film formation chamber, a removal chamber, two sluice valves which are apart from each other and provided between the film formation chamber and the removal chamber, and a shadow mask transfer mechanism. The film formation chamber includes an evaporation source. The removal chamber includes a parallel plate plasma source and a shadow mask stage which is between an upper electrode and a lower electrode of the plasma source. The film formation apparatus has a film formation mode in which a shadow mask overlapped with an object is transferred by the shadow mask transfer mechanism and a film is formed on the object; and a cleaning mode in which the shadow mask is irradiated with plasma by the plasma source, the shadow mask being held between the upper electrode and the lower electrode by the shadow mask stage.

That is, one embodiment of the present invention is a film formation apparatus including a removal chamber; a first sluice valve and a second sluice valve connected to the removal chamber and provided apart from each other; a film formation chamber connected to the first sluice valve and the second sluice valve; an evaporation source in the film formation chamber; a parallel plate plasma source in the removal chamber; a shadow mask stage between an upper electrode and a lower electrode of the plasma source; and a shadow mask transfer mechanism which transfers an object and a shadow mask covering part of the object through a region where the evaporation source ejects a film formation material, the object and the shadow mask being overlapped with each other. The film formation apparatus further includes a film formation mode in which the shadow mask overlapped with the object is transferred by the shadow mask transfer mechanism and the film formation material ejected by the evaporation source is deposited on the object; and a cleaning mode in which the shadow mask is irradiated with plasma by the plasma source, the shadow mask being held on the upper electrode side by the shadow mask stage.

With this film formation apparatus, a film can be formed on the object with use of the shadow mask in the film formation mode, the used shadow mask can be carried out from the film formation chamber to the removal chamber through the first sluice valve, and the film formation material attached to the shadow mask can be removed in the cleaning mode. Further, the shadow mask from which the film formation material is removed (also referred to as a reproduced shadow mask) can be carried into the film formation chamber from the removal chamber through the second sluice valve to be reused. Consequently, film formation and cleaning can be repeated without the shadow mask being taken out of the film formation apparatus, which prevents attachment of dust or the like to the shadow mask outside the film formation apparatus. It is also possible to prevent generation of a membranous or powdery substance from the film formation material attached to the shadow mask. Thus, a film formation apparatus capable of forming a film with a shadow mask and removing a film formation material attached to the shadow mask can be provided.

One embodiment of the present invention is a film formation apparatus including a removal chamber; a first sluice valve and a second sluice valve connected to the removal chamber and provided apart from each other; a film formation chamber connected to the first sluice valve and the second sluice valve; an evaporation source in the film formation chamber; a plasma source in the removal chamber; a shadow mask stage which holds a shadow mask to enable the shadow mask to be irradiated with plasma emitted from the plasma source; and a shadow mask transfer mechanism which transfers an object and a shadow mask covering part of the object through a region where the evaporation source ejects a film formation material, the object and the shadow mask being overlapped with each other. The film formation apparatus further includes a film formation mode in which the shadow mask overlapped with the object is transferred by the shadow mask transfer mechanism and the film formation material ejected by the evaporation source is deposited on the object; and a cleaning mode in which the shadow mask is irradiated with plasma by the plasma source, the shadow mask being held on the upper electrode side by the shadow mask stage. A distance in which the shadow mask is transferred through the removal chamber is shorter than a distance in which the shadow mask is transferred through the film formation chamber.

In the film formation apparatus of one embodiment of the present invention, the distance in which the shadow mask is transferred through the removal chamber is shorter than the distance in which the shadow mask is transferred through the film formation chamber. For example, the film formation chamber has a square-bracket-like shape, a U shape, a V shape, an S shape, or the like and the shadow mask is transferred through a bent path. The removal chamber is provided with two sluice valves which are apart from each other and connected to the film formation chamber, and has a shorter shadow-mask transfer path than the film formation chamber. This structure enables a reduction in the area occupied by the film formation apparatus (also referred to as footprint).

In one embodiment of the present invention, the shadow mask stage includes an insulating support member on the upper electrode side. In the cleaning mode of the film formation apparatus, the shadow mask is irradiated with plasma by the plasma source, being held by the insulating support member to be in contact with the upper electrode.

The film formation apparatus of one embodiment of the present invention has a cleaning mode in which the shadow mask is irradiated with plasma by the plasma source, the shadow mask being held by the insulating support member to be in contact with the upper electrode of the parallel plate plasma source. In this structure, the shadow mask is placed in a region where ions are greatly accelerated by self-bias voltage, which enables the film formation material attached to the shadow mask to be removed at higher speed.

In one embodiment of the present invention, during irradiation with plasma, the upper electrode and the shadow mask stage in the film formation apparatus are electrically insulated from each other, and a distance D2 between a portion with a potential equal to that of the upper electrode and a grounded portion of the shadow mask stage is shorter than a distance D1 between the upper electrode and the lower electrode, being less than or equal to half the distance D1.

The film formation apparatus of one embodiment of the present invention has a cleaning mode in which the shadow mask is irradiated with plasma by the plasma source, the shadow mask being held by the insulating support member to be in contact with the upper electrode of the parallel plate plasma source. The upper electrode and the shadow mask stage are electrically insulated from each other, and the distance D2 between the portion with a potential equal to that of the upper electrode and the grounded portion of the shadow mask stage is shorter than the distance D1 between the upper electrode and the lower electrode. This structure prevents abnormal discharge between the shadow mask stage and the portion with a potential equal to that of the upper electrode to enable stable generation of plasma.

In one embodiment of the present invention, the upper electrode in the film formation apparatus is provided with a temperature adjustment mechanism.

In the film formation apparatus of one embodiment of the present invention, the upper electrode which is in contact with the shadow mask held by the shadow mask stage is provided with a temperature adjustment mechanism. Heat is conducted between the shadow mask and the upper electrode through a contact portion thereof; thus, the temperature of the shadow mask irradiated with plasma can be adjusted with the temperature adjustment mechanism. This can prevent damage to the shadow mask, such as a change in its dimensions due to a temperature rise.

In one embodiment of the present invention, the film formation apparatus includes a plurality of removal chambers, each removal chamber being provided with the shadow mask stage and the plasma source.

The film formation apparatus of one embodiment of the present invention includes a plurality of removal chambers which can execute the cleaning mode independently of each other. In this structure, a plurality of shadow masks can be concurrently irradiated with plasma in the plurality of removal chambers. Consequently, the film formation material can be concurrently removed from the plurality of shadow masks. Furthermore, this structure enables the shadow masks to be irradiated with plasma for a longer time without interruption of continuous film formation on objects.

One embodiment of the present invention is a method for forming a film with use of the above film formation apparatus, including the following four steps. The first step is to overlap an object with an opening of a shadow mask. The second step is to transfer, with use of the shadow mask transfer mechanism, the shadow mask whose opening is overlapped with the object and to deposit a film formation material ejected by the evaporation source on the object. The third step is to carry out the shadow mask to the removal chamber through the first sluice valve and to irradiate the shadow mask with plasma from the plasma source, the shadow mask being held on the upper electrode side by the shadow mask stage. The fourth step is to carry in the shadow mask to the film formation chamber through the second sluice valve.

The method for forming a film of one embodiment of the present invention includes a step of forming a film on an object with use of a shadow mask and a step of reproducing the shadow mask by removing a film formation material attached thereto. In this method, the film formation material attached to the shadow mask in the second step can be removed in the third step. The shadow mask reproduced in the third step is used again in the first step; thus, the shadow mask can be repeatedly used. Consequently, a method for forming a film using a shadow mask and a method for removing a film formation material attached to the shadow mask can be provided.

One embodiment of the present invention is a film formation apparatus including a plurality of processing units each including a connection chamber, a carrying-in chamber which supplies an object to the connection chamber, a film formation chamber with one opening connected to the connection chamber, a delivery chamber to which the other opening of the film formation chamber is connected, a carrying-out chamber which withdraws the object from the delivery chamber, a removal chamber with one opening connected to the delivery chamber, and a shadow mask transfer mechanism.

The connection chamber of one processing unit is connected to the other opening of the removal chamber of another processing unit in an annular manner. The connection chamber has a first mode in which an object supplied from the carrying-in chamber is supplied to the film formation chamber, the object being overlapped with a shadow mask supplied through the other opening of the removal chamber of another processing unit, and a second mode in which a shadow mask overlapped with an object and supplied through the other opening of the removal chamber of another processing unit is supplied to the film formation chamber.

The film formation chamber includes an evaporation source. The shadow mask transfer mechanism transfers a shadow mask overlapped with an object through a region where the evaporation source ejects a film formation material.

The delivery chamber has a first mode in which an object and a shadow mask are supplied to the carrying-out chamber and the removal chamber, respectively, and a second mode in which a shadow mask overlapped with an object is supplied to the removal chamber.

The removal chamber has a cleaning mechanism, a first mode in which a shadow mask is cleaned by the cleaning mechanism and the shadow mask is supplied to the connection chamber of one processing unit, and a second mode in which a shadow mask overlapped with an object is supplied to the connection chamber of the one processing unit.

The film formation apparatus of one embodiment of the present invention includes a plurality of processing units each including a connection chamber, a carrying-in chamber which supplies an object to the connection chamber, a film formation chamber with one opening connected to the connection chamber, a delivery chamber to which the other opening of the film formation chamber is connected, a carrying-out chamber which withdraws the object from the delivery chamber, and a removal chamber with one opening connected to the delivery chamber. The connection chamber of one processing unit is connected to the other opening of the removal chamber of another processing unit in an annular manner.

The connection chamber of one processing unit and the delivery chamber of another processing unit whose removal chamber is connected to the connection chamber can be operated in the first mode, and all the other connection chambers and delivery chambers can be operated in the second mode. In this manner, film formation materials can be stacked, with use of all the film formation chambers in the film formation apparatus, on one object which is supplied to the connection chamber in the first mode, and the object can be withdrawn by the carrying-out chamber connected to the delivery chamber in the first mode of another processing unit.

In addition, the removal chamber of another processing unit connected to the connection chamber can be operated in the first mode. Thus, the film formation materials attached to the shadow mask can be removed.

Alternatively, the connection chambers, the delivery chambers, and the removal chambers of all the processing units can be operated in the first mode. In this manner, film formation materials can be concurrently deposited on a plurality of objects in the plurality of film formation chambers in the film formation apparatus. Further, the film formation materials attached to a plurality of shadow masks can be concurrently removed in the plurality of removal chambers. Consequently, it is possible to provide a film formation apparatus in which the number of films which can be continuously formed can be flexibly changed while a decrease in the rate of operation of film formation chambers which are provided for continuous stacking of a large number of films is suppressed.

One embodiment of the present invention is a film formation apparatus including a first processing unit and a second processing unit.

The first processing unit includes a first connection chamber, a first carrying-in chamber which supplies an object to the first connection chamber, a first film formation chamber with one opening connected to the first connection chamber, a first delivery chamber to which the other opening of the first film formation chamber is connected, a first carrying-out chamber which withdraws the object from the first delivery chamber, a first removal chamber with one opening connected to the first delivery chamber, and a first shadow mask transfer mechanism.

The second processing unit includes a second connection chamber, a second carrying-in chamber which supplies an object to the second connection chamber, a second film formation chamber with one opening connected to the second connection chamber, a second delivery chamber to which the other opening of the second film formation chamber is connected, a second carrying-out chamber which withdraws the object from the second delivery chamber, a second removal chamber with one opening connected to the second delivery chamber, and a second shadow mask transfer mechanism.

The first connection chamber of the first processing unit is connected to the other opening of the second removal chamber of the second processing unit, and the second connection chamber of the second processing unit is connected to the other opening of the first removal chamber of the first processing unit.

The first connection chamber has a first mode in which an object supplied from the first carrying-in chamber is supplied to the first film formation chamber, the object being overlapped with a shadow mask supplied through the other opening of the second removal chamber, and a second mode in which a shadow mask overlapped with an object and supplied through the other opening of the second removal chamber is supplied to the first film formation chamber.

The second connection chamber has a first mode in which an object supplied from the second carrying-in chamber is supplied to the second film formation chamber, the object being overlapped with a shadow mask supplied through the other opening of the first removal chamber, and a second mode in which a shadow mask overlapped with an object and supplied through the other opening of the first removal chamber is supplied to the second film formation chamber.

The first film formation chamber includes a first evaporation source, and the second film formation chamber includes a second evaporation source. The first shadow mask transfer mechanism transfers a shadow mask overlapped with an object through a region where the first evaporation source ejects a film formation material, and the second shadow mask transfer mechanism transfers a shadow mask overlapped with an object through a region where the second evaporation source ejects a film formation material.

The first delivery chamber has a first mode in which an object and a shadow mask are supplied to the first carrying-out chamber and the first removal chamber, respectively, and a second mode in which a shadow mask overlapped with an object is supplied to the first removal chamber.

The second delivery chamber has a first mode in which an object and a shadow mask are supplied to the second carrying-out chamber and the second removal chamber, respectively, and a second mode in which a shadow mask overlapped with an object is supplied to the second removal chamber.

The first removal chamber has a first cleaning mechanism, a first mode in which a shadow mask is cleaned and supplied to the second connection chamber of the second processing unit, and a second mode in which a shadow mask overlapped with an object is supplied to the second connection chamber of the second processing unit.

The second removal chamber has a second cleaning mechanism, a first mode in which a shadow mask is cleaned and supplied to the first connection chamber of the first processing unit, and a second mode in which a shadow mask overlapped with an object is supplied to the first connection chamber of the first processing unit.

In the film formation apparatus of one embodiment of the present invention, the first connection chamber of the first processing unit is connected to the other opening of the second removal chamber of the second processing unit, and the second connection chamber of the second processing unit is connected to the other opening of the first removal chamber of the first processing unit.

The first connection chamber of the first processing unit and the second delivery chamber of the second processing unit can be operated in the first mode, and the first delivery chamber of the first processing unit and the second connection chamber of the second processing unit can be operated in the second mode. In this manner, with use of the first film formation chamber and the second film formation chamber in the film formation apparatus, the film formation material of the first evaporation source can be deposited on one object carried into the first connection chamber in the first mode, and the film formation material of the second evaporation source can be deposited to overlap with the film formation material of the first evaporation source. Then, the second carrying-out chamber connected to the second delivery chamber in the first mode of the second processing unit can withdraw the object. Further, the film formation materials attached to the shadow mask can be removed in the second removal chamber in the first mode connected to the second delivery chamber in the first mode.

Alternatively, the first connection chamber and the first delivery chamber in the first processing unit and the second connection chamber and the second delivery chamber in the second processing unit can all be operated in the first mode. In this manner, film formation materials can be concurrently deposited on two objects with use of the first film formation chamber and the second film formation chamber. Consequently, it is possible to provide a film formation apparatus in which the number of films which can be continuously formed can be flexibly changed while a decrease in the rate of operation of film formation chambers which are provided for continuous stacking of a large number of films is suppressed.

One embodiment of the present invention is a method for forming a multilayer film with use of the above film formation apparatus, including the following seven steps.

The first processing unit of the film formation apparatus includes the first film formation chamber in which an evaporation source containing a material for forming a first layer, an evaporation source containing a material for forming a second layer, an evaporation source containing a material for forming a third layer, and an evaporation source containing a material for forming a fourth layer are placed in that order from the one opening side to the other opening side.

The second processing unit of the film formation apparatus includes the second film formation chamber in which an evaporation source containing a material for forming a fifth layer, an evaporation source containing a material for forming a sixth layer, and an evaporation source containing a material for forming a seventh layer are placed in that order from the one opening side to the other opening side.

With use of this film formation apparatus, in the first step, an object supplied from the first carrying-in chamber is supplied to the first film formation chamber, being overlapped with a shadow mask supplied through the other opening of the second removal chamber.

In the second step, with use of the first film formation chamber, the first layer, the second layer, the third layer, and the fourth layer are formed in that order on the object exposed in an opening of the shadow mask, and the object is supplied to the first delivery chamber.

In the third step, the first delivery chamber in the second mode supplies the shadow mask overlapped with the object to the first removal chamber, and the first removal chamber in the second mode supplies the shadow mask overlapped with the object to the second connection chamber of the second processing unit.

In the fourth step, the second connection chamber in the second mode supplies the shadow mask overlapped with the object to the second film formation chamber.

In the fifth step, with use of the second film formation chamber, the fifth layer, the sixth layer, and the seventh layer are formed in that order to overlap with the fourth layer formed on the object exposed in an opening of the shadow mask, and the object is supplied to the second delivery chamber.

In the sixth step, the second delivery chamber in the first mode supplies the object and the shadow mask to the second carrying-out chamber and the second removal chamber, respectively.

In the seventh step, the second removal chamber in the first mode cleans the shadow mask and supplies the shadow mask to the first connection chamber of the first processing unit.

With the method for forming a multilayer film of one embodiment of the present invention, four layers can be stacked on one object supplied to the first connection chamber in the first mode with use of the first film formation chamber in the film formation apparatus, three layers can be stacked with use of the second film formation chamber, and the object can be supplied to the second carrying-out chamber connected to the second delivery chamber in the first mode. Further, film formation materials attached to the shadow mask can be removed in the second removal chamber in the first mode. Consequently, a large number of films can be continuously stacked.

One embodiment of the present invention is a method for forming a multilayer film with use of the above film formation apparatus, including the following four steps.

The first processing unit of the film formation apparatus includes the first film formation chamber in which an evaporation source containing a material for forming a first layer, an evaporation source containing a material for forming a second layer, and an evaporation source containing a material for forming a third layer are placed in that order from the one opening side to the other opening side.

The second processing unit of the film formation apparatus includes the second film formation chamber in which an evaporation source containing a material for forming a first layer, an evaporation source containing a material for forming a second layer, and an evaporation source containing a material for forming a third layer are placed in that order from the one opening side to the other opening side.

With use of this film formation apparatus, in the first step, a first object supplied from the first carrying-in chamber is supplied to the first film formation chamber, being overlapped with a first shadow mask supplied through the other opening of the second removal chamber. Further, a second object supplied from the second carrying-in chamber is supplied to the second film formation chamber, being overlapped with a second shadow mask supplied through the other opening of the first removal chamber.

In the second step, with use of the first film formation chamber, the first layer, the second layer, and the third layer are formed in that order on the first object exposed in an opening of the first shadow mask, and the first object is supplied to the first delivery chamber. Further, with use of the second film formation chamber, the first layer, the second layer, and the third layer are formed in that order on the second object exposed in an opening of the second shadow mask, and the second object is supplied to the second delivery chamber.

In the third step, the first delivery chamber in the first mode supplies the first object and the first shadow mask to the first carrying-out chamber and the first removal chamber, respectively. Further, the second delivery chamber in the first mode supplies the second object and the second shadow mask to the second carrying-out chamber and the second removal chamber, respectively.

In the fourth step, the first removal chamber in the first mode cleans the first shadow mask and supplies the first shadow mask to the second connection chamber of the second processing unit. Further, the second removal chamber in the first mode cleans the second shadow mask and supplies the second shadow mask to the first connection chamber of the first processing unit.

With the method for forming multilayer films of one embodiment of the present invention, film formation materials can be concurrently deposited on two objects with use of the first film formation chamber and the second film formation chamber in the film formation apparatus. Consequently, it is possible to provide a film formation apparatus in which the number of films which can be continuously formed can be flexibly changed while a decrease in the rate of operation of film formation chambers which are provided for continuous stacking of a large number of films is suppressed.

One embodiment of the present invention is a method for manufacturing a light-emitting element with use of the above film formation apparatus, including the following ten steps.

The first processing unit of the film formation apparatus includes the first film formation chamber in which an evaporation source containing a material for forming a first layer, an evaporation source containing a material for forming a second layer, an evaporation source containing a material for forming a third layer, and an evaporation source containing a material for forming a fourth layer are placed in that order from the one opening side to the other opening side.

The second processing unit of the film formation apparatus includes a second conductive film formation chamber connected to the second carrying-out chamber, a second sealing chamber connected to the second conductive film formation chamber, a second extraction chamber connected to the second sealing chamber, and the second film formation chamber in which an evaporation source containing a material for forming a fifth layer, an evaporation source containing a material for forming a sixth layer, and an evaporation source containing a material for forming a seventh layer are placed in that order from the one opening side to the other opening side.

The first layer and the fifth layer have one of a hole-transport property and an electron-transport property, the third layer and the seventh layer have the other of a hole-transport property and an electron-transport property, the second layer and the sixth layer contain a light-emitting organic compound, and the fourth layer is an intermediate layer.

With use of this film formation apparatus, in the first step, an object provided with a first electrode and supplied from the first carrying-in chamber is supplied to the first film formation chamber, being overlapped with a shadow mask supplied through the other opening of the second removal chamber.

In the second step, with use of the first film formation chamber, the first layer, the second layer, the third layer, and the fourth layer are formed in that order on the first electrode of the object exposed in an opening of the shadow mask, and the object is supplied to the first delivery chamber.

In the third step, the first delivery chamber in the second mode supplies the shadow mask overlapped with the object to the first removal chamber, and the first removal chamber in the second mode supplies the shadow mask overlapped with the object to the second connection chamber of the second processing unit.

In the fourth step, the second connection chamber in the second mode supplies the shadow mask overlapped with the object to the second film formation chamber.

In the fifth step, with use of the second film formation chamber, the fifth layer, the sixth layer, and the seventh layer are formed in that order to overlap with the fourth layer formed on the object exposed in an opening of the shadow mask, and the object is supplied to the second delivery chamber.

In the sixth step, the second delivery chamber in the first mode supplies the object and the shadow mask to the second carrying-out chamber and the second removal chamber, respectively.

In the seventh step, the second removal chamber in the first mode cleans the shadow mask and supplies the shadow mask to the first connection chamber of the first processing unit.

In the eighth step, the second carrying-out chamber supplies the object to the second conductive film formation chamber.

In the ninth step, with use of the second conductive film formation chamber, a second electrode is formed to overlap with the seventh layer, and the object is supplied to the second sealing chamber from the second conductive film formation chamber.

In the tenth step, with the second sealing chamber, the multilayer film in which the first layer, the second layer, the third layer, the fourth layer, the fifth layer, the sixth layer, the seventh layer, and the second electrode are stacked in that order is sealed between the object and a sealant.

With the method for manufacturing a light-emitting element of one embodiment of the present invention, four layers can be formed to overlap with the first electrode provided on the object with use of the first film formation chamber. For example, a first hole-transport layer as the first layer, a first light-emitting layer as the second layer, a first electron-transport layer as the third layer, and an intermediate layer as the fourth layer can be formed. Further, three layers can be formed to overlap with the fourth layer with use of the second film formation chamber. For example, a second hole-transport layer as the fifth layer, a second light-emitting layer as the sixth layer, and a second electron-transport layer as the seventh layer can be formed. Then, the second delivery chamber in the first mode can supply the object to the second carrying-out chamber.

Further, the second electrode can be formed to overlap with the seventh layer with use of the second conductive film formation chamber connected to the second carrying-out chamber, whereby the light-emitting element is manufactured, and the light-emitting element can be sealed between the object and the sealant with use of the second sealing chamber connected to the second conductive film formation chamber.

Further, film formation materials attached to the shadow mask can be removed in the second removal chamber in the first mode. Consequently, a method for manufacturing a light-emitting element in which a large number of films are continuously stacked can be provided.

One embodiment of the present invention is a method for manufacturing a light-emitting element with use of the above film formation apparatus, including the following seven steps.

The first processing unit of the film formation apparatus includes a first conductive film formation chamber connected to the first carrying-out chamber, a first sealing chamber connected to the first conductive film formation chamber, a first extraction chamber connected to the first sealing chamber, and the first film formation chamber in which an evaporation source containing a material for forming a first layer, an evaporation source containing a material for forming a second layer, and an evaporation source containing a material for forming a third layer are placed in that order from the one opening side to the other opening side.

The second processing unit of the film formation apparatus includes a second conductive film formation chamber connected to the second carrying-out chamber, a second sealing chamber connected to the second conductive film formation chamber, a second extraction chamber connected to the second sealing chamber, and the second film formation chamber in which an evaporation source containing a material for forming a first layer, an evaporation source containing a material for forming a second layer, and an evaporation source containing a material for forming a third layer are placed in that order from the one opening side to the other opening side.

The first layer has one of a hole-transport property and an electron-transport property, the third layer has the other of a hole-transport property and an electron-transport property, and the second layer contains a light-emitting organic compound.

With use of this film formation apparatus, in the first step, a first object provided with a first electrode and supplied from the first carrying-in chamber is supplied to the first film formation chamber, being overlapped with a first shadow mask supplied through the other opening of the second removal chamber. Further, a second object provided with a first electrode and supplied from the second carrying-in chamber is supplied to the second film formation chamber, being overlapped with a second shadow mask supplied through the other opening of the first removal chamber.

In the second step, with use of the first film formation chamber, the first layer, the second layer, and the third layer are formed in that order on the first electrode of the first object exposed in an opening of the first shadow mask, and the first object is supplied to the first delivery chamber. Further, with use of the second film formation chamber, the first layer, the second layer, and the third layer are formed in that order on the first electrode of the second object exposed in an opening of the second shadow mask, and the second object is supplied to the second delivery chamber.

In the third step, the first delivery chamber in the first mode supplies the first object and the first shadow mask to the first carrying-out chamber and the first removal chamber, respectively. Further, the second delivery chamber in the first mode supplies the second object and the second shadow mask to the second carrying-out chamber and the second removal chamber, respectively.

In the fourth step, the first removal chamber in the first mode cleans the first shadow mask and supplies the first shadow mask to the second connection chamber of the second processing unit. Further, the second removal chamber in the first mode cleans the second shadow mask and supplies the second shadow mask to the first connection chamber of the first processing unit.

In the fifth step, the first carrying-out chamber supplies the first object to the first conductive film formation chamber, and the second carrying-out chamber supplies the second object to the second conductive film formation chamber.

In the sixth step, with the first conductive film formation chamber, a second electrode is formed to overlap with the third layer of the first object, and the first object is supplied to the first sealing chamber from the first conductive film formation chamber. Further, with the second conductive film formation chamber, a second electrode is formed to overlap with the third layer of the second object, and the second object is supplied to the second sealing chamber from the second conductive film formation chamber.

In the seventh step, with the first sealing chamber, the multilayer film in which the first layer, the second layer, the third layer, and the second electrode are stacked in that order is sealed between the first object and a sealant, and with the second sealing chamber, the multilayer film in which the first layer, the second layer, the third layer, and the second electrode are stacked in that order is sealed between the second object and a sealant.

With the method for manufacturing light-emitting elements of one embodiment of the present invention, three layers can be formed to overlap with a first electrode provided on an object with use of the first film formation chamber, and concurrently therewith, three layers can be formed to overlap with a first electrode provided on an object with use of the second film formation chamber. For example, hole-transport layers as the first layers, light-emitting layers as the second layers, and electron-transport layers as the third layers can be formed. Then, the delivery chambers in the first mode can supply the objects to the respective carrying-out chambers connected to the delivery chambers.

Further, the second electrode can be formed to overlap with the third layer with use of each of the conductive film formation chambers connected to the carrying-out chambers, whereby the light-emitting elements are manufactured, and the light-emitting element can be sealed between the object and the sealant with use of each of the sealing chambers connected to the conductive film formation chambers.

Further, film formation materials attached to the shadow masks can be removed in the removal chambers in the first mode. Consequently, it is possible to provide a method for manufacturing a light-emitting element in which films are continuously stacked while a decrease in the rate of operation of film formation chambers which are provided for continuous stacking of a large number of films is suppressed.

Note that in this specification, an “EL layer” refers to a layer provided between a pair of electrodes in a light-emitting element. Thus, a light-emitting layer containing an organic compound that is a light-emitting substance which is interposed between electrodes is one embodiment of the EL layer.

In this specification, in the case where a substance A is dispersed in a matrix formed using a substance B, the substance B forming the matrix is referred to as a host material, and the substance A dispersed in the matrix is referred to as a guest material. Note that the substance A and the substance B may each be a single substance or a mixture of two or more kinds of substances.

Note that a light-emitting device in this specification means an image display device or a light source (including a lighting device). In addition, the light-emitting device includes any of the following modules in its category: a module in which a connector such as a flexible printed circuit (FPC) or a tape carrier package (TCP) is attached to a light-emitting device; a module having a TCP provided with a printed wiring board at the end thereof; and a module having an integrated circuit (IC) directly mounted over a substrate over which a light-emitting element is formed by a chip on glass (COG) method.

According to one embodiment of the present invention, a film formation apparatus capable of forming a film with a shadow mask and removing a film formation material attached to the shadow mask can be provided. Further, a method for forming a film using a shadow mask and a method for removing a film formation material attached to the shadow mask can be provided.

According to one embodiment of the present invention, a film formation apparatus in which the number of continuously stacked films can be flexibly changed while a decrease in the rate of operation of a film formation chamber or a film formation region provided in the film formation apparatus is suppressed can be provided. Further, a method for forming a multilayer film in which the number of continuously stacked films can be flexibly changed can be provided. Furthermore, a method for manufacturing a light-emitting element can be provided.

### BRIEF DESCRIPTION OF THE DRAWINGS

FIG. 1 illustrates a structure of a film formation apparatus of one embodiment.

FIGS. 2A and 2B illustrate a structure of a removal chamber of one embodiment.

FIGS. 3A to 3D each illustrate a structure of a film formation apparatus of one embodiment.

FIGS. 4A and 4B illustrate a structure of a film formation apparatus of one embodiment.

FIGS. 5A and 5B each illustrate a structure of a film formation apparatus of one embodiment.

FIGS. 6A and 6B illustrate a structure of a processing unit of a film formation apparatus of one embodiment.

FIGS. 7A and 7B illustrate a structure of a film formation apparatus of one embodiment.

FIGS. 8A to 8D illustrate structures of a film formation apparatus of one embodiment.

FIGS. 9A to 9D illustrate a structure of a film formation apparatus of one embodiment.

FIGS. 10A and 10B each illustrate a structure of a film formation apparatus of one embodiment.

FIGS. 11A and 11B each illustrate a structure of a film formation apparatus of one embodiment.

FIG. 12 illustrates a structure of a film formation apparatus of one embodiment.

FIG. 13 illustrates a structure of a film formation apparatus of one embodiment.

FIGS. 14A to 14E each illustrate a structure of a light-emitting element which can be manufactured using a film formation apparatus of one embodiment.

FIGS. 15A to 15C illustrate a structure of a display panel which can be manufactured using a film formation apparatus of one embodiment.

FIGS. 16A and 16B illustrate a structure of a display panel which can be manufactured using a film formation apparatus of one embodiment.

FIGS. 17A and 17B each illustrate a structure of a display panel of one embodiment.

FIG. 18 shows the dependence of the removal speed of a removal chamber of one example on the kind of gas and the output of a power source.

FIG. 19 shows the dependence of the removal speed of a removal chamber of one example on the kind of gas and the distance from an upper electrode to a sample.

### DETAILED DESCRIPTION OF THE INVENTION

Embodiments and an example will be described in detail with reference to the accompanying drawings. Note that the invention is not limited to the following description, and it will be easily understood by those skilled in the art that various changes and modifications can be made without departing from the spirit and scope of the invention. Therefore, the invention should not be construed as being limited to the description in the following embodiments and example. Note that in the structures of the invention described below, the same portions or portions having similar functions are denoted by the same reference numerals in different drawings, and description of such portions is not repeated.

### Embodiment 1

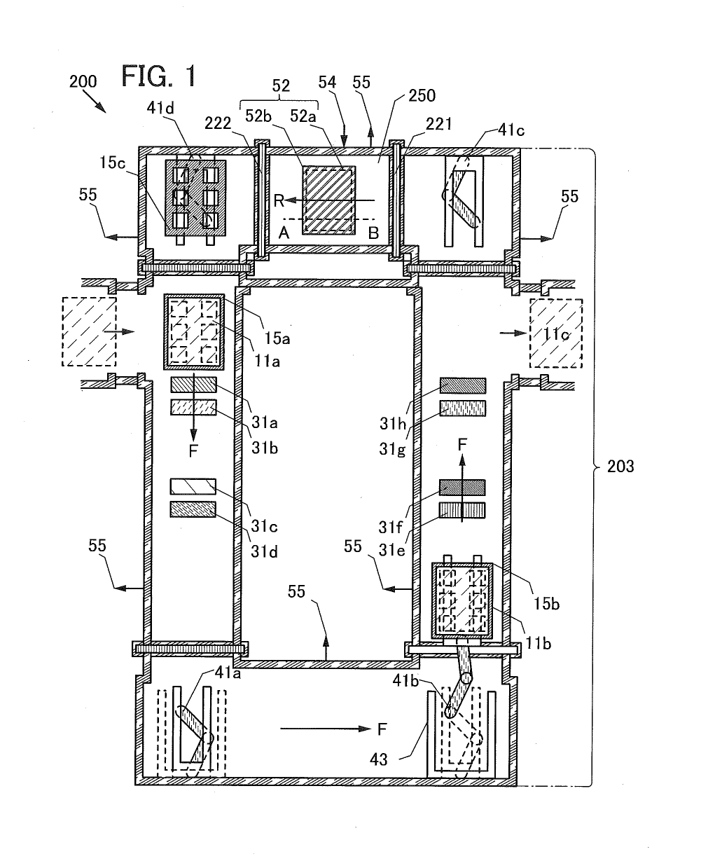

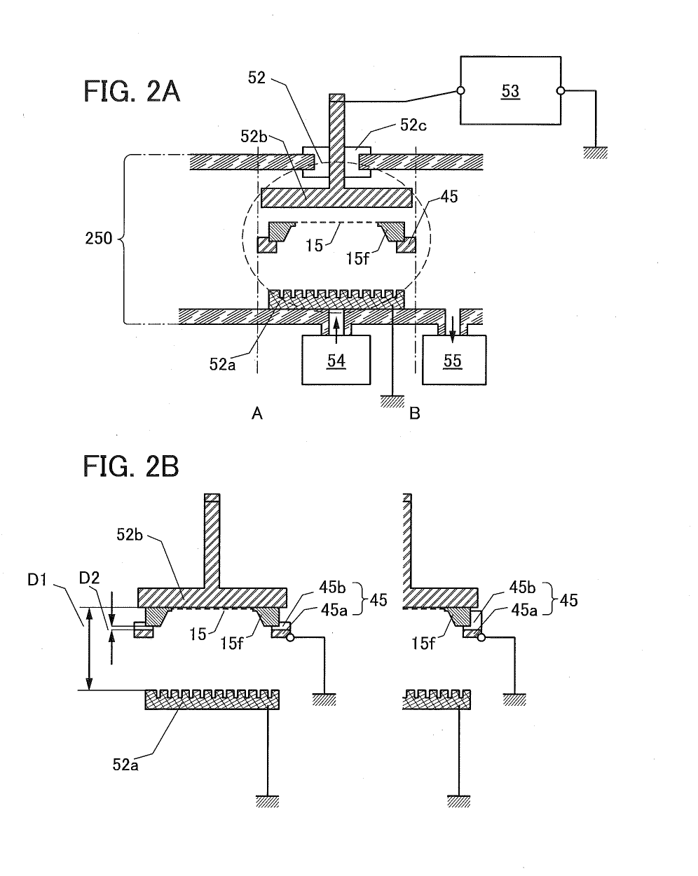

In this embodiment, a structure of a film formation apparatus of one embodiment of the present invention will be described with reference to FIG. 1 and FIGS. 2A and 2B. FIG. 1 is a top view of a structure of a film formation apparatus of one embodiment of the present invention. FIGS. 2A and 2B are side views of the structure of the film formation apparatus, which each include a cross section taken along line A-B in FIG. 1.

A film formation apparatus 200 described in this embodiment includes a removal chamber 250 and a film formation chamber 203. A first sluice valve 221 and a second sluice valve 222, which each connect the removal chamber 250 to the film formation chamber 203, are provided apart from each other between the removal chamber 250 and the film formation chamber 203. This enables a shadow mask to be carried in or carried out from/to one of the removal chamber 250 and the film formation chamber 203 to/from the other.

The film formation apparatus 200 includes a shadow mask transfer mechanism. The shadow mask transfer mechanism transfers a shadow mask through the film formation chamber 203 and the removal chamber 250. The shadow mask transfer mechanism exemplified in this embodiment includes a robot 41a (and robots 41b to 41d).

An evaporation source 31a (and evaporation sources 31b to 31h) is provided in the film formation chamber 203. The evaporation source 31a exemplified in this embodiment is a linear evaporation source which ejects a film formation material linearly, and can form a film on an object which crosses over the evaporation source 31a.

A parallel plate plasma source 52 is provided in the removal chamber 250. The plasma source 52 includes an upper electrode 52b and a lower electrode 52a with a shadow mask stage 45 provided therebetween (see FIG. 2A). Note that in the case where the shadow mask stage 45 includes a conductive support member 45a made of metal or the like, an insulating support member 45b is provided on the upper electrode 52b side (see FIG. 2B).

In this embodiment, a substrate is used as an object 11a (see FIG. 1). In the drawing, an arrow F indicates the track of the shadow mask transfer mechanism transferring the object 11a and a shadow mask 15a covering part of the object 11a through the film formation chamber 203 with the object 11a and the shadow mask 15a overlapped with each other, and an arrow R indicates the track of the shadow mask transfer mechanism transferring a shadow mask 15b to which the film formation material is attached through the removal chamber 250. Note that the robot 41c and the robot 41d transfer the shadow mask 15b to which the film formation material is attached and a shadow mask 15c from which the film formation material is removed, respectively.

The film formation apparatus 200 has a film formation mode in which the shadow mask 15a overlapped with the object 11a is transferred by the shadow mask transfer mechanism and the film formation material ejected by the evaporation source 31a or the like is deposited on the object 11a. Note that an object 11b is the object 11a on which film formation materials ejected by the evaporation sources 31a to 31d are deposited, and an object 11c is the object 11b on which film formation materials ejected by the evaporation sources 31e to 31h are deposited.

The film formation apparatus 200 also has a cleaning mode in which the shadow mask is irradiated with plasma by the plasma source 52, the shadow mask being held on the upper electrode 52b side by the shadow mask stage.

Note that the film formation chamber may be divided into a plurality of portions. When the film formation chamber is divided into a plurality of portions with a shielding plate or the like, unintentional mixing of film formation materials ejected by adjacent evaporation sources can be prevented. A sluice valve may be used instead of the shielding plate as long as it shields an object from a film formation material ejected by the adjacent evaporation source. In the case of dividing the film formation chamber into a plurality of portions, the film formation chamber is preferably divided so that films having different functions are formed in the respective portions. For example, in the case of forming layers containing light-emitting organic compounds, when the film formation chamber is divided so that layers containing light-emitting organic compounds which emit light of different colors are formed in the respective portions, each light-emitting organic compound can be made to emit light at a desired intensity. Further, when the film formation chamber is divided so that layers having different carrier (electron or hole)-transport properties are formed in the respective portions, adjustment can be made so that each layer has a desired carrier mobility.

Provision of a shadow-mask standby portion in the film formation chamber 203 facilitates switching from the film formation mode to the cleaning mode or switching from the cleaning mode to the film formation mode. Specifically, when a reproduced shadow mask is carried out from the removal chamber 250 to the shadow-mask standby portion in the film formation chamber 203, the next used shadow mask can be immediately carried into the removal chamber 250. In the film formation apparatus 200 exemplified in this embodiment, the robot 41c and the robot 41d function as shadow-mask standby portions.

The film formation apparatus 200 exemplified in this embodiment includes, as portions which perform film formation on an object, a portion provided with the evaporation sources 31a to 31d and a portion provided with evaporation sources 31e to 31h. The film formation apparatus 200 also includes, as a portion which connects the two portions, a portion provided with the robots 41a and 41b. Further, a portion provided with the robot 41c and a portion provided with the robot 41d connect the removal chamber 250 to the film formation chamber 203.

The film formation chamber 203 is provided with an exhaust mechanism 55. Since the film formation apparatus 200 exemplified in this embodiment is divided into a plurality of portions, each portion is provided with the exhaust mechanism 55.

Note that the exhaust mechanism 55, a gas introduction mechanism 54, and a high-frequency power source 53 are connected to the removal chamber 250 (see FIGS. 2A and 2B).

The high-frequency power source 53 is electrically connected to the upper electrode 52b. An insulating member 52c electrically insulates the upper electrode 52b from the wall of the removal chamber 250. A shadow mask 15 is fixed to a mask frame 15f. The mask frame 15f is held by the shadow mask stage 45.

The exhaust mechanism 55 evacuates the removal chamber 250 and adjusts the pressure inside the removal chamber 250 at the time of generating plasma.

The gas introduction mechanism 54 introduces a specific gas into the removal chamber 250 while adjusting the flow rate of the gas. A shower plate may be used for uniform introduction of gas into the removal chamber 250. Note that in this embodiment, the lower electrode 52a of the parallel plate plasma source 52 also serves as a shower plate for gas introduction.

With the film formation apparatus 200 exemplified in this embodiment, a film can be formed on the object 11a which is overlapped with the shadow mask 15a carried into the film formation chamber 203 in the film formation mode. Then, the used shadow mask 15b is carried out from the film formation chamber 203 to the removal chamber 250 through the second sluice valve 222, and the film formation material attached to the shadow mask 15b can be removed in the cleaning mode. Consequently, film formation and cleaning can be repeated without the shadow mask being taken out of the film formation apparatus, which can prevent attachment of a membranous or powdery substance to the shadow mask. Thus, a film formation apparatus capable of forming a film with a reproduced shadow mask and removing a film formation material attached to a used shadow mask can be provided.

In the film formation apparatus 200 exemplified in this embodiment, the distance in which the shadow mask is transferred through the removal chamber 250 is shorter than the distance in which the shadow mask is transferred through the film formation chamber 203. The film formation chamber 203 has a square-bracket-like shape (also referred to as a U shape) and the shadow mask is transferred through a bent path. The removal chamber 250 is provided with the first sluice valve 221 and the second sluice valve 222 apart from each other and has a shorter shadow-mask transfer path than the film formation chamber 203. This structure enables a reduction in the area occupied by the film formation apparatus (also referred to as footprint).

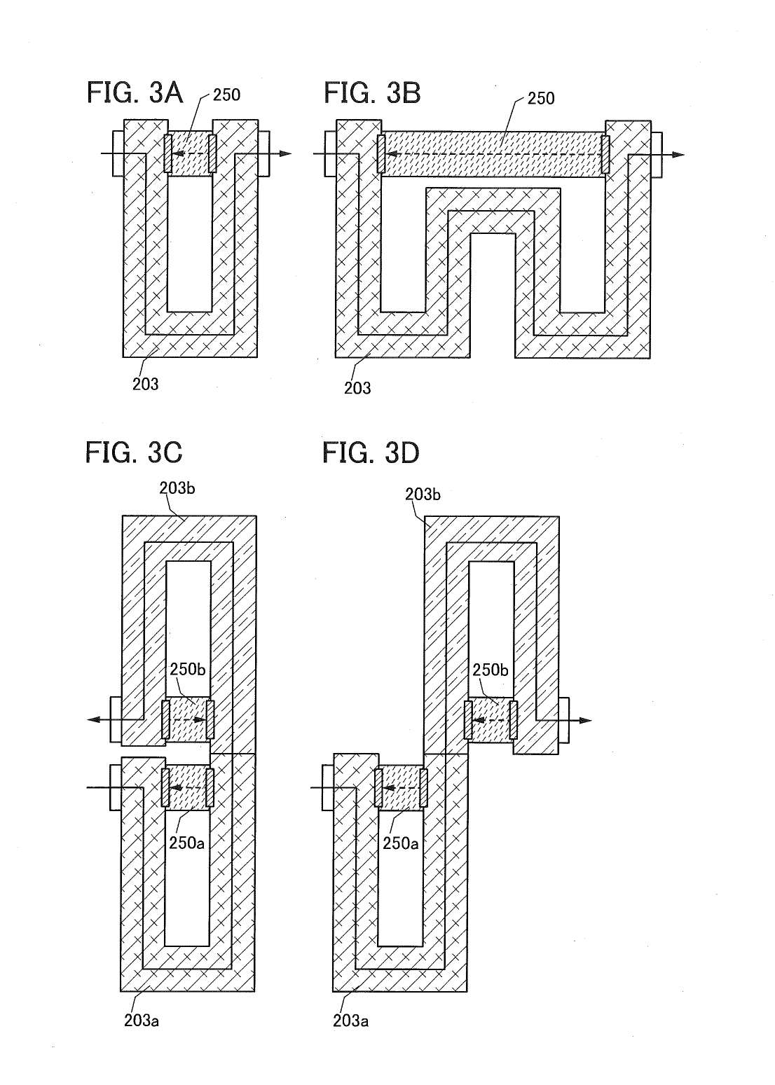

The structure of the film formation apparatus of one embodiment of the present invention is not limited to the above; for example, various structures illustrated in FIGS. 3A to 3D can be employed. Note that a solid line indicates the track of a shadow mask being transferred through the film formation chamber 203, and a broken line indicates the track of a shadow mask being transferred through the removal chamber 250. Every structure has an effect of reducing the area occupied by the film formation apparatus.

The film formation apparatus illustrated in FIG. 3A includes the film formation chamber 203 having a U shape and the removal chamber 250. This structure enables the shadow mask used in the film formation chamber 203 to be reproduced in the removal chamber 250 and used again the film formation chamber 203.

The film formation apparatus illustrated in FIG. 3B includes the film formation chamber 203 having a W shape and the removal chamber 250. This structure enables the shadow mask used in the film formation chamber 203 to be reproduced in the removal chamber 250 and used again the film formation chamber 203.

In the film formation apparatuses illustrated in FIGS. 3C and 3D, a first film formation chamber 203a having a U shape and a first removal chamber 250a are connected to each other, a second film formation chamber 203b having a U shape and a second removal chamber 250b are connected to each other, and the first film formation chamber 203a and the second film formation chamber 203b are connected to each other. This structure enables a first shadow mask used in the first film formation chamber 203a to be reproduced in the first removal chamber 250a and used again the first film formation chamber 203a. Further, a film can be formed to overlap with a film formed in the first film formation chamber 203a with use of a second shadow mask in the second film formation chamber 203b. Then, the second shadow mask used in the second film formation chamber 203b can be reproduced in the second removal chamber 250b and used again the second film formation chamber 203b.

### Modification Example

A modification example of the structure of the removal chamber in the film formation apparatus 200 described in this embodiment will be described with reference to FIG. 2B.

The shadow mask stage 45 in the film formation apparatus described in this modification example includes the support member 45a which is grounded and the insulating support member 45b which is on the upper electrode 52b side. In the cleaning mode of the film formation apparatus, the shadow mask 15 is irradiated with plasma by the plasma source, being held by the insulating support member 45b to be in contact with the upper electrode 52b.

In this structure, the shadow mask 15 is placed in a region where ions are greatly accelerated by self-bias voltage, which enables the film formation material attached to the shadow mask 15 to be removed at higher speed.

During irradiation with plasma, the upper electrode 52b and the shadow mask stage 45 are electrically insulated from each other, and a distance D2 between a portion with a potential equal to that of the upper electrode 52b and a grounded portion of the shadow mask stage 45 is shorter than a distance D1 between the upper electrode 52b and the lower electrode 52a. It is particularly preferable that the distance D2 be greater than 0 and less than or equal to half the distance D1 (see the left side of FIG. 2B).

This structure prevents abnormal discharge between the shadow mask stage 45 and the portion with a potential equal to that of the upper electrode 52b to enable stable generation of plasma.

In the case where there is a space between the upper electrode 52b and the shadow mask stage 45, abnormal discharge can be prevented by providing an insulating member in the space. For example, the insulating support member 45b may be extended to the space (see the right side of FIG. 2B).

Note that the upper electrode 52b which is in contact with the shadow mask 15 may be provided with a temperature adjustment mechanism. Heat is conducted between the shadow mask 15 and the upper electrode 52b through a contact portion thereof. The upper electrode 52b whose temperature is adjusted with the temperature adjustment mechanism is in contact with the shadow mask 15 irradiated with plasma, which enables the temperature of the shadow mask 15 to be adjusted. This can prevent damage to the shadow mask 15, such as a change in its dimensions due to a temperature rise.

The following describes individual components included in the film formation apparatus of one embodiment of the present invention.

### <Exhaust Mechanism and Gas Introduction Mechanism>

The film formation apparatus 200 exemplified in this embodiment includes the exhaust mechanism 55 that controls the pressure inside the film formation chamber 203, the exhaust mechanism 55 that controls the pressure inside the removal chamber 250, and the gas introduction mechanism 54 that adjusts the atmosphere inside the removal chamber 250.

As each exhaust mechanism 55, for example, a turbo pump, a cryopump, or the like can be used. The exhaust mechanism 55 for the removal chamber 250 is provided with an automatic pressure controller that adjusts the pressure of the removal chamber 250.

As the gas introduction mechanism 54, a mass flow meter or the like can be used. Note that the gas introduced into the removal chamber 250 is preferred to have high purity, and the content of an impurity which is contained unintentionally is preferably less than or equal to 1 ppm.

### <Shadow Mask Transfer Mechanism>

The shadow mask transfer mechanism performs a first transfer operation (arrow F) in which the shadow mask 15a before being used for film formation is transferred through the film formation chamber 203 and a second transfer operation (arrow R) in which the shadow mask 15b after being used for film formation is transferred through the removal chamber 250.

The shadow mask transfer mechanism can use any of a variety of transfer methods, such as a method in which a pair of caterpillar tracks is provided to move along with each other with an evaporation source therebetween, a support member for a shadow mask is fixed to the caterpillar tracks, and the shadow mask is transferred to cross over the evaporation source.

In the first transfer operation, the shadow mask transfer mechanism transfers a shadow mask with the shadow mask facing the direction from which a film formation material is ejected by an evaporation source and the distance between the shadow mask and the evaporation source being kept constant.

In the second transfer operation, the shadow mask transfer mechanism transfers a shadow mask to the shadow mask stage of the removal chamber 250 from the film formation chamber 203 through the first sluice valve 221, and transfers a shadow mask to the film formation chamber 203 from the shadow mask stage of the removal chamber 250 through the second sluice valve 222.

### <Sluice Valve>

Any sluice valve can be used as each of the first sluice valve 221 and the second sluice valve 222 as long as the film formation chamber 203 can be parted from the plasma source 52 while plasma irradiation is performed by the plasma source 52.

Any sluice valve which can prevent, during removal of a film formation material attached to the shadow mask with use of plasma, an increase in the pressure inside the film formation chamber 203 or contamination of the film formation chamber 203 by a substance which is vaporized by exposure to plasma is used.

### <Evaporation Source>

Any evaporation source can be used as the evaporation source 31a (and the evaporation sources 31b to 31h) as long as a film formation material can be ejected, and an evaporation source having directivity in a direction in which a film formation material is ejected is preferred because the material can be utilized efficiently.

As examples of the evaporation source 31a (and the evaporation sources 31b to 31h), other than a linear evaporation source, a point evaporation source, an evaporation source in which point sources are arranged linearly or in a matrix, and an evaporation source from which a vaporized film formation material is ejected from slit-like spaces can be given.

Moreover, the evaporation source 31a (and the evaporation sources 31b to 31h) may be made to be able to move and may be combined with a method for forming a film while scanning the object with the evaporation source.

### <Plasma Source>

The plasma source 52 is a parallel plate plasma source.

The gas used for plasma can be selected depending on a film formation material and a material of a shadow mask; for example, a rare gas (e.g., argon, xenon, or helium), a reducing gas (e.g., hydrogen), an oxidizing gas (e.g., oxygen), a halide gas (e.g., carbon tetrafluoride), or a gas in which any of these gases are mixed as appropriate can be used.

Alternatively, with the use of a linear laser as an auxiliary besides the plasma, an organic substance attached to the shadow mask may be baked and separated from the shadow mask to be removed by plasma.

Note that a structure in which plasma generated in a region far from a plasma irradiation region is supplied to the plasma irradiation region (a remote plasma source) can be employed. In that case, for example, a hollow cathode type can be employed.

### <Shadow Mask>

A variety of shadow masks can be used for the film formation apparatus of one embodiment of the present invention. For example, a thin plate or a foil provided with an opening and attached to a rigid frame (also referred to as a mask frame) can be used.

Metal, ceramics, or the like with small thermal expansion coefficient, for example, a nickel alloy or stainless steel, can be used for a rigid frame. Metal with small thermal expansion coefficient is used for a thin plate or a foil provided with an opening. For example, a metal plate containing nickel provided with an opening by an etching method, a metal foil formed by an electroforming method, or the like can be used.

In the removal chamber of the film formation apparatus of one embodiment of the present invention, a film formation material attached to a shadow mask can be removed. In particular, a film formation material which is attached to a shadow mask provided with a minute opening (whose diameter or one side is greater than or equal to 1 μm and less than or equal to 500 μm, for example) can be removed without damage to the shadow mask.

Next, a method for forming a film and a method for removing a film formation material attached to a shadow mask which use the above film formation apparatus will be described.

<Method for Forming Film and Method for Removing Film Formation Material Attached to Shadow Mask which Use Film Formation Apparatus>

The method for forming a film and the method for removing a film formation material attached to a shadow mask which is exemplified in this embodiment include four steps.

In the first step, the object 11a is overlapped with an opening of the shadow mask 15a (see FIG. 1). The shadow mask 15a and the object 11a may be provided with alignment markers, in which case the position at which the object 11a is overlapped over the shadow mask 15a can be adjusted.

In the second step, the shadow mask 15a whose opening is overlapped with the object 11a is transferred with use of the shadow mask transfer mechanism, and the film formation material ejected upwards by the evaporation source 31a (and the evaporation sources 31b to 31h) is deposited on the object 11a from the lower side.

In the third step, the shadow mask used in the second step is carried out to the removal chamber 250 through the first sluice valve 221. Then, the used shadow mask held on the upper electrode 52b side by the shadow mask stage 45 is irradiated with plasma by the plasma source 52 (see FIGS. 2A and 2B).

In the fourth step, the shadow mask from which the film formation material is removed in the third step is carried into the film formation chamber 203 through the second sluice valve 222.

The above method includes a step of forming a film on an object with use of a shadow mask and a step of reproducing the shadow mask by removing a film formation material attached thereto. In this method, the film formation material attached to the shadow mask in the second step can be removed in the third step. The shadow mask reproduced in the third step is used again in the first step; thus, the shadow mask can be repeatedly used. Consequently, a method for forming a film using a shadow mask and a method for removing a film formation material attached to the shadow mask can be provided.

Note that this embodiment can be combined with any of the other embodiments and example in this specification as appropriate.

### Embodiment 2

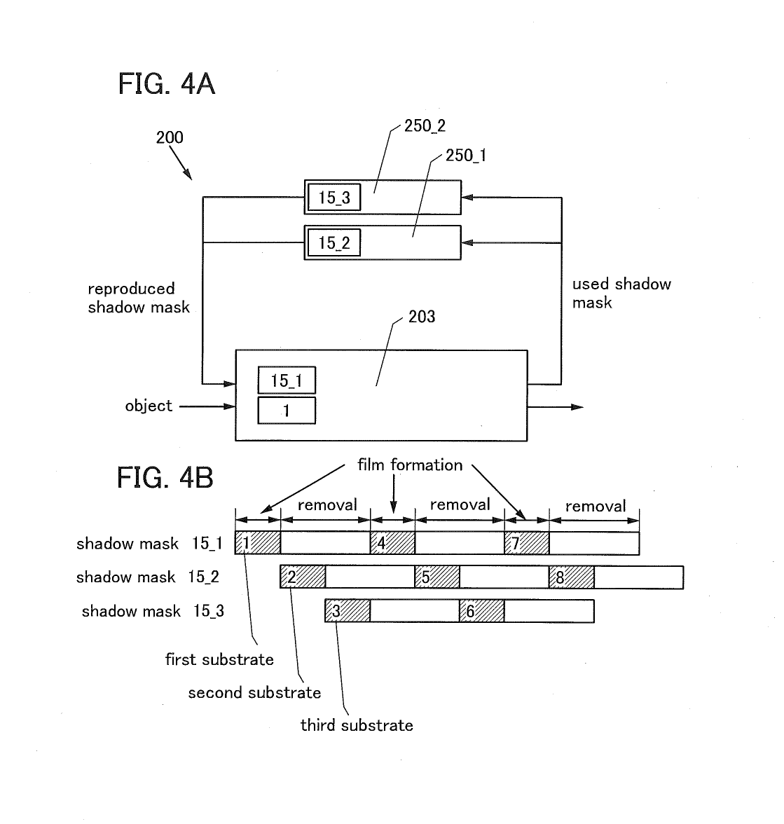

In this embodiment, a structure of a film formation apparatus of one embodiment of the present invention will be described with reference to FIGS. 4A and 4B. FIG. 4A is a block diagram schematically showing the structure of the film formation apparatus of one embodiment of the present invention, and FIG. 4B is a chart showing a method for continuously forming films on a plurality of objects and continuously reproducing used shadow masks with use of the film formation apparatus and the shadow masks in FIG. 4A.

The film formation apparatus described in this embodiment includes a first removal chamber 250_1 and a second removal chamber 250_2 (see FIG. 4A). Each removal chamber includes a shadow mask stage and a plasma source which are not shown.

This structure enables a plurality of shadow masks to be concurrently irradiated with plasma in the plurality of removal chambers; thus, film formation materials can be concurrently removed from the plurality of shadow masks. Furthermore, this structure enables the shadow masks to be irradiated with plasma for a longer time without interruption of continuous film formation on objects.

For example, in a film formation apparatus having one film formation chamber and one removal chamber, removal of a film formation material needs to be finished within a film formation period in order to continuously form films on a plurality of objects without interruption. Accordingly, the removal speed needs to be higher than or equal to the film formation speed.

In contrast, in a film formation apparatus having one film formation chamber and n (n is a natural number) removal chambers, continuous film formation on objects can be performed without interruption as long as removal of a film formation material is finished within n times a film formation period. Accordingly, the removal speed only needs to be higher than or equal to 1/n times the film formation speed. Note that the removal needs to be finished in a shorter time in the case where the gas introduction, the pressure adjustment, and the evacuation performed on the removal chamber take much time. In that case, an additional removal chamber may be provided.

FIG. 4A illustrates a first shadow mask 15_1, a second shadow mask 15_2, a third shadow mask 15_3, and an object 1, which is one of a plurality of objects on which films are continuously formed.

A method for continuous film formation using a film formation apparatus including a plurality of removal chambers is described. Specifically, a method for continuously forming films on objects with use of a film formation apparatus having one film formation chamber and two removal chambers and three shadow masks is described with reference to FIG. 4B. Note that numbers 1 to 8 in FIG. 4B denote the order of film formation on the objects in the film formation apparatus.

### <Method for Continuous Film Formation on Objects>

The method for forming a film and the method for removing a film formation material attached to a shadow mask which is exemplified in this embodiment include seven steps. FIGS. 4A and 4B illustrate the case where a substrate is used as an object. Note that the first substrate, the second substrate, and the third substrate in the drawing can also be referred to as a first object, a second object, and a third object, respectively.

In the first step, a film is formed on the first object in the film formation chamber 203 with use of the first shadow mask 15_1.

In the second step, a reproduced shadow mask is carried into the film formation chamber 203 from the removal chamber, and a film is formed on an object with use thereof. For example, the second shadow mask 15_2 is carried in from the first removal chamber 250_1, and a film is formed on the second object with use of the second shadow mask 15_2.

In the third step, the used first shadow mask 15_1 is carried out to the removal chamber and the film formation material is removed therefrom. For example, the used first shadow mask 15_1 is carried out to the first removal chamber 250_1 to be reproduced.

In the fourth step, a reproduced shadow mask is carried into the film formation chamber 203 from the removal chamber, and a film is formed on an object with use thereof. For example, the third shadow mask 15_3 is carried in from the second removal chamber 250_2, and a film is formed on the third object with use of the third shadow mask 15_3.

In the fifth step, the used second shadow mask 15_2 is carried out to the removal chamber and the film formation material is removed therefrom. For example, the used second shadow mask 15_1 is carried out to the second removal chamber 250_2 to be reproduced.

In the sixth step, a reproduced shadow mask is carried into the film formation chamber 203 from the removal chamber.

In the seventh step, the used third shadow mask 15_3 is carried out to the removal chamber and the film formation material is removed therefrom. For example, the used third shadow mask 15_3 is carried out to the first removal chamber 250_1 to be reproduced. Here, in the case of further performing film formation continuously, the first step is performed again, in which a film is formed on an object with use of the shadow mask carried into the film formation chamber 203 in the sixth step. For example, the first shadow mask 15_1 is carried in from the first removal chamber 250_1, and a film is formed on a fourth object with use of the first shadow mask 15_1.

The above steps are repeated; thus, the shadow masks can be irradiated with plasma for a longer time without interruption of continuous film formation on the objects.

Note that this embodiment can be combined with any of the other embodiments and example in this specification as appropriate.

### Embodiment 3

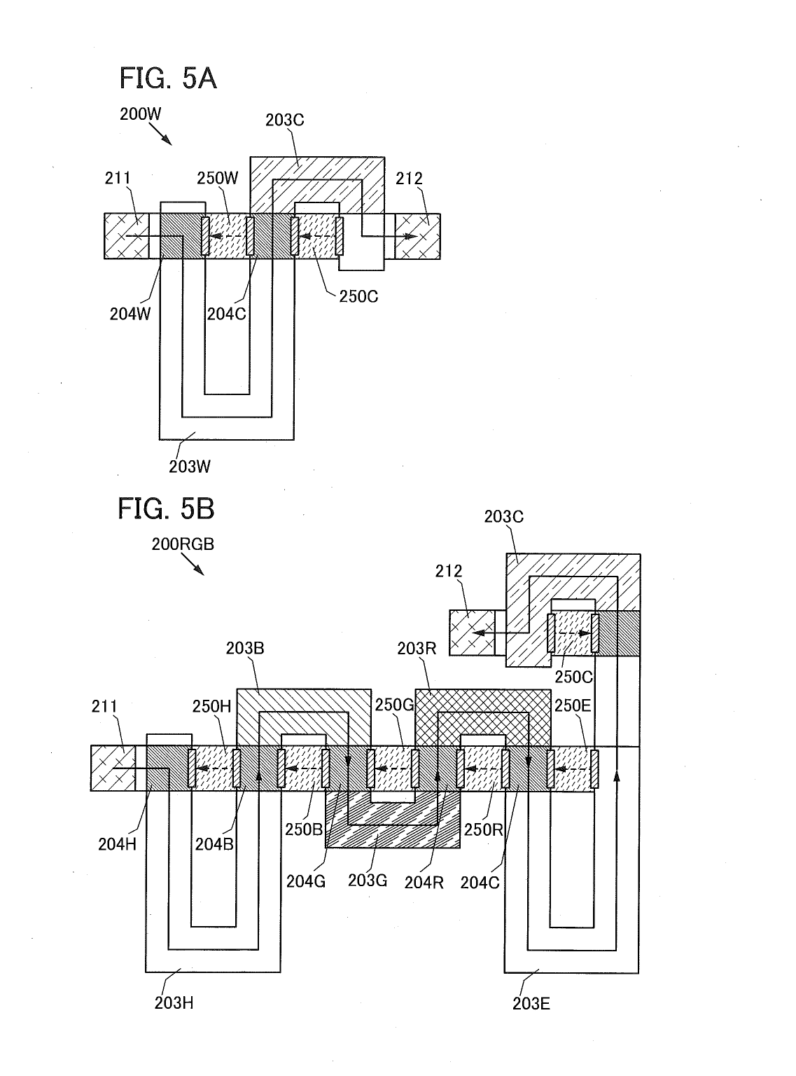

In this embodiment, an example of a structure of a film formation apparatus of one embodiment of the present invention which can be used for manufacture of a display panel will be described. FIGS. 5A and 5B illustrate structures of a film formation apparatus described in this embodiment. Note that a solid line indicates the track of a shadow mask being transferred through a film formation chamber, and a broken line indicates the track of a shadow mask being transferred through a removal chamber.

### Structure Example 1 of Film Formation Apparatus

A film formation apparatus 200W illustrated in FIG. 5A is a film formation apparatus which can be used for manufacture of a light-emitting element.

The film formation apparatus 200W includes a first film formation chamber 203W, a first removal chamber 250W, a second film formation chamber 203C, a second removal chamber 250C, and a carrying-in chamber 211 and a carrying-out chamber 212 for an object. The carrying-in chamber 211 is for carrying in the object to the film formation apparatus 200W. The carrying-out chamber 212 is for carrying out the object on which a film formation material is deposited from the film formation apparatus 200W.

Note that the carrying-out chamber 212 may be provided with a sealing portion so that an object with a sealed film formation material layer is carried out from the film formation apparatus.

An alignment portion 204W performs alignment between the object and a first shadow mask. An alignment portion 204C performs alignment between the object and a second shadow mask.

A method for manufacturing a light-emitting element which emits white light with use of the film formation apparatus 200W is described. Structure Example 3 of a light-emitting element which is described in Embodiment 10 is an example of a light-emitting element which emits white light.

A substrate over which a first electrode, a first terminal electrically connected to the first electrode, and a second terminal electrically connected to a second electrode, which is formed later, are formed can be used as the object. For example, the substrate may be an active matrix substrate in which the first electrodes are provided in a matrix and electrically connected to respective transistors.

In the first film formation chamber 203W, a layer containing a light-emitting organic compound is formed over the first electrode with use of the first shadow mask. The first film formation chamber 203W may be divided into a plurality of regions or a plurality of chambers, and the layer containing a light-emitting organic compound may be formed by stacking films formed in the respective regions or chambers. Note that a film formation material used for the layer containing a light-emitting organic compound is attached to the used first shadow mask.

The film formation material attached to the used first shadow mask is removed in the first removal chamber 250W.

The distance in which the first shadow mask is transferred through the first removal chamber 250W is shorter than the distance in which the first shadow mask is transferred through the first film formation chamber 203W in which film formation is performed during transfer. Thus, a structure in which the first shadow mask is transferred through a bent path has an effect of reducing the area occupied by the film formation apparatus.

In the second film formation chamber 203C, the second electrode is formed to overlap with the layer containing a light-emitting organic compound with use of the second shadow mask. The second film formation chamber 203C may be one region or divided into two or more regions; the formed second electrode may be a single film or stacked films. Note that the second shadow mask is provided with an opening for forming the second electrode of the light-emitting element. The second electrode is formed with a shape corresponding to the shape of the opening, whereby the second electrode is electrically connected to the second terminal.

The film formation material attached to the used second shadow mask is removed in the second removal chamber 250C. Here, the shadow mask is damaged when plasma which removes the material used for the second electrode etches the shadow mask. Thus, a gas which hardly etches the material for the shadow mask is selected.

With the use of the film formation apparatus 200W exemplified in this embodiment, a display panel exemplified in Embodiment 12 can be manufactured, for example. Specifically, a display panel in which a color filter is provided to overlap with a light-emitting element which emits white light can be manufactured. Note that the color filter may be provided either on a side closer to the substrate than the first electrode of the object or on a side closer to a sealing substrate than the second electrode.

### Structure Example 2 of Film Formation Apparatus

A film formation apparatus 200RGB illustrated in FIG. 5B is a film formation apparatus which can be used for manufacture of a light-emitting element.

The film formation apparatus 200RGB includes a first film formation chamber 203H, a first removal chamber 250H, a second film formation chamber 203B, a second removal chamber 250B, a third film formation chamber 2036, a third removal chamber 2506, a fourth film formation chamber 203R, a fourth removal chamber 250R, a fifth film formation chamber 203E, a fifth removal chamber 250E, a sixth film formation chamber 203C, a sixth removal chamber 250C, and the carrying-in chamber 211 and the carrying-out chamber 212 for an object. The carrying-in chamber 211 is for carrying in the object to the film formation apparatus 200RGB. The carrying-out chamber 212 is for carrying out the object on which a film formation material is deposited from the film formation apparatus 200RGB.

Note that the carrying-out chamber 212 may be provided with a sealing portion so that an object with a sealed film formation material layer is carried out from the film formation apparatus.

An alignment portion 204H performs alignment between the object and a first shadow mask. An alignment portion 204B performs alignment between the object and a second shadow mask. An alignment portion 204G performs alignment between the object and a third shadow mask. An alignment portion 204R performs alignment between the object and a fourth shadow mask. An alignment portion 204E performs alignment between the object and a fifth shadow mask. An alignment portion 204C performs alignment between the object and a sixth shadow mask.

A method for manufacturing light-emitting elements which emit light of different colors over one substrate with use of the film formation apparatus 200RGB is described. Structure Example 1 of a light-emitting element which is described in Embodiment 10 is an example of a structure of each light-emitting element.

Specifically, a method for manufacturing three kinds of light-emitting elements, a light-emitting element which emits blue light, a light-emitting element which emits green light, and a light-emitting element which emits red light, over one object is described.

A substrate over which a first electrode of a light-emitting element which emits blue light, a first electrode of a light-emitting element which emits green light, a first electrode of a light-emitting element which emits red light, first terminals electrically connected to the respective first electrodes, and a second terminal electrically connected to a second electrode, which is formed later, are formed can be used as the object. For example, the substrate may be an active matrix substrate in which the first electrodes are provided in a matrix and electrically connected to respective transistors.

In the first film formation chamber 203H, layers containing an organic compound which transports one carrier (e.g., holes) are formed over the first electrodes with use of the first shadow mask. The first film formation chamber 203H may be divided into a plurality of regions or a plurality of chambers, and the layers containing an organic compound which transports one carrier may be formed by stacking films formed in the respective regions or chambers. Note that a film formation material used for the layers containing an organic compound which transports one carrier is attached to the used first shadow mask.

The film formation material attached to the used first shadow mask is removed in the first removal chamber 250H.

The distance in which the first shadow mask is transferred through the first removal chamber 250H is shorter than the distance in which the first shadow mask is transferred through the first film formation chamber 203H in which film formation is performed during transfer. Thus, a structure in which the first shadow mask is transferred through a bent path has an effect of reducing the area occupied by the film formation apparatus.

In the alignment portion 204B, the second shadow mask and the object are overlapped with each other so that the opening of the second shadow mask overlaps with the first electrode of the light-emitting element which emits blue light of the object. Then, in the second film formation chamber 203B, a layer containing a light-emitting organic compound which emits blue light is formed over the layer containing an organic compound which transports one carrier with use of the second shadow mask. Note that a film formation material used for the layer containing a light-emitting organic compound which emits blue light is attached to the used second shadow mask.

The film formation material attached to the used second shadow mask is removed in the second removal chamber 250B.

In the alignment portion 204G, the third shadow mask and the object are overlapped with each other so that the opening of the third shadow mask overlaps with the first electrode of the light-emitting element which emits green light of the object. Then, in the third film formation chamber 203G, a layer containing a light-emitting organic compound which emits green light is formed over the layer containing an organic compound which transports one carrier with use of the third shadow mask. Note that a film formation material used for the layer containing a light-emitting organic compound which emits green light is attached to the used third shadow mask.

The film formation material attached to the used third shadow mask is removed in the third removal chamber 250G.

In the alignment portion 204R, the fourth shadow mask and the object are overlapped with each other so that the opening of the fourth shadow mask overlaps with the first electrode of the light-emitting element which emits red light of the object. Then, in the fourth film formation chamber 203R, a layer containing a light-emitting organic compound which emits red light is formed over the layer containing an organic compound which transports one carrier with use of the fourth shadow mask. Note that a film formation material used for the layer containing a light-emitting organic compound which emits red light is attached to the used fourth shadow mask.

The film formation material attached to the used fourth shadow mask is removed in the fourth removal chamber 250R.

Note that the second film formation chamber 203B, the third film formation chamber 203G, and the fourth film formation chamber 203R may each be divided into a plurality of regions or a plurality of chambers.

In the fifth film formation chamber 203E, layers containing an organic compound which transports the other carrier are formed to overlap with the layer containing a light-emitting organic compound which emits blue light, the layer containing a light-emitting organic compound which emits green light, and the layer containing a light-emitting organic compound which emits red light with use of the fifth shadow mask. The fifth film formation chamber 203E may be divided into a plurality of regions or a plurality of chambers, and the layers containing an organic compound which transports the other carrier may be formed by stacking films formed in the respective regions or chambers. Note that a film formation material used for the layers containing an organic compound which transports the other carrier is attached to the used fifth shadow mask.

The film formation material attached to the used fifth shadow mask is removed in the fifth removal chamber 250E.

The distance in which the fifth shadow mask is transferred through the fifth removal chamber 250E is shorter than the distance in which the fifth shadow mask is transferred through the fifth film formation chamber 203E in which film formation is performed during transfer. Thus, a structure in which the fifth shadow mask is transferred through a bent path has an effect of reducing the area occupied by the film formation apparatus.

In the sixth film formation chamber 203C, the second electrode is formed to overlap with the layers containing an organic compound which transports the other carrier with use of the sixth shadow mask. The sixth film formation chamber 203C may be one region or divided into two or more regions; the formed second electrode may be a single film or stacked films. Note that the sixth shadow mask is provided with an opening for forming the second electrode of the light-emitting elements. The second electrode is formed with a shape corresponding to the shape of the opening, whereby the second electrode is electrically connected to the second terminal.

The film formation material attached to the used sixth shadow mask is removed in the sixth removal chamber 250C. Here, the shadow mask is damaged when plasma which removes the material used for the second electrode etches the shadow mask. Thus, a gas which hardly etches the material for the shadow mask is selected.

With the use of Structure Example 2 of the film formation apparatus exemplified in this embodiment, a display panel exemplified in Embodiment 12 can be manufactured, for example. Specifically, a display panel which includes a pixel which emits blue light, a pixel which emits green light, and a pixel which emits red light over an active matrix substrate can be manufactured. Note that the display panel may perform display on either the first electrode side or the second electrode side.

The film formation apparatus exemplified in this embodiment can be used for manufacture of not only a display panel but also a light-emitting device which is applicable to a lighting device or the like.

Note that this embodiment can be combined with any of the other embodiments and example in this specification as appropriate.

### Embodiment 4

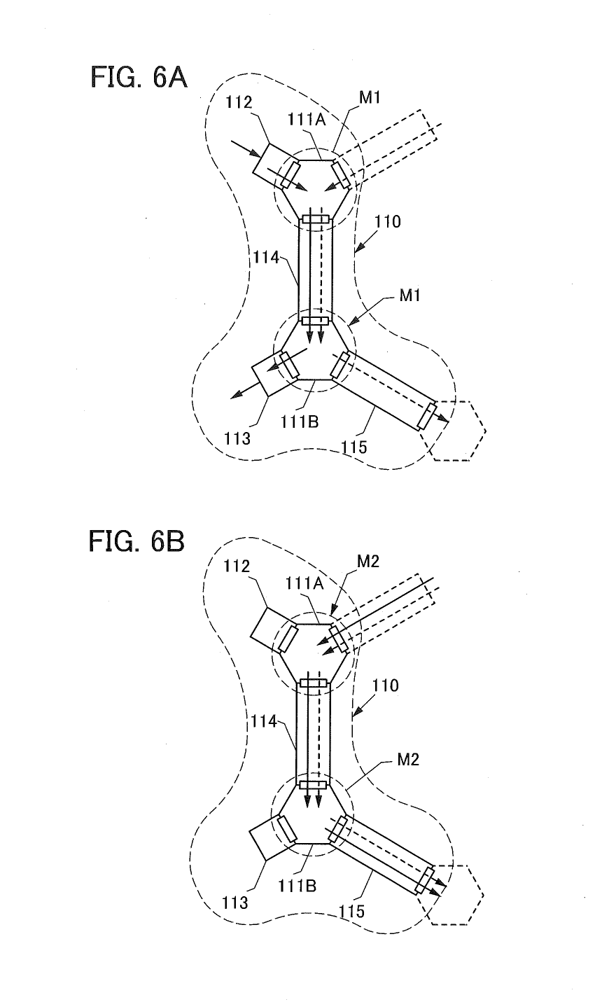

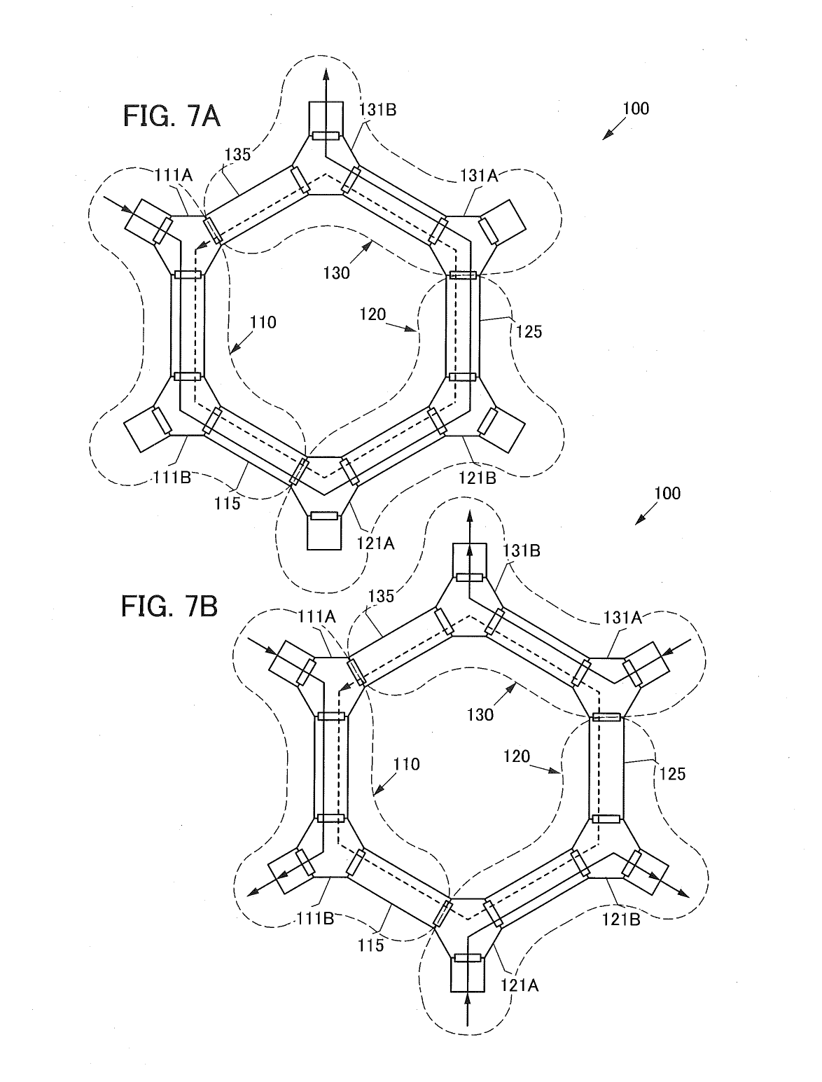

In this embodiment, a structure of a film formation apparatus of one embodiment of the present invention will be described with reference to FIGS. 6A and 6B and FIGS. 7A and 7B. FIGS. 6A and 6B are top views of a first processing unit 110 included in a film formation apparatus of one embodiment of the present invention. FIGS. 7A and 7B are top views of a film formation apparatus 100 of one embodiment of the present invention.

The film formation apparatus 100 described in this embodiment includes the first processing unit 110 including a connection chamber 111A and a delivery chamber 111B, a second processing unit 120 including a connection chamber 121A and a delivery chamber 121B, and a third processing unit 130 including a connection chamber 131A and a delivery chamber 131B (see FIGS. 7A and 7B).

The first processing unit 110 includes a connection chamber 111A, a carrying-in chamber 112 which supplies an object to the connection chamber 111A, a film formation chamber 114 with one opening connected to the connection chamber 111A, a delivery chamber 111B to which the other opening of the film formation chamber 114 is connected, a carrying-out chamber 113 which withdraws the object from the delivery chamber 111B, a removal chamber 115 with one opening connected to the delivery chamber 111B, and a shadow mask transfer mechanism which is not shown (see FIGS. 6A and 6B).

The second processing unit 120 and the third processing unit 130 each have a structure similar to that of the first processing unit 110.

The connection chamber 111A of the first processing unit 110 is connected to the other opening of a removal chamber 135 of the third processing unit 130, the connection chamber 121A of the second processing unit 120 is connected to the other opening of the removal chamber 115 of the first processing unit 110, and the connection chamber 131A of the third processing unit 130 is connected to the other opening of a removal chamber 125 of the second processing unit 120 (see FIGS. 7A and 7B).

Each connection chamber has a first mode and a second mode. The first mode (M1 in the drawing) of the connection chamber 111A illustrated in FIG. 6A is a mode in which an object (indicated by a solid line arrow) supplied from the carrying-in chamber 112 is overlapped with a shadow mask (indicated by a broken line arrow) supplied from the other opening of the removal chamber of another processing unit (e.g., the removal chamber 135 of the third processing unit 130) and supplied to the film formation chamber 114.

The second mode (M2 in the drawing) of the connection chamber 111A illustrated in FIG. 6B is a mode in which a shadow mask overlapped with an object (indicated by solid line and broken line arrows) and supplied from the other opening of the removal chamber of another processing unit is supplied to the film formation chamber 114.

Each film formation chamber includes an evaporation source which is not shown.

The shadow mask transfer mechanism which is not shown transfers the shadow mask overlapped with the object through a region where the evaporation source ejects a film formation material, and the evaporation source deposits the film formation material on the object exposed in an opening of the shadow mask.

Each delivery chamber has a first mode and a second mode. The first mode (M1 in the drawing) of the delivery chamber 111B illustrated in FIG. 6A is a mode in which an object (indicated by a sold line arrow) and a shadow mask (indicated by a broken line arrow) are supplied to the carrying-out chamber 113 and the removal chamber 115, respectively.

The second mode (M2 in the drawing) of the delivery chamber 111B illustrated in FIG. 6B is a mode in which a shadow mask overlapped with an object (indicated by solid line and broken line arrows) is supplied to the removal chamber 115.

The removal chamber has a cleaning mechanism, a first mode, and a second mode. The first mode is a mode in which a shadow mask is cleaned by the cleaning mechanism and the shadow mask is supplied to the connection chamber of another processing unit. The second mode is a mode in which a shadow mask overlapped with an object is supplied to the connection chamber of another processing unit.

For example, in the film formation apparatus 100 exemplified in this embodiment, the connection chamber 111A of the first processing unit 110 and the delivery chamber 131B of the third processing unit 130 can be operated in the first mode, and all the other connection chambers and delivery chambers can be operated in the second mode (see FIG. 7A).

In this manner, an object can be supplied to the first processing unit 110 from the carrying-in chamber 112, transferred through all the film formation chambers provided in the film formation apparatus 100, and supplied to a carrying-out chamber 133 of the third processing unit 130. Thus, films can be continuously formed on the object with use of all the film formation chambers provided in the film formation apparatus 100 (the track of the object is indicated by a solid line arrow in FIG. 7A).

Note that the removal chamber 135 of the third processing unit 130 connected to the connection chamber 111A can be operated in the first mode. Thus, the film formation materials attached to the shadow mask can be removed (the track of the shadow mask is indicated by a broken line arrow in FIG. 7A).

Alternatively, in the film formation apparatus 100 exemplified in this embodiment, the connection chambers, the delivery chambers, and the removal chambers of all the processing units can be operated in the first mode (see FIG. 7B).

In this manner, film formation materials can be concurrently deposited on a plurality of objects in the plurality of film formation chambers in the film formation apparatus 100.

Note that the film formation materials attached to a plurality of shadow masks can be concurrently removed in the plurality of removal chambers in the film formation apparatus 100.

As described above, it is possible to provide a film formation apparatus in which the number of films which can be continuously formed can be flexibly changed while a decrease in the rate of operation of film formation chambers which are provided for continuous stacking of a large number of films is suppressed.

### Modification Example 1

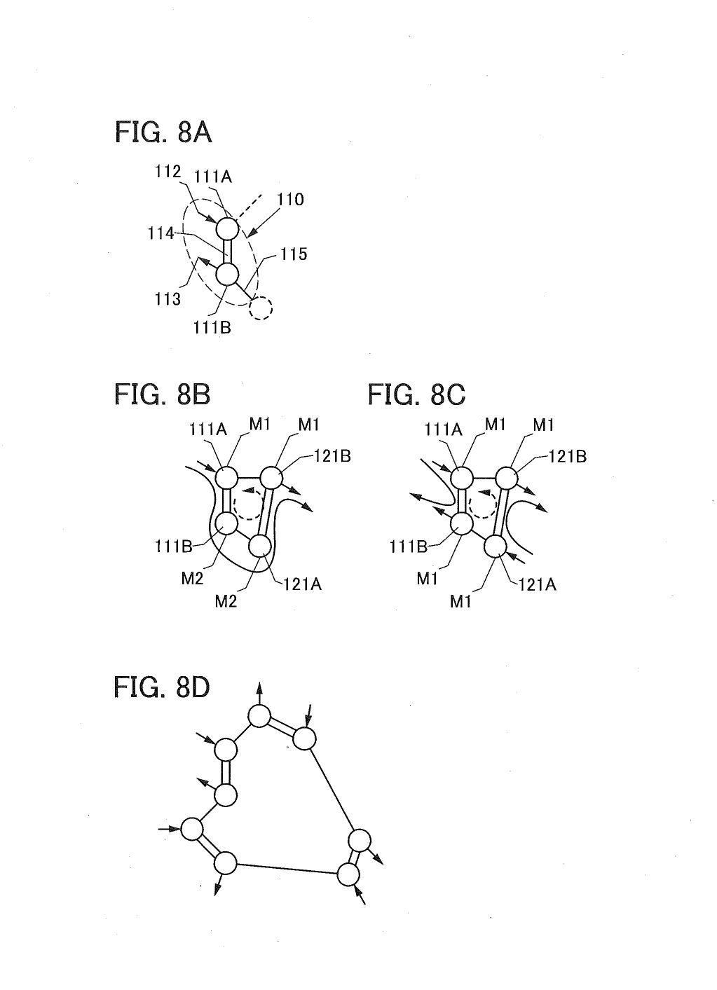

A modification example of the film formation apparatus exemplified in this embodiment is described with reference to FIGS. 8A to 8D. FIG. 8A schematically illustrates a structure of the first processing unit 110 included in the film formation apparatus of one embodiment of the present invention. FIGS. 8B and 8C are examples in which two processing units are connected to form a film formation apparatus. FIG. 8D is an example in which four processing units are connected to form a film formation apparatus. In this manner, the number of connected processing units can be changed depending on the number of films to be stacked.

Each of the film formation apparatuses described in this embodiment as modification examples (see FIGS. 8B to 8D) includes a plurality of processing units each including a connection chamber, a carrying-in chamber which supplies an object to the connection chamber, a film formation chamber with one opening connected to the connection chamber, a delivery chamber to which the other opening of the film formation chamber is connected, a carrying-out chamber which withdraws the object from the delivery chamber, and a removal chamber with one opening connected to the delivery chamber. The connection chamber of one processing unit is connected to the other opening of the removal chamber of another processing unit in an annular manner.

The connection chamber of one processing unit and the delivery chamber of another processing unit whose removal chamber is connected to the connection chamber can be operated in the first mode, and all the other connection chambers and delivery chambers can be operated in the second mode (see FIG. 8B). In this manner, film formation materials can be stacked on one object with use of all the film formation chambers in the film formation apparatus, and the object can be withdrawn by the carrying-out chamber connected to the delivery chamber in the first mode of another processing unit.

In addition, the removal chamber of another processing unit connected to the connection chamber can be operated in the first mode. Thus, the film formation materials attached to the shadow mask can be removed.

Alternatively, the connection chambers, the delivery chambers, and the removal chambers of all the processing units can be operated in the first mode (see FIG. 8C). In this manner, film formation materials can be concurrently deposited on a plurality of objects in the plurality of film formation chambers in the film formation apparatus. Further, the film formation materials attached to a plurality of shadow masks can be concurrently removed in the plurality of removal chambers. Consequently, it is possible to provide a film formation apparatus in which the number of films which can be continuously formed can be flexibly changed while a decrease in the rate of operation of film formation chambers which are provided for continuous stacking of a large number of films is suppressed.

The following describes individual components included in the film formation apparatus of one embodiment of the present invention.

### <<Connection Chamber and Delivery Chamber>>

The connection chamber connects the carrying-in chamber, the film formation chamber, and the removal chamber of another processing unit so that an object and a shadow mask can be transferred therebetween. Further, in the connection chamber, an object supplied from the carrying-in chamber is overlapped with a shadow mask supplied from another processing unit. The connection chamber is preferably provided with an alignment mechanism for aligning an object with a shadow mask.

The delivery chamber connects the carrying-out chamber, the film formation chamber, and the removal chamber so that an object and a shadow mask can be transferred therebetween.

### <<Evaporation Source>>

Any evaporation source can be used as long as a film formation material can be ejected, and an evaporation source having directivity in a direction in which a film formation material is ejected is preferred because the material can be utilized efficiently.

As examples of the evaporation source, other than a linear evaporation source, a point evaporation source, an evaporation source in which point sources are arranged linearly or in a matrix, and an evaporation source from which a vaporized film formation material is ejected from slit-like spaces can be given.

Moreover, the evaporation source may be made to be able to move and may be combined with a method for forming a film while scanning the object with the evaporation source.

### <<Shadow Mask>>

A variety of shadow masks can be used for the film formation apparatus of one embodiment of the present invention. For example, a thin plate or a foil provided with an opening and attached to a rigid frame (also referred to as a mask frame) can be used.

Metal, ceramics, or the like with small thermal expansion coefficient, for example, a nickel alloy or stainless steel, can be used for a rigid frame. Metal with small thermal expansion coefficient is used for a thin plate or a foil provided with an opening. For example, a metal plate containing nickel provided with an opening by an etching method, a metal foil formed by an electroforming method, or the like can be used.

### <<Shadow Mask Transfer Mechanism>>

The shadow mask transfer mechanism transfers a shadow mask through a processing unit.

The shadow mask transfer mechanism can use any of a variety of transfer methods, such as a method in which a pair of caterpillar tracks is provided to move along with each other with an evaporation source therebetween, a support member for a shadow mask is fixed to the caterpillar tracks, and the shadow mask is transferred to cross over the evaporation source.

The shadow mask transfer mechanism transfers a shadow mask, one surface of which is overlapped with an object, with the other surface of the shadow mask facing the direction from which a film formation material is ejected by an evaporation source and the distance between the shadow mask and the evaporation source being kept constant.

### <<Removal Chamber>>

In the removal chamber, a cleaning mechanism is provided, which can remove a film formation material attached to a shadow mask. In particular, a film formation material which is attached to a shadow mask provided with a minute opening (whose diameter or one side is greater than or equal to 1 μm and less than or equal to 500 μm, for example) can be removed without damage to the shadow mask.

A plasma source can be used as the cleaning mechanism, for example. The film formation material attached to the shadow mask is irradiated with plasma by the plasma source, whereby the film formation material can be removed. The film formation material reacts with plasma to be vaporized and exhausted from the removal chamber.

### <<Plasma Source>>

As the plasma source used as the cleaning mechanism, a variety of plasma sources can be used as well as a parallel plate plasma source.

Note that a structure in which plasma generated in a region far from a plasma irradiation region is supplied to the plasma irradiation region (a remote plasma source) can be employed. In that case, for example, a hollow cathode type can be employed.

The gas used for plasma can be selected depending on a film formation material and a material of a shadow mask; for example, a rare gas (e.g., argon, xenon, or helium), a reducing gas (e.g., hydrogen), an oxidizing gas (e.g., oxygen), a halide gas (e.g., carbon tetrafluoride), or a gas in which any of these gases are mixed as appropriate can be used.

Alternatively, with the use of a linear laser as an auxiliary besides the plasma, an organic substance attached to the shadow mask may be baked and separated from the shadow mask to be removed by plasma.

### <<Exhaust Mechanism and Gas Introduction Mechanism>>

In the case where a plasma source is used as the cleaning mechanism of the removal chamber, the removal chamber includes an exhaust mechanism that controls the pressure inside the removal chamber and a gas introduction mechanism that adjusts the atmosphere inside the removal chamber.

As the exhaust mechanism, for example, a turbo pump, a cryopump, or the like can be used. The exhaust mechanism can be provided with an automatic pressure controller that adjusts the pressure of the removal chamber.

As the gas introduction mechanism, a mass flow meter or the like can be used. Note that the gas introduced into the removal chamber is preferred to have high purity, and the content of an impurity which is contained unintentionally is preferably less than or equal to 1 ppm.

Note that this embodiment can be combined with any of the other embodiments and example in this specification as appropriate.

### Embodiment 5

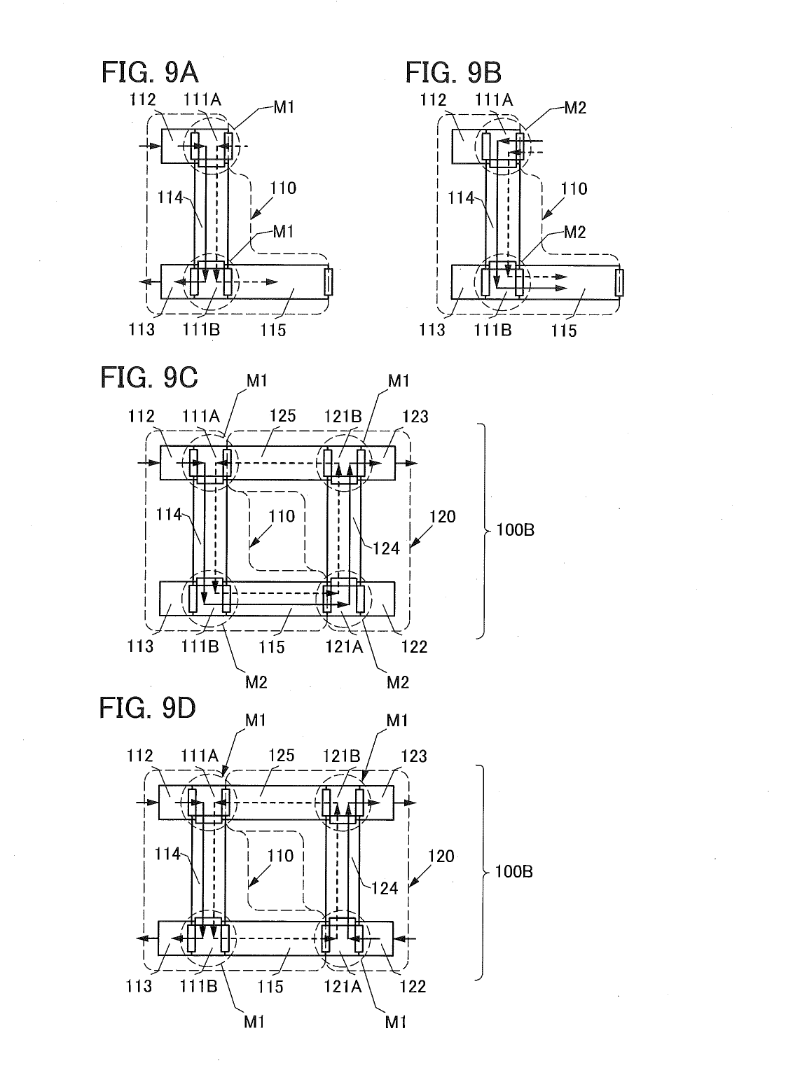

In this embodiment, a structure of a film formation apparatus of one embodiment of the present invention will be described with reference to FIGS. 9A to 9D. FIGS. 9A and 9B are top views of the first processing unit 110 included in a film formation apparatus of one embodiment of the present invention. FIGS. 9C and 9D are top views of a film formation apparatus 100B of one embodiment of the present invention.

The film formation apparatus 100B described in this embodiment includes the first processing unit 110 and the second processing unit 120 (see FIG. 9C).

The first processing unit 110 includes a first connection chamber 111A, a first carrying-in chamber 112 which supplies an object to the first connection chamber 111A, a first film formation chamber 114 with one opening connected to the first connection chamber 111A, a first delivery chamber 111B to which the other opening of the first film formation chamber 114 is connected, a first carrying-out chamber 113 which withdraws the object from the first delivery chamber 111B, a first removal chamber 115 with one opening connected to the first delivery chamber 111B, and a first shadow mask transfer mechanism which is not shown.

The second processing unit 120 includes a second connection chamber 121A, a second carrying-in chamber 122 which supplies an object to the second connection chamber 121A, a second film formation chamber 124 with one opening connected to the second connection chamber 121A, a second delivery chamber 121B to which the other opening of the second film formation chamber 124 is connected, a second carrying-out chamber 123 which withdraws the object from the second delivery chamber 121B, a second removal chamber 125 with one opening connected to the second delivery chamber 121B, and a second shadow mask transfer mechanism which is not shown.

The first connection chamber 111A of the first processing unit 110 is connected to the other opening of the second removal chamber 125 of the second processing unit 120.

The second connection chamber 121A of the second processing unit 120 is connected to the other opening of the first removal chamber 115 of the first processing unit 110.

The first connection chamber 111A has a first mode in which an object supplied from the first carrying-in chamber 112 is supplied to the first film formation chamber 114, the object being overlapped with a shadow mask supplied through the other opening of the second removal chamber 125, and a second mode in which a shadow mask overlapped with an object and supplied through the other opening of the second removal chamber 125 is supplied to the first film formation chamber 114.

The second connection chamber 121A has a first mode in which an object supplied from the second carrying-in chamber 122 is supplied to the second film formation chamber 124, the object being overlapped with a shadow mask supplied through the other opening of the first removal chamber 115, and a second mode in which a shadow mask overlapped with an object and supplied through the other opening of the first removal chamber 115 is supplied to the second film formation chamber 124.

The first film formation chamber 114 includes a first evaporation source which is not shown.

The second film formation chamber 124 includes a second evaporation source which is not shown.

The first shadow mask transfer mechanism which is not shown transfers a shadow mask overlapped with an object through a region where the first evaporation source ejects a film formation material, and the second shadow mask transfer mechanism which is also not shown transfers a shadow mask overlapped with an object through a region where the second evaporation source ejects a film formation material.

The first delivery chamber 111B has a first mode in which an object and a shadow mask are supplied to the first carrying-out chamber 113 and the first removal chamber 115, respectively, and a second mode in which a shadow mask overlapped with an object is supplied to the first removal chamber 115.

The second delivery chamber 121B has a first mode in which an object and a shadow mask are supplied to the second carrying-out chamber 123 and the second removal chamber 125, respectively, and a second mode in which a shadow mask overlapped with an object is supplied to the second removal chamber 125.

The first removal chamber 115 has a first cleaning mechanism, a first mode in which a shadow mask is cleaned and supplied to the second connection chamber 121A of the second processing unit 120, and a second mode in which a shadow mask overlapped with an object is supplied to the second connection chamber 121A of the second processing unit 120.

The second removal chamber 125 has a second cleaning mechanism, a first mode in which a shadow mask is cleaned and supplied to the first connection chamber 111A of the first processing unit 110, and a second mode in which a shadow mask overlapped with an object is supplied to the first connection chamber 111A of the first processing unit 110.

Next, the operation of the film formation apparatus of one embodiment of the present invention is described.

In the film formation apparatus 100B of one embodiment of the present invention, the first connection chamber 111A of the first processing unit 110 is connected to the other opening of the second removal chamber 125 of the second processing unit 120, and the second connection chamber 121A of the second processing unit 120 is connected to the other opening of the first removal chamber 115 of the first processing unit 110.

### Operation Example 1

The first connection chamber 111A of the first processing unit 110 and the second delivery chamber 121B of the second processing unit 120 can be operated in the first mode, and the first delivery chamber 111B of the first processing unit 110 and the second connection chamber 121A of the second processing unit 120 can be operated in the second mode (see FIG. 9C).

In this manner, with use of the first film formation chamber 114 and the second film formation chamber 124 in the film formation apparatus 100B, the film formation material of the first evaporation source can be deposited on one object carried into the first connection chamber 111A in the first mode, and the film formation material of the second evaporation source can be deposited to overlap with the film formation material of the first evaporation source. Then, the second carrying-out chamber 123 connected to the second delivery chamber 121B in the first mode of the second processing unit 120 can withdraw the object. Further, the film formation materials attached to the shadow mask can be removed in the second removal chamber 125 in the first mode connected to the second delivery chamber 121B in the first mode.

### Operation Example 2

Alternatively, the first connection chamber 111A and the first delivery chamber 111B in the first processing unit 110 and the second connection chamber 121A and the second delivery chamber 121B in the second processing unit 120 can all be operated in the first mode (see FIG. 9D).

In this manner, film formation materials can be concurrently deposited on two objects with use of the first film formation chamber 114 and the second film formation chamber 124. Consequently, it is possible to provide a film formation apparatus in which the number of films which can be continuously formed can be flexibly changed while a decrease in the rate of operation of film formation chambers which are provided for continuous stacking of a large number of films is suppressed.

Note that this embodiment can be combined with any of the other embodiments and example in this specification as appropriate.

### Embodiment 6

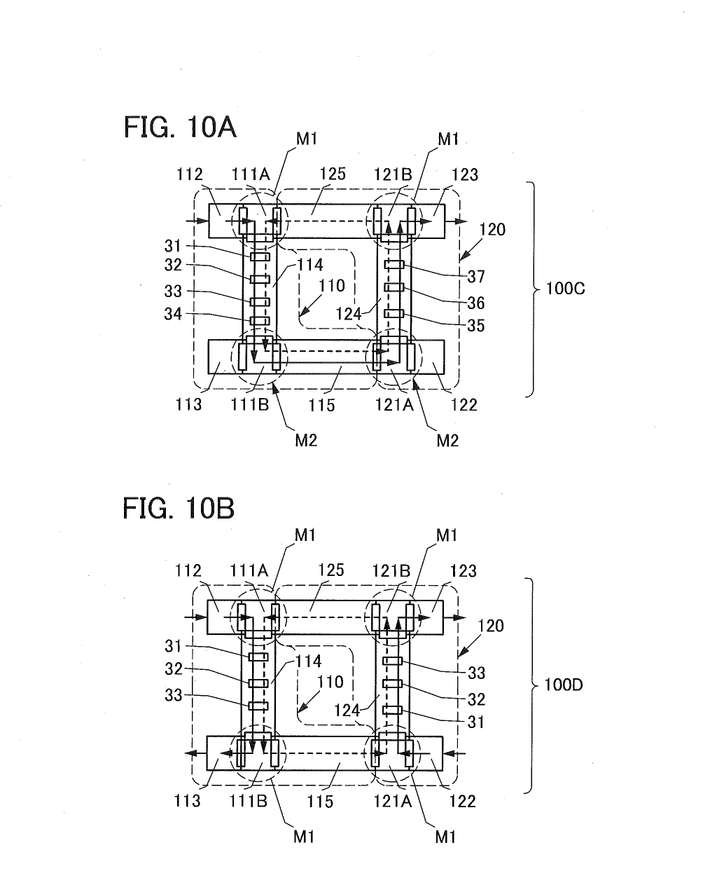

In this embodiment, a method for forming a multilayer film using the film formation apparatus of one embodiment of the present invention described in Embodiment 5 will be described with reference to FIG. 10A.

Specifically, a method is described in which, with use of a film formation apparatus including two processing units, a layer of a film formation material deposited in a film formation chamber of one processing unit is stacked over a layer of a film formation material deposited in a film formation chamber of the other processing unit.

FIG. 10A illustrates a film formation apparatus 100C of one embodiment of the present invention. Similarly to the film formation apparatus described in Embodiment 5, the film formation apparatus 100C includes the first processing unit 110 and the second processing unit 120.

In the first processing unit 110, an evaporation source 31 containing a material for forming a first layer, an evaporation source 32 containing a material for forming a second layer, an evaporation source 33 containing a material for forming a third layer, and an evaporation source 34 containing a material for forming a fourth layer are placed in that order from the one opening side to the other opening side in the first film formation chamber 114.

In the second processing unit 120, an evaporation source 35 containing a material for forming a fifth layer, an evaporation source 36 containing a material for forming a sixth layer, and an evaporation source 37 containing a material for forming a seventh layer are placed in that order from the one opening side to the other opening side in the second film formation chamber 124.

A method for forming seven layers on one object by seven steps with use of the film formation apparatus 100C is described below. Note that, in the drawing, a solid line arrow indicates the track of the object being transferred and a broken line arrow indicates the track of a shadow mask being transferred.

### <First Step>

With the use of the film formation apparatus 100C having the above structure, an object supplied from the first carrying-in chamber 112 is supplied to the first film formation chamber 114, being overlapped with a shadow mask supplied through the other opening of the second removal chamber 125.

### <Second Step>

With the first film formation chamber 114, the first layer containing the film formation material ejected by the evaporation source 31, the second layer containing the film formation material ejected by the evaporation source 32, the third layer containing the film formation material ejected by the evaporation source 33, and the fourth layer containing the film formation material ejected by the evaporation source 34 are formed in that order on the object exposed in an opening of the shadow mask, and the object is supplied to the first delivery chamber 111B.

### <Third Step>

The first delivery chamber 111B in the second mode supplies the shadow mask overlapped with the object to the first removal chamber 115, and the first removal chamber 115 in the second mode supplies the shadow mask overlapped with the object to the second connection chamber 121A of the second processing unit 120.

### <Fourth Step>

The second connection chamber 121A in the second mode supplies the shadow mask overlapped with the object to the second film formation chamber 124.

### <Fifth Step>

With use of the second film formation chamber 124, the fifth layer containing the film formation material ejected by the evaporation source 35, the sixth layer containing the film formation material ejected by the evaporation source 36, and the seventh layer containing the film formation material ejected by the evaporation source 37 are formed in that order to overlap with the fourth layer formed on the object exposed in an opening of the shadow mask, and the object is supplied to the second delivery chamber 121B.

### <Sixth Step>

The second delivery chamber 121B in the first mode supplies the object and the shadow mask to the second carrying-out chamber 123 and the second removal chamber 125, respectively.

### <Seventh Step>

The second removal chamber 125 in the first mode cleans the shadow mask and supplies the shadow mask to the first connection chamber 111A of the first processing unit 110.

With the method for forming a multilayer film of one embodiment of the present invention, four layers can be stacked on one object supplied to the first connection chamber 111A in the first mode with use of the first film formation chamber 114 in the film formation apparatus 100C. Three layers can be formed to overlap with the four layers with use of the second film formation chamber 124. Then, the object can be supplied to the second carrying-out chamber 123 connected to the second delivery chamber 121B in the first mode. Further, film formation materials attached to the shadow mask can be removed in the second removal chamber 125 in the first mode. Consequently, a large number of films can be continuously stacked.

Note that this embodiment can be combined with any of the other embodiments and example in this specification as appropriate.

### Embodiment 7

In this embodiment, a method for forming multilayer films using the film formation apparatus of one embodiment of the present invention described in Embodiment 5 will be described with reference to FIG. 10B.

Specifically a method is described in which, with use of a film formation apparatus including two processing units, a film formation material is deposited on one object in a film formation chamber provided in one processing unit, and concurrently therewith, a film formation material is deposited on another object in a film formation chamber provided in the other processing unit.

FIG. 10B illustrates a film formation apparatus 100D of one embodiment of the present invention. Similarly to the film formation apparatus described in Embodiment 5, the film formation apparatus 100D includes the first processing unit 110 and the second processing unit 120.

In the first processing unit 110, the evaporation source 31 containing a material for forming a first layer, the evaporation source 32 containing a material for forming a second layer, and the evaporation source 33 containing a material for forming a third layer are placed in that order from the one opening side to the other opening side in the first film formation chamber 114.

In the second processing unit 120, the evaporation source 31 containing a material for forming a first layer, the evaporation source 32 containing a material for forming a second layer, and the evaporation source 33 containing a material for forming a third layer are placed in that order from the one opening side to the other opening side in the second film formation chamber 124.

### <First Step>

The first connection chamber 111A in the first mode of the film formation apparatus having the above structure supplies a first object supplied from the first carrying-in chamber 112 to the first film formation chamber 114, the first object being overlapped with a first shadow mask supplied through the other opening of the second removal chamber 125. Further, the second connection chamber 121A in the first mode supplies a second object supplied from the second carrying-in chamber 122 to the second film formation chamber 124, the second object being overlapped with a second shadow mask supplied through the other opening of the first removal chamber 115.

### <Second Step>

With the first film formation chamber 114, the first layer containing the film formation material ejected by the evaporation source 31, the second layer containing the film formation material ejected by the evaporation source 32, and the third layer containing the film formation material ejected by the evaporation source 33 are formed in that order on the first object exposed in an opening of the first shadow mask, and the first object is supplied to the first delivery chamber 111B.

Further, with the second film formation chamber 124, the first layer containing the film formation material ejected by the evaporation source 31, the second layer containing the film formation material ejected by the evaporation source 32, and the third layer containing the film formation material ejected by the evaporation source 33 are formed in that order on the second object exposed in an opening of the second shadow mask, and the second object is supplied to the second delivery chamber 121B.

### <Third Step>

The first delivery chamber 111B in the first mode supplies the first object and the first shadow mask to the first carrying-out chamber 113 and the first removal chamber 115, respectively. Further, the second delivery chamber 121B in the first mode supplies the second object and the second shadow mask to the second carrying-out chamber 123 and the second removal chamber 125, respectively.

### <Fourth Step>

The first removal chamber 115 in the first mode cleans the first shadow mask and supplies the first shadow mask to the second connection chamber 121A of the second processing unit 120. Further, the second removal chamber 125 in the first mode cleans the second shadow mask and supplies the second shadow mask to the first connection chamber 111A of the first processing unit 110.

With the method for forming multilayer films of one embodiment of the present invention, film formation materials can be concurrently deposited on two objects with use of the first film formation chamber 114 and the second film formation chamber 124 in the film formation apparatus 100D. Consequently, it is possible to provide a film formation apparatus in which the number of films which can be continuously formed can be flexibly changed while a decrease in the rate of operation of film formation chambers which are provided for continuous stacking of a large number of films is suppressed.

Note that this embodiment can be combined with any of the other embodiments and example in this specification as appropriate.

### Embodiment 8

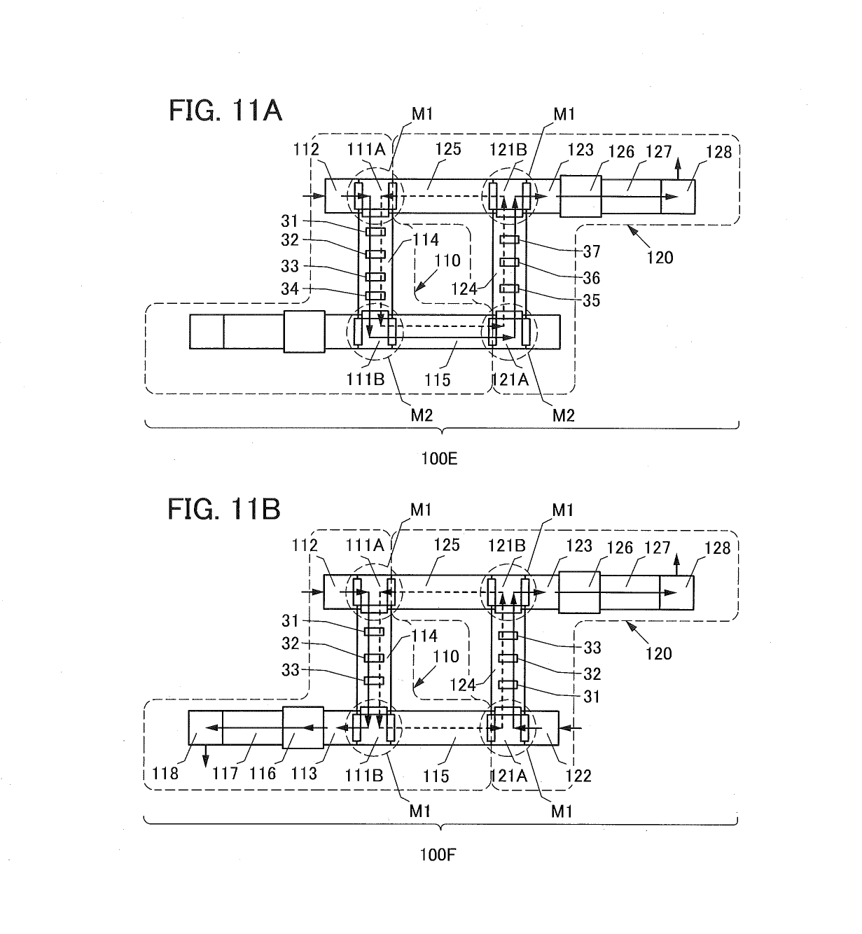

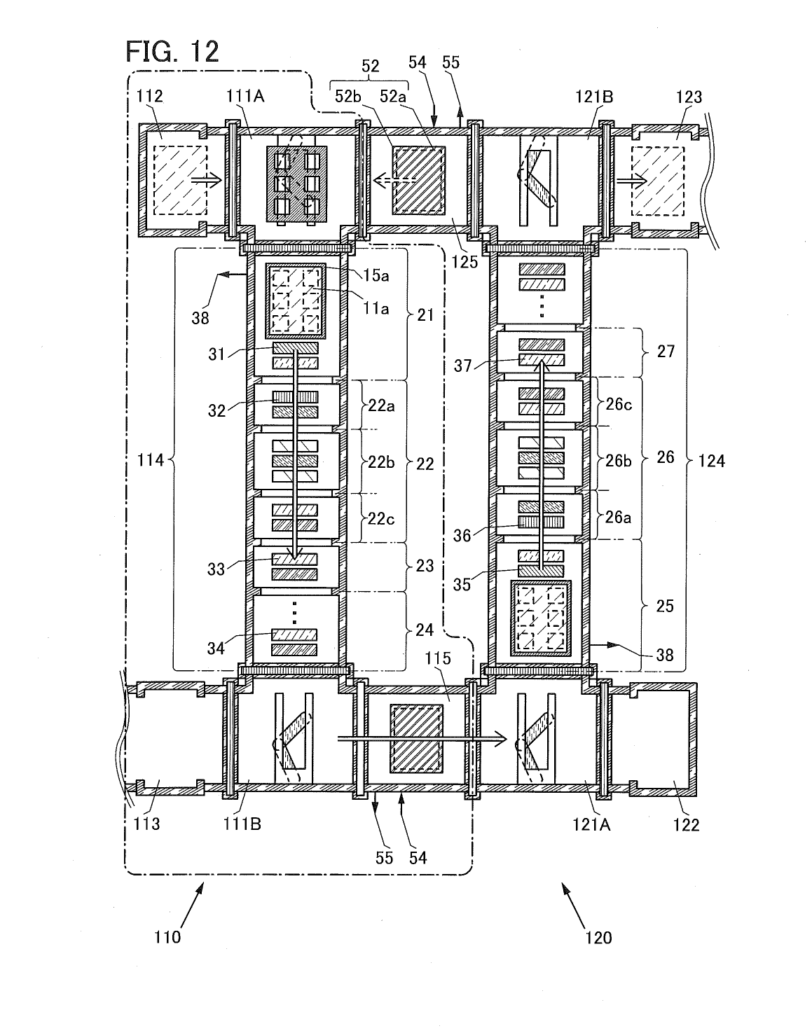

In this embodiment, a method for manufacturing a light-emitting element using the film formation apparatus of one embodiment of the present invention described in Embodiment 5 will be described with reference to FIG. 11A and FIG. 12.

Specifically, a method is described in which, with use of a film formation apparatus including two processing units, a layer of a film formation material deposited in a film formation chamber of one processing unit is stacked over a layer of a film formation material deposited in a film formation chamber of the other processing unit, whereby a light-emitting element with a structure exemplified by Structure Example 3 of the light-emitting element in Embodiment 10 is manufactured.

### <Structure of Film Formation Apparatus>

First, a structure of a film formation apparatus 100E which can be used for manufacture of the light-emitting element exemplified in this embodiment is described with reference to FIG. 11A.

FIG. 11A illustrates the film formation apparatus 100E of one embodiment of the present invention. Similarly to the film formation apparatus described in Embodiment 5, the film formation apparatus 100E includes the first processing unit 110 and the second processing unit 120.

The first processing unit 110 includes the first connection chamber 111A, the first carrying-in chamber 112 which supplies an object to the first connection chamber 111A, the first film formation chamber 114 with one opening connected to the first connection chamber 111A, the first delivery chamber 111B to which the other opening of the first film formation chamber 114 is connected, the first carrying-out chamber 113 which withdraws the object from the first delivery chamber 111B, and the first removal chamber 115 with one opening connected to the first delivery chamber 111B.

Further, the first processing unit 110 includes the first film formation chamber 114 in which the evaporation source 31 containing a material for forming a first layer, the evaporation source 32 containing a material for forming a second layer, the evaporation source 33 containing a material for forming a third layer, and the evaporation source 34 containing a material for forming a fourth layer are placed in that order from the one opening side to the other opening side.

The second processing unit 120 includes the second connection chamber 121A, the second carrying-in chamber 122 which supplies an object to the second connection chamber 121A, the second film formation chamber 124 with one opening connected to the second connection chamber 121A, the second delivery chamber 121B to which the other opening of the second film formation chamber 124 is connected, the second carrying-out chamber 123 which withdraws the object from the second delivery chamber 121B, and the second removal chamber 125 with one opening connected to the second delivery chamber 121B.

The second processing unit 120 also includes a second conductive film formation chamber 126 connected to the second carrying-out chamber 123, a second sealing chamber 127 connected to the second conductive film formation chamber 126, and a second extraction chamber 128 connected to the second sealing chamber 127.

Further, the second processing unit 120 includes the second film formation chamber 124 in which the evaporation source 35 containing a material for forming a fifth layer, the evaporation source 36 containing a material for forming a sixth layer, and the evaporation source 37 containing a material for forming a seventh layer are placed in that order from the one opening side to the other opening side.

The second conductive film formation chamber 126 includes an evaporation source containing a material for forming a second electrode of a light-emitting element and is connected to the second carrying-out chamber 123.

In the second sealing chamber 127, films formed in the first film formation chamber 114, the second film formation chamber 124, and the second conductive film formation chamber 126 are sealed between the object and a sealant.

The second extraction chamber 128 is for taking out the light-emitting element from the film formation apparatus.

Note that the first layer and the fifth layer have one of a hole-transport property and an electron-transport property, and the third layer and the seventh layer have the other of a hole-transport property and an electron-transport property. The second layer and the sixth layer contain a light-emitting organic compound. The fourth layer is an intermediate layer.

A specific structure of the film formation apparatus 100E exemplified in this embodiment is described below with reference to FIG. 12. FIG. 12 is a top view of part of the first processing unit 110 and part of the second processing unit 120, which is used for describing details of part of the film formation apparatus 100E.

### <<First Film Formation Chamber>>

In the first film formation chamber 114, the evaporation source 31 containing a material for forming the first layer, the evaporation source 32 containing a material for forming the second layer, the evaporation source 33 containing a material for forming the third layer, and the evaporation source 34 containing a material for forming the fourth layer are placed in that order from the one opening side to the other opening side. Note that an exhaust mechanism 38 is connected to the first film formation chamber 114. As the exhaust mechanism 38, for example, a turbo pump, a cryopump, or the like can be used.

Note that the first film formation chamber 114 is divided into a film formation region 21, a film formation region 22, a film formation region 23, and a film formation region 24. The film formation region 22 is divided into a film formation region 22a, a film formation region 22b, and a film formation region 22c. In each film formation region, a film formation material ejected by an evaporation source provided in that region is deposited on an object. A partition is provided between adjacent film formation regions so that a film formation material ejected by an evaporation source provided in one film formation region is not deposited on the object in the other film formation region. The shadow mask 15a overlapped with the object 11a is shown in the drawing.

Further, by using different materials for a plurality of evaporation sources provided in one film formation region, a mixed layer including those materials can be formed.

### <<Second Film Formation Chamber>>

In the second film formation chamber 124, the evaporation source 35 containing a material for forming the fifth layer, the evaporation source 36 containing a material for forming the sixth layer, and the evaporation source 37 containing a material for forming the seventh layer are placed in that order from the one opening side to the other opening side. Note that the exhaust mechanism 38 is connected to the second film formation chamber 124.

Note that the second film formation chamber 124 is divided into a film formation region 25, a film formation region 26, and a film formation region 27. The film formation region 26 is divided into a film formation region 26a, a film formation region 26b, and a film formation region 26c. In each film formation region, a film formation material ejected by an evaporation source provided in that region is deposited on an object. A partition is provided between adjacent film formation regions so that a film formation material ejected by an evaporation source provided in one film formation region is not deposited on the object in the other film formation region.

### <<Example of Film Formation Material Applicable to Film Formation Apparatus>>

With the method for manufacturing a light-emitting element exemplified in this embodiment, a layer of a film formation material deposited in a film formation chamber of one processing unit can be stacked over a layer of a film formation material deposited in a film formation chamber of the other processing unit with use of a film formation apparatus including two processing units. Thus, the method for manufacturing a light-emitting element exemplified in this embodiment is favorably used for manufacture of a light-emitting element with a structure exemplified by Structure Example 3 of the light-emitting element in Embodiment 10.

For example, a first hole-transport layer as the first layer, a first light-emitting layer as the second layer, a first electron-transport layer as the third layer, an intermediate layer as the fourth layer, a second hole-transport layer as the fifth layer, a second light-emitting layer as the sixth layer, and a second electron-transport layer as the seventh layer can be continuously formed to be stacked over a first electrode provided on the object. Further, a second electrode can be stacked over the seventh layer.

It is also possible to form a layer containing a light-emitting organic compound which emits blue fluorescence as the first light-emitting layer and a stack of a layer containing a light-emitting organic compound which emits green phosphorescence and a layer containing a light-emitting organic compound which emits red phosphorescence as the second light-emitting layer and use the first electrode as an anode and the second electrode as a cathode. Such a structure enables a reduction in driving voltage; thus, a light-emitting element which efficiently emits white light and has low power consumption can be provided.

### <<Removal Chamber>>

The removal chamber is provided with the plasma source 52, the gas introduction mechanism 54, and the exhaust mechanism 55. The plasma source 52 is a parallel plate plasma source which includes the lower electrode 52a and the upper electrode 52b.

As the exhaust mechanism 55, for example, a turbo pump, a cryopump, or the like can be used. The exhaust mechanism 55 is provided with an automatic pressure controller that adjusts the pressure of the removal chamber.

As the gas introduction mechanism 54, a mass flow meter or the like can be used. Note that the gas introduced into the removal chamber is preferred to have high purity, and the content of an impurity which is contained unintentionally is preferably less than or equal to 1 ppm.

### <Method for Manufacturing Light-Emitting Element>

A method for manufacturing a light-emitting element using the film formation apparatus 100E will be described below with reference to FIG. 11A.

### <First Step>

With the use of the film formation apparatus having the above structure, an object provided with a first electrode and supplied from the first carrying-in chamber 112 is supplied to the first film formation chamber 114, being overlapped with a shadow mask supplied through the other opening of the second removal chamber 125.

### <Second Step>

With the first film formation chamber 114, the first layer containing the film formation material ejected by the evaporation source 31, the second layer containing the film formation material ejected by the evaporation source 32, the third layer containing the film formation material ejected by the evaporation source 33, and the fourth layer containing the film formation material ejected by the evaporation source 34 are formed in that order on the first electrode of the object exposed in an opening of the shadow mask, and the object is supplied to the first delivery chamber 111B.

### <Third Step>

The first delivery chamber 111B in the second mode supplies the shadow mask overlapped with the object to the first removal chamber 115, and the first removal chamber 115 in the second mode supplies the shadow mask overlapped with the object to the second connection chamber 121A of the second processing unit 120.

### <Fourth Step>

The second connection chamber 121A in the second mode supplies the shadow mask overlapped with the object to the second film formation chamber 124.

### <Fifth Step>

With use of the second film formation chamber 124, the fifth layer containing the film formation material ejected by the evaporation source 35, the sixth layer containing the film formation material ejected by the evaporation source 36, and the seventh layer containing the film formation material ejected by the evaporation source 37 are formed in that order to overlap with the fourth layer formed on the object exposed in an opening of the shadow mask, and the object is supplied to the second delivery chamber 121B.

### <Sixth Step>

The second delivery chamber 121B in the first mode supplies the object and the shadow mask to the second carrying-out chamber 123 and the second removal chamber 125, respectively.

### <Seventh Step>

The second removal chamber 125 in the first mode cleans the shadow mask and supplies the shadow mask to the first connection chamber 111A of the first processing unit 110.

### <Eighth Step>

The second carrying-out chamber 123 supplies the object to the second conductive film formation chamber 126.

### <Ninth Step>

With use of the second conductive film formation chamber 126, a second electrode is formed to overlap with the seventh layer, and the object is supplied to the second sealing chamber 127 from the second conductive film formation chamber 126.

### <Tenth Step>

With the second sealing chamber 127, the multilayer film in which the first layer, the second layer, the third layer, the fourth layer, the fifth layer, the sixth layer, the seventh layer, and the second electrode are stacked in that order is sealed between the object and a sealant.

With the method for manufacturing a light-emitting element exemplified in this embodiment, four layers can be formed to overlap with the first electrode provided on the object with use of the first film formation chamber 114. For example, a first hole-transport layer as the first layer, a first light-emitting layer as the second layer, a first electron-transport layer as the third layer, and an intermediate layer as the fourth layer can be formed. Further, three layers can be formed to overlap with the fourth layer with use of the second film formation chamber 124. For example, a second hole-transport layer as the fifth layer, a second light-emitting layer as the sixth layer, and a second electron-transport layer as the seventh layer can be formed. Then, the second delivery chamber 121B in the first mode can supply the object to the second carrying-out chamber 123.

Further, the second electrode can be formed to overlap with the seventh layer with use of the second conductive film formation chamber 126 connected to the second carrying-out chamber 123, whereby the light-emitting element is manufactured, and the light-emitting element can be sealed between the object and the sealant with use of the second sealing chamber 127 connected to the second conductive film formation chamber 126.

Further, film formation materials attached to the shadow mask can be removed in the second removal chamber 125 in the first mode. Consequently, a method for manufacturing a light-emitting element in which a large number of films are continuously stacked can be provided.

Note that this embodiment can be combined with any of the other embodiments and example in this specification as appropriate.

### Embodiment 9

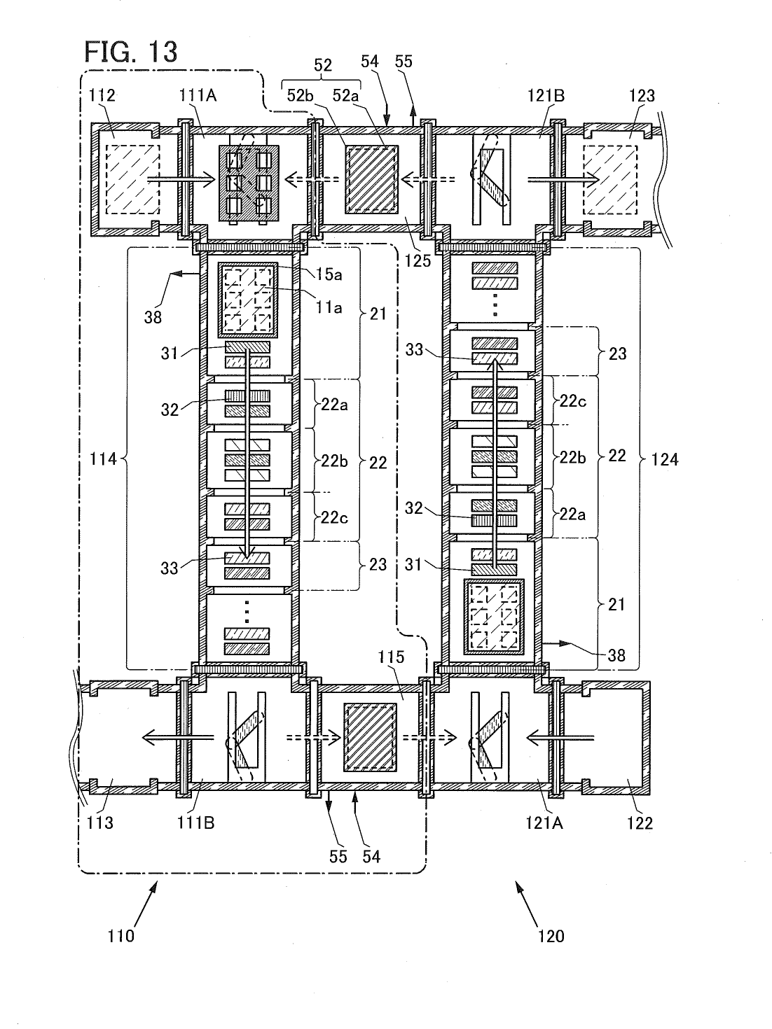

In this embodiment, a method for manufacturing a light-emitting element using the film formation apparatus of one embodiment of the present invention described in Embodiment 5 will be described with reference to FIG. 11B and FIG. 13.

Specifically, a method is described in which, with use of a film formation apparatus including two processing units, film formation is concurrently performed in film formation chambers provided in the two processing units, whereby light-emitting elements with a structure exemplified by Structure Example 1 of the light-emitting element in Embodiment 10 are manufactured.

### <Structure of Film Formation Apparatus>

First, a structure of a film formation apparatus 100F which can be used for manufacture of the light-emitting element exemplified in this embodiment is described with reference to FIG. 11B.

FIG. 11B illustrates the film formation apparatus 100F of one embodiment of the present invention. Similarly to the film formation apparatus described in Embodiment 5, the film formation apparatus 100F includes the first processing unit 110 and the second processing unit 120.

The first processing unit 110 includes the first connection chamber 111A, the first carrying-in chamber 112 which supplies an object to the first connection chamber 111A, the first film formation chamber 114 with one opening connected to the first connection chamber 111A, the first delivery chamber 111B to which the other opening of the first film formation chamber 114 is connected, the first carrying-out chamber 113 which withdraws the object from the first delivery chamber 111B, and the first removal chamber 115 with one opening connected to the first delivery chamber 111B.

The first processing unit 110 also includes a first conductive film formation chamber 116 connected to the first carrying-out chamber 113, a first sealing chamber 117 connected to the first conductive film formation chamber 116, and a first extraction chamber 118 connected to the first sealing chamber 117. Note that the first extraction chamber 118 is for taking out the manufactured light-emitting element from the film formation apparatus.

Further, the first processing unit 110 includes the first film formation chamber 114 in which the evaporation source 31 containing a material for forming a first layer, the evaporation source 32 containing a material for forming a second layer, and the evaporation source 33 containing a material for forming a third layer are placed in that order from the one opening side to the other opening side.

The second processing unit 120 includes the second connection chamber 121A, the second carrying-in chamber 122 which supplies an object to the second connection chamber 121A, the second film formation chamber 124 with one opening connected to the second connection chamber 121A, the second delivery chamber 121B to which the other opening of the second film formation chamber 124 is connected, the second carrying-out chamber 123 which withdraws the object from the second delivery chamber 121B, and the second removal chamber 125 with one opening connected to the second delivery chamber 121B.

The second processing unit 120 also includes the second conductive film formation chamber 126 connected to the second carrying-out chamber 123, the second sealing chamber 127 connected to the second conductive film formation chamber 126, and the second extraction chamber 128 connected to the second sealing chamber 127. Note that the second extraction chamber 128 is for taking out the manufactured light-emitting element from the film formation apparatus.

Further, the second processing unit 120 includes the second film formation chamber 124 in which the evaporation source 31 containing a material for forming a first layer, the evaporation source 32 containing a material for forming a second layer, and the evaporation source 33 containing a material for forming a third layer are placed in that order from the one opening side to the other opening side.

Note that the first layer has one of a hole-transport property and an electron-transport property, and the third layer has the other of a hole-transport property and an electron-transport property. The second layer contains a light-emitting organic compound.

A specific structure of the film formation apparatus 100F exemplified in this embodiment is described below with reference to FIG. 13. FIG. 13 is a top view of part of the first processing unit 110 and part of the second processing unit 120, which is used for describing details of part of the film formation apparatus 100F.

### <<First Film Formation Chamber and Second Film Formation Chamber>>

In both the first film formation chamber 114 and the second film formation chamber 124, the evaporation source 31 containing a material for forming the first layer, the evaporation source 32 containing a material for forming the second layer, and the evaporation source 33 containing a material for forming the third layer are placed in that order from the one opening side to the other opening side.

Note that the first film formation chamber 114 and the second film formation chamber 124 are each divided into the film formation region 21, the film formation region 22, and the film formation region 23. The film formation region 22 is divided into the film formation region 22a, the film formation region 22b, and the film formation region 22c. In each film formation region, a film formation material ejected by an evaporation source provided in that region is deposited on an object. A partition is provided between adjacent film formation regions so that a film formation material ejected by an evaporation source provided in one film formation region is not deposited on the object in the other film formation region.

Further, by using different materials for a plurality of evaporation sources provided in one film formation region, a mixed layer including those materials can be formed.

### <<Example of Combination of Film Formation Materials>>

With the method for manufacturing a light-emitting element exemplified in this embodiment, light-emitting elements can be concurrently manufactured with use of a film formation apparatus including two processing units. Thus, the method for manufacturing a light-emitting element exemplified in this embodiment is favorably used for manufacture of light-emitting elements with a structure exemplified by Structure Example 1 of the light-emitting element in Embodiment 10.

For example, a hole-transport layer as the first layer, a light-emitting layer as the second layer, and an electron-transport layer as the third layer can be continuously formed to be stacked over a first electrode provided on the object. Further, a second electrode can be stacked over the third layer.

It is also possible to form a stack in which a layer emitting blue light, a layer emitting green light, and a layer emitting red light are provided in that order from the first layer side as the light-emitting layer and use the first electrode as an anode and the second electrode as a cathode. With such a structure, a light-emitting element which includes a small number of layers and thus can be easily manufactured and which efficiently emits white light can be provided.

### <Method for Manufacturing Light-Emitting Elements>

A method for manufacturing light-emitting elements using the film formation apparatus 100F will be described below with reference to FIG. 11B.

### <First Step>

A first object supplied from the first carrying-in chamber 112 is supplied to the first film formation chamber 114, being overlapped with a first shadow mask supplied through the other opening of the second removal chamber 125.

Further, a second object supplied from the second carrying-in chamber 122 is supplied to the second film formation chamber 124, being overlapped with a second shadow mask supplied through the other opening of the first removal chamber 115.

### <Second Step>

With the first film formation chamber 114, the first layer containing the film formation material ejected by the evaporation source 31, the second layer containing the film formation material ejected by the evaporation source 32, and the third layer containing the film formation material ejected by the evaporation source 33 are formed in that order on the first object exposed in an opening of the first shadow mask, and the first object is supplied to the first delivery chamber 111B.

Further, with the second film formation chamber 124, the first layer containing the film formation material ejected by the evaporation source 31, the second, layer containing the film formation material ejected by the evaporation source 32, and the third layer containing the film formation material ejected by the evaporation source 33 are formed in that order on the second object exposed in an opening of the second shadow mask, and the second object is supplied to the second delivery chamber 121B.

### <Third Step>

The first delivery chamber 111B in the first mode supplies the first object and the first shadow mask to the first, carrying-out chamber 113 and the first removal chamber 115, respectively.

Further, the second delivery chamber 121B in the first mode supplies the second object and the second shadow mask to the second carrying-out chamber 123 and the second removal chamber 125, respectively.

### <Fourth Step>

The first removal chamber 115 in the first mode cleans the first shadow mask and supplies the first shadow mask to the second connection chamber 121A of the second processing unit 120.

Further, the second removal chamber 125 in the first mode cleans the second shadow mask and supplies the second shadow mask to the first connection chamber 111A of the first processing unit 110.

### <Fifth Step>

The first carrying-out chamber 113 supplies the first object to the first conductive film formation chamber 116, and the second carrying-out chamber 123 supplies the second object to the second conductive film formation chamber 126.

### <Sixth Step>

With the first conductive film formation chamber 116, a second electrode is formed to overlap with the third layer of the first object, and the first object is supplied to the first sealing chamber 117 from the first conductive film formation chamber 116.

Further, with the second conductive film formation chamber 126, a second electrode is formed to overlap with the third layer of the second object, and the second object is supplied to the second sealing chamber 127 from the second conductive film formation chamber 126.

### <Seventh Step>

With the first sealing chamber 117, the multilayer film in which the first layer, the second layer, the third layer, and the second electrode are stacked in that order is sealed between the first object and a sealant.

With the second sealing chamber 127, the multilayer film in which the first layer, the second layer, the third layer, and the second electrode are stacked in that order is sealed between the second object and a sealant.

With the method for manufacturing light-emitting elements exemplified in this embodiment, three layers can be formed to overlap with a first electrode provided on an object with use of the first film formation chamber 114, and concurrently therewith, three layers can be formed to overlap with a first electrode provided on an object with use of the second film formation chamber 124. For example, hole-transport layers as the first layers, light-emitting layers as the second layers, and electron-transport layers as the third layers can be formed. Then, the delivery chambers (the first delivery chamber 111B and the second delivery chamber 121B) in the first mode can supply the objects to the respective carrying-out chambers (the first carrying-out chamber 113 and the second carrying-out chamber 123) connected to the delivery chambers.

Further, the second electrode can be formed to overlap with the third layer with use of each of the conductive film formation chambers connected to the carrying-out chambers, whereby the light-emitting elements are manufactured, and the light-emitting element can be sealed between the object and the sealant with use of each of the sealing chambers connected to the conductive film formation chambers.

Further, film formation materials attached to the shadow masks can be removed in the removal chambers (the first removal chamber 115 and the second removal chamber 125) in the first mode. Consequently, it is possible to provide a method for manufacturing a light-emitting element in which films are continuously stacked while a decrease in the rate of operation of film formation chambers which are provided for continuous stacking of a large number of films is suppressed.

Note that this embodiment can be combined with any of the other embodiments and example in this specification as appropriate.

### Embodiment 10

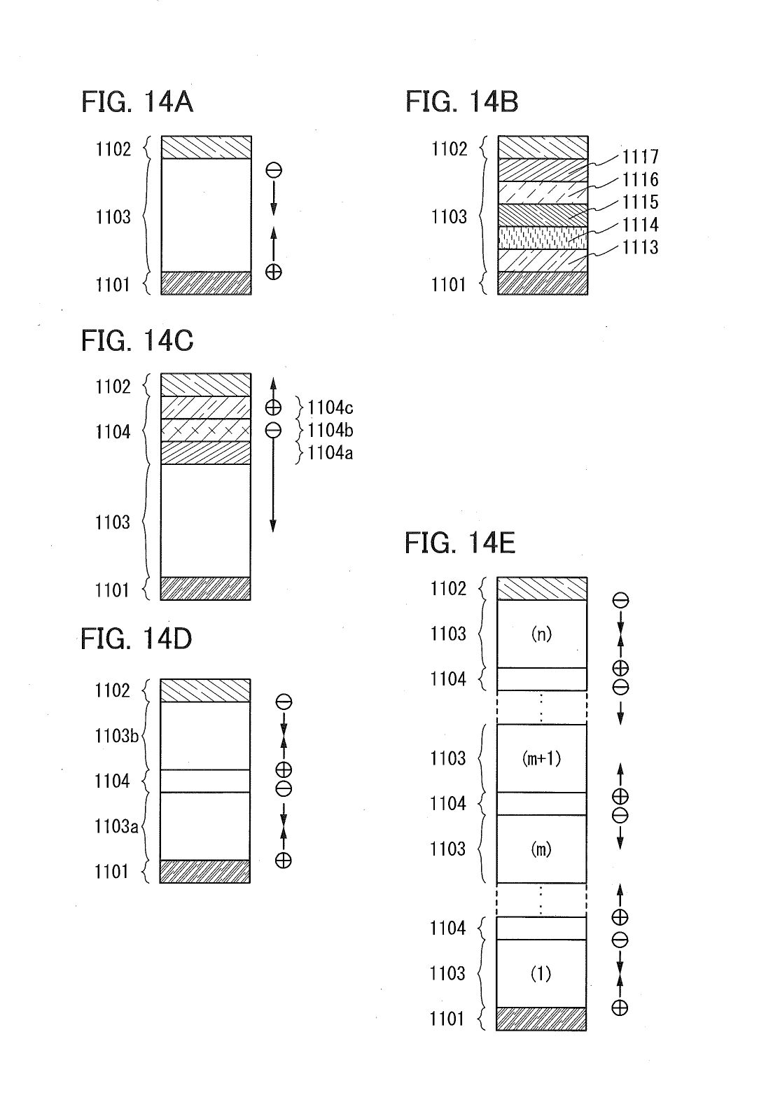

This embodiment describes structures of a light-emitting element which can be formed using a film formation apparatus and a method for forming a film, a method for forming a multilayer film, or a method for manufacturing a light-emitting element of one embodiment of the present invention, with reference to FIGS. 14A to 14E.

For example, with the method for manufacturing a light-emitting element described in Embodiment 8 or Embodiment 9, a light-emitting element which is exemplified below can be formed.

The light-emitting element exemplified in this embodiment includes a first electrode, a second electrode, and a layer containing a light-emitting organic compound (hereinafter referred to as an EL layer) between the first and second electrodes. One of the first electrode and the second electrode serves as an anode, and the other serves as a cathode. The EL layer is provided between the first and second electrodes, and a structure of the EL layer may be selected as appropriate in accordance with materials of the first and second electrodes. Examples of the structure of the light-emitting element are described below; it is needless to say that the structure of the light-emitting element is not limited to these examples.

### Structure Example 1 of Light-Emitting Element

An example of the structure of the light-emitting element is illustrated in FIG. 14A. In the light-emitting element illustrated in FIG. 14A, an EL layer is provided between an anode 1101 and a cathode 1102.

Upon application of a voltage higher than the threshold voltage of the light-emitting element between the anode 1101 and the cathode 1102, holes are injected to the EL layer from the anode 1101 side and electrons are injected to the EL layer from the cathode 1102 side. The injected electrons and holes are recombined in the EL layer, so that a light-emitting substance contained in the EL layer emits light.

In this specification, a layer or a stack which includes one region where electrons and holes injected from both ends are recombined is referred to as a light-emitting unit. Therefore, Structure Example 1 of the light-emitting element includes one light-emitting unit.

A light-emitting unit 1103 includes at least one light-emitting layer containing a light-emitting substance, and may have a structure in which the light-emitting layer and a layer other than the light-emitting layer are stacked. Examples of the layer other than the light-emitting layer include layers containing a substance having a high hole-injection property, a substance having a high hole-transport property, a substance having a poor hole-transport property (a substance which blocks holes), a substance having a high electron-transport property, a substance having a high electron-injection property, and a substance having a bipolar property (a substance having high electron-and hole-transport properties).

An example of a specific structure of the light-emitting unit 1103 is illustrated in FIG. 14B. In the light-emitting unit 1103 illustrated in FIG. 14B, a hole-injection layer 1113, a hole-transport layer 1114, a light-emitting layer 1115, an electron-transport layer 1116, and an electron-injection layer 1117 are stacked in that order from the anode 1101 side.

### Structure Example 2 of Light-Emitting Element

Another example of the structure of the light-emitting element is illustrated in FIG. 14C. In the light-emitting element illustrated in FIG. 14C, an EL layer including the light-emitting unit 1103 is provided between the anode 1101 and the cathode 1102. Further, an intermediate layer 1104 is provided between the cathode 1102 and the light-emitting unit 1103. Note that a structure similar to that of the light-emitting unit included in Structure Example 1 of the light-emitting element, which is described above, can be applied to the light-emitting unit 1103 in Structure Example 2 of the light-emitting element and that the description of Structure Example 1 of the light-emitting element can be referred to for the details.

The intermediate layer 1104 includes at least a charge generation region, and may have a structure in which the charge generation region and a layer other than the charge generation region are stacked. For example, a structure can be employed in which a first charge generation region 1104c, an electron-relay layer 1104b, and an electron-injection buffer 1104a are stacked in that order from the cathode 1102 side.

The behavior of electrons and holes in the intermediate layer 1104 is described. Upon application of a voltage higher than the threshold voltage of the light-emitting element between the anode 1101 and the cathode 1102, holes and electrons are generated in the first charge generation region 1104c, and the holes are transferred to the cathode 1102 and the electrons are transferred to the electron-relay layer 1104b. The electron-relay layer 1104b has a high electron-transport property and immediately transfers the electrons generated in the first charge generation region 1104c to the electron-injection buffer 1104a. The electron-injection buffer 1104a can reduce a barrier against electron injection into the light-emitting unit 1103, so that the efficiency of the electron injection into the light-emitting unit 1103 can be improved. Thus, the electrons generated in the first charge generation region 1104c are injected into the LUMO level of the light-emitting unit 1103 through the electron-relay layer 1104b and the electron-injection buffer 1104a.

In addition, the electron-relay layer 1104b can prevent interaction in which, for example, a substance included in the first charge generation region 1104c and a substance included in the electron-injection buffer 1104a react with each other at the interface thereof to impair the functions of the first charge generation region 1104c and the electron-injection buffer 1104a.

The range of choices of materials that can be used for the cathode in Structure Example 2 of the light-emitting element is wider than that of materials that can be used for the cathode in Structure Example 1. This is because a material having a relatively high work function can be used for the cathode in Structure Example 2 as long as the cathode can receive holes generated by the intermediate layer.

### Structure Example 3 of Light-Emitting Element

Another example of the structure of the light-emitting element is illustrated in FIG. 14D. In the light-emitting element illustrated in FIG. 14D, an EL layer including two light-emitting units is provided between the anode 1101 and the cathode 1102. Furthermore, the intermediate layer 1104 is provided between a first light-emitting unit 1103a and a second light-emitting unit 1103b.

Note that the number of the light-emitting units provided between the anode and the cathode is not limited to two. A light-emitting element illustrated in FIG. 14E has what is called a tandem structure, that is, a structure in which a plurality of light-emitting units 1103 are stacked. Note that in the case where n (n is a natural number greater than or equal to 2) light-emitting units 1103 are provided between the anode and the cathode, for example, the intermediate layer 1104 is provided between an m-th (m is a natural number greater than or equal to 1 and less than or equal to n−1) light-emitting unit and an (m+1)-th light-emitting unit.

Note that a structure similar to that in Structure Example 1 of the light-emitting element can be applied to the light-emitting unit 1103 in Structure Example 3 of the light-emitting element; a structure similar to that in Structure Example 2 of the light-emitting element can be applied to the intermediate layer 1104 in Structure Example 3 of the light-emitting element. Thus, for the details, the description of the Structure Example 1 of the light-emitting element or the Structure Example 2 of the light-emitting element can be referred to.

The behavior of electrons and holes in the intermediate layer 1104 provided between the light-emitting units is described. Upon application of a voltage higher than the threshold voltage of the light-emitting element between the anode 1101 and the cathode 1102, holes and electrons are generated in the intermediate layer 1104, and the holes are transferred to the light-emitting unit provided on the cathode 1102 side and the electrons are transferred to the light-emitting unit provided on the anode 1101 side. The holes injected into the light-emitting unit provided on the cathode side are recombined with the electrons injected from the cathode side, so that a light-emitting substance contained in the light-emitting unit emits light. The electrons injected into the light-emitting unit provided on the anode side are recombined with the holes injected from the anode side, so that a light-emitting substance contained in the light-emitting unit emits light. Thus, the holes and electrons generated in the intermediate layer 1104 cause light emission in the respective light-emitting units.

Note that in the case where a structure which is the same as the intermediate layer is formed between the light-emitting units by providing the light-emitting units in contact with each other, the light-emitting units can be formed to be in contact with each other. Specifically, when one surface of the light-emitting unit is provided with a charge generation region, the charge generation region functions as a first charge generation region of the intermediate layer; thus, the light-emitting units can be provided in contact with each other.

The Structure Examples 1 to 3 of the light-emitting element can be implemented in combination. For example, an intermediate layer may be provided between the cathode and the light-emitting unit in Structure Example 3 of the light-emitting element.

Further, a plurality of light-emitting substances which emit light of different colors can be used, whereby, for example, white light emission can also be obtained by expanding the width of the emission spectrum. In order to obtain white light emission, for example, a structure may be employed in which at least two layers containing light-emitting substances are provided so that light of complementary colors is emitted.

Specific examples of complementary colors include “blue and yellow” and “blue-green and red”.

Further, in order to obtain white light emission with an excellent color rendering property, an emission spectrum is preferred to spread through the entire visible light region. For example, a light-emitting element may include layers emitting light of blue, green, and red.

Note that this embodiment can be combined with any of the other embodiments and example in this specification as appropriate.

### Embodiment 11

This embodiment describes a structure of a light-emitting element which can be formed using a film formation apparatus and a method for manufacturing a light-emitting element of one embodiment of the present invention.

For example, with the method for manufacturing a light-emitting element described in Embodiment 9, a light-emitting element which is exemplified below can be formed.

Specifically, a structure of a multicolor light-emitting element in which a first phosphorescent compound and a second phosphorescent compound emitting light with a wavelength longer than that of light emitted from the first phosphorescent compound are used, which enables efficient light emission, is described.

As a technique for obtaining a multicolor light-emitting element, what is called a tandem structure (Structure Example 3 of the light-emitting element described in Embodiment 10), in which light-emitting units having different emission colors are stacked in series, can be given. For example, a first light-emitting unit emitting blue light, a second light-emitting unit emitting green light, and a third light-emitting unit emitting red light are stacked in series and made to emit light at the same time, whereby polychromatic light (in this case, white light) can be easily obtained. The element structure can be relatively easily designed and controlled because the blue light-emitting unit, the green light-emitting unit, and the red light-emitting unit can be independently optimized. However, the stacking of three light-emitting units is accompanied by an increase in the number of layers and makes the fabrication complicated. In addition, when a problem occurs in electrical contact at connection portions between the light-emitting units (what is called intermediate layers), an increase in drive voltage, i.e., power loss might be caused.

In contrast, in the light-emitting element described below, between a pair of electrodes are stacked a first light-emitting layer in which the first phosphorescent compound is dispersed in a first host material and a second light-emitting layer in which the second phosphorescent compound emitting light with a wavelength longer than that of light emitted from the first phosphorescent compound is dispersed in a second host material. Here, unlike the case of a tandem structure, the first and second light-emitting layers are provided in contact with each other; thus, the number of stacked layers can be significantly reduced as compared with a tandem structure. In this case, the phosphorescent compounds (the first and second phosphorescent compounds) are dispersed in the host materials so that the phosphorescent compounds are separated from each other by the host materials.

In such a structure, between the phosphorescent compounds, energy transfer by electron exchange interaction (what is called Dexter mechanism) is suppressed. Thus, a phenomenon in which the second phosphorescent compound emitting light with the longest wavelength mainly emits light can be suppressed. Note that the second phosphorescent compound mainly emits light in the case where an exciton is directly generated in the second light-emitting layer; therefore, it is preferable that a recombination region of carriers be in the first light-emitting layer (i.e., the first phosphorescent compound be mainly excited).

Note that if energy transfer from the first phosphorescent compound is completely suppressed, in turn, light emission from the second phosphorescent compound cannot be obtained. Thus, in this structure, element design is performed such that excitation energy of the first phosphorescent compound is partly transferred to the second phosphorescent compound. Such energy transfer between separated molecules becomes possible by utilizing dipole-dipole interaction (Förster mechanism).

Here, Förster mechanism is described. The molecule which donates excitation energy and the molecule which receives excitation energy are hereinafter referred to as an energy donor and an energy acceptor, respectively. That is, in one embodiment of the present invention, both the energy donor and the energy acceptor are phosphorescent compounds and are separated from each other by the host materials.

In Förster mechanism, direct intermolecular contact is not necessary for energy transfer. Through a resonant phenomenon of dipolar oscillation between an energy donor and an energy acceptor, energy transfer occurs. The resonant phenomenon of dipolar oscillation causes the energy donor to donate energy to the energy acceptor; thus, the energy donor in an excited state relaxes to a ground state and the energy acceptor in a ground state is excited. The rate constant k_{F} of energy transfer by Förster mechanism is expressed by a formula (1).

$$\begin{matrix}[ FORMULA 1 ] & \\ {k}_{F} = \frac{9000 {c}^{4} {K}^{2} φln10}{128 {π}^{5} {n}^{4} {NτR}^{6}} \int \frac{F ( v ) ɛ ( v )}{{v}^{4}} d v & ( 1 )\end{matrix}$$

In the formula (1), v denotes a frequency, F(v) denotes a normalized emission spectrum of an energy donor (a fluorescence spectrum in energy transfer from a singlet excited state, and a phosphorescence spectrum in energy transfer from a triplet excited state), ε(v) denotes a molar absorption coefficient of an energy acceptor, N denotes Avogadro's number, n denotes a refractive index of a medium, R denotes an intermolecular distance between the energy donor and the energy acceptor, τ denotes a measured lifetime of an excited state (fluorescence lifetime or phosphorescence lifetime), c denotes the speed of light, φ denotes a luminescence quantum yield (a fluorescence quantum yield in energy transfer from a singlet excited state, and a phosphorescence quantum yield in energy transfer from a triplet excited state), and K² denotes a coefficient (0 to 4) of orientation of a transition dipole moment between the energy donor and the energy acceptor. Note that K²=⅔ in random orientation.

As the formula (1) suggests, the following can be given as necessary conditions for energy transfer by Förster mechanism (Förster energy transfer): 1. the energy donor and the energy acceptor are not too far apart from each other (which relates to the distance R); 2. the energy donor emits light (which relates to the luminescence quantum yield φ); and 3. an emission spectrum of the energy donor overlaps with an absorption spectrum of the energy acceptor (which relates to the integral term).

Here, as described above, the phosphorescent compounds (the first and second phosphorescent compounds) are dispersed in the respective host materials and separated from each other by the host materials; thus, the distance R is at least one molecule length or longer (i.e., 1 nm or more). Therefore, the excitation energy generated in the first phosphorescent compound is not entirely transferred to the second phosphorescent compound by Förster mechanism. Meanwhile, Förster energy transfer to the distance R can occur when R is less than or equal to approximately 10 nm to 20 nm. So that the distance R at least longer than or equal to one molecule length is secured between the first and second phosphorescent compounds, the mass of the phosphorescent compound dispersed in the host material is preferably set to less than or equal to a certain mass. On the basis of this, the concentration of the phosphorescent compound in the light-emitting layer is 10 wt % or less. When the concentration of the phosphorescent compound is too low, favorable characteristics are difficult to be achieved; thus, the concentration of the phosphorescent compound in this element structure is preferably greater than or equal to 0.1 wt % and less than or equal to 10 wt %. Specifically, it is more preferable that the first phosphorescent compound be contained in the first light-emitting layer at a concentration of greater than or equal to 0.1 wt % and less than or equal to 5 wt %.

In the light-emitting element having the structure in which the first phosphorescent compound and the second phosphorescent compound emitting light with a wavelength longer than that of light emitted from the first phosphorescent compound are used, first, a singlet excited state formed in the first phosphorescent compound (Sₐ) is converted into a triplet excited state (Tₐ) by intersystem crossing. In other words, an exciton in the first light-emitting layer is basically brought into Tₐ.

Then, the energy of the exciton in the Tₐ state, some of which is converted into light emission, can be partly transferred to the triplet excited state of the second phosphorescent compound (T_{b}) by Förster mechanism. This results from the fact that the first phosphorescent compound has a light-emitting property (has a high phosphorescence quantum yield φ) and that direct absorption, which corresponds to electron transition from a singlet ground state to a triplet excited state, is observed in the second phosphorescent compound (an absorption spectrum of a triplet excited state exists). When these conditions are fulfilled, triplet-triplet Förster energy transfer from Tₐ to T_{b} is possible.

Note that to make the above Förster energy transfer efficiently occur between the phosphorescent compounds serving as the dopants, not to the host materials, it is preferable that absorption spectra of the first and second host materials not be in the emission region of the first phosphorescent compound. In this manner, energy is transferred directly between dopants without being transferred through the host material (specifically, the second host material), so that formation of an extra path of energy transfer is suppressed and high emission efficiency can be achieved.

Further, the first host material preferably has a triplet excitation energy higher than that of the first phosphorescent compound so as not to quench the first phosphorescent compound.

Here, what is more important in this structure is that the materials and the element structure are determined in consideration of the above energy transfer.

As for selection of materials, specifically, materials are selected such that the integral term of the formula (1) is made large, i.e., an emission spectrum F(v) of the energy donor is made to properly overlap with the molar absorption coefficient ε(v) of the energy acceptor.

In general, it is thought that the emission spectrum F(v) of the energy donor simply needs to overlap with a wavelength range in which the molar absorption coefficient ε(v) of the energy acceptor is large (i.e., the product of F(v) and ε(v) simply needs to be large). However, this does not necessarily apply to Förster mechanism because the integral term in the formula (1) is inversely proportional to the frequency v raised to the fourth power to have wavelength dependence.

For easier understanding, here, the formula (1) is transformed. Since v=c/λ, where λ denotes a wavelength of light, the formula (1) can be transformed into a formula (2).

$$\begin{matrix}[ FORMULA 2 ] & \\ {k}_{F} = \frac{9000 {K}^{2} φln10}{128 {π}^{5} {n}^{4} {NτR}^{6}} \int F ( λ ) ɛ ( λ ) {λ}^{4} d λ & ( 2 )\end{matrix}$$

In other words, it can be found that the longer the wavelength λ is, the larger the integral term is. In simpler terms, it is indicated that energy transfer occurs more easily on a longer wavelength side. That is, this is not so simple that F(λ) needs to overlap with the wavelength range in which the molar absorption coefficient ε(λ) is large. It is necessary that F(λ) overlap with a range in which ε(λ)λ⁴ is large.

Thus, in the light-emitting element of one embodiment of the present invention, in order to increase efficiency of energy transfer from the first phosphorescent compound, a phosphorescent compound allowing a crest having the maximum value of an emission spectrum of the first phosphorescent compound to overlap with a crest having the longest-wavelength-side local maximum value of the function ε(λ)λ⁴ of the second phosphorescent compound is used as the second phosphorescent compound.

In a light-emitting element having the above-described structure, high emission efficiency can be achieved and the phosphorescent compounds can provide light emissions in a good balance.

From the above, it is preferable that absorption spectrum of the second phosphorescent compound shows, on the longest wavelength side, direct absorption which corresponds to electron transition from a singlet ground state to a triplet excited state (e.g., triplet MLCT absorption). Such a structure leads to high efficiency of triplet-triplet energy transfer.

To obtain the above-described recombination region, in the case where the first light-emitting layer is positioned on the anode side, at least the second light-emitting layer preferably has an electron-transport property, and both the first light-emitting layer and the second light-emitting layer may have an electron-transport property. In the case where the first light-emitting layer is positioned on the cathode side, at least the second light-emitting layer preferably has a hole-transport property, and both the first light-emitting layer and the second light-emitting layer may have a hole-transport property.

Note that this embodiment can be combined with any of the other embodiments and example in this specification as appropriate.

### Embodiment 12

In this embodiment, examples of a structure of a display panel which can be manufactured using a film formation apparatus of one embodiment of the present invention will be described.

### <Structure of Display Panel>

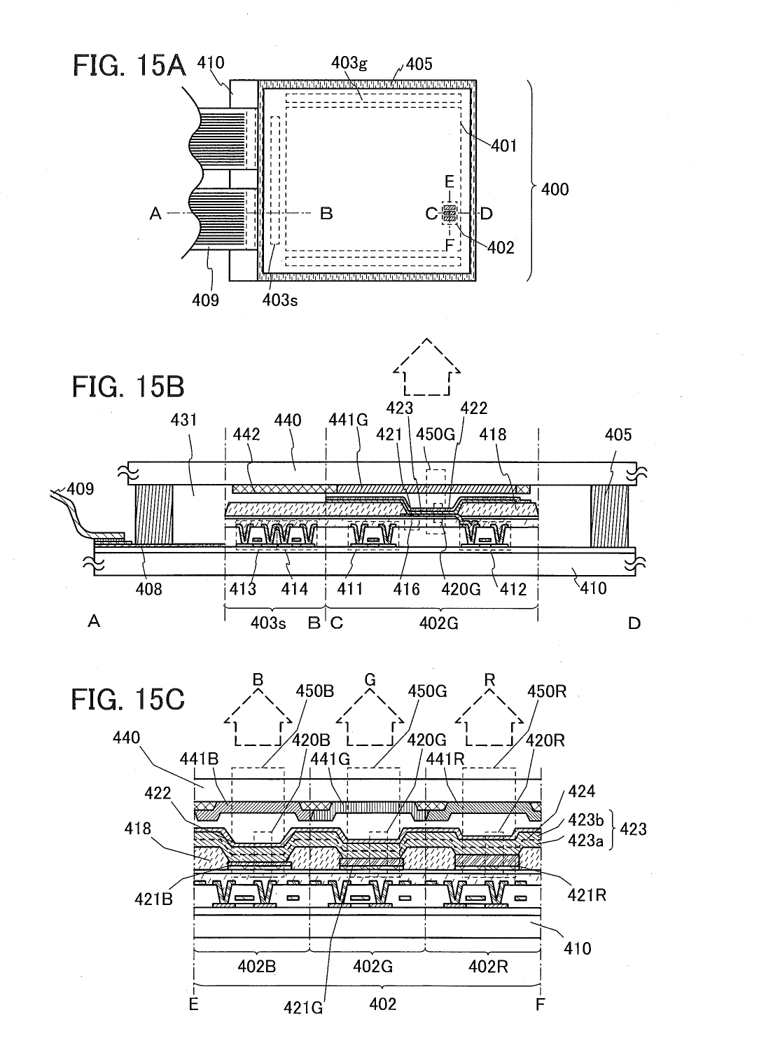

The structure of the display panel which is exemplified in this embodiment is described with reference to FIGS. 15A to 15C. FIG. 15A is a top view of a structure of a display panel which is exemplified in this embodiment, FIG. 15B is a side view of a structure including a cross section taken along line A-B and C-D in FIG. 15A, and FIG. 15C is a side view of a structure of a pixel including a cross section taken along line E-F in FIG. 15A.

A display panel 400 exemplified in this embodiment includes a display portion 401 over a first substrate 410. The display portion 401 includes a plurality of pixels 402. The pixel 402 includes a plurality of sub-pixels (e.g., three sub-pixels) (FIG. 15A). Over the first substrate 410, in addition to the display portion 401, a source side driver circuit portion 403s and a gate side driver circuit portion 403g which drive the display portion 401 are provided. Note that the driver circuit portions can be provided not over the first substrate 410 but externally.

The display panel 400 includes an external input terminal and receives a video signal, a clock signal, a start signal, a reset signal, and the like from an FPC (flexible printed circuit) 409. Note that only the FPC is illustrated here; however, the FPC may be provided with a printed wiring board (PWB). The display panel in this specification includes not only a main body of the display panel but one with an FPC or a PWB attached thereto.

A sealant 405 bonds the first substrate 410 and a second substrate 440. The display portion 401 is sealed in a space 431 formed between the substrates (see FIG. 15B).

The structure including the cross-section of the display panel 400 is described with reference to FIG. 15B. The display panel 400 includes the source side driver circuit portion 403s, a sub-pixel 402G included in the pixel 402, and a lead wiring 408. Note that the display portion 401 of the display panel 400 exemplified in this embodiment emits light in the direction denoted by the arrow in the drawing, thereby displaying images.

A CMOS circuit, which is a combination of an n-channel transistor 413 and a p-channel transistor 414, is formed for the source side driver circuit portion 403s. Note that the driver circuit is not limited to this structure and may be various circuits, such as a CMOS circuit, a PMOS circuit, or an NMOS circuit.

The lead wiring 408 transmits a signal inputted from an external input terminal to the source side driver circuit portion 403s and the gate side driver circuit portion 403g.

The sub-pixel 402G includes a switching transistor 411, a current control transistor 412, and a light-emitting module 450G. Note that an insulating layer 416 and a partition 418 are formed over the transistor 411 and the like. The light-emitting module 450G includes a reflective film, a semi-transmissive and semi-reflective film, a light-emitting element 420G between the reflective film and the semi-transmissive and semi-reflective film, and a color filter 441G provided on the semi-transmissive and semi-reflective film side through which light emitted from the light-emitting element 420G is extracted. In the light-emitting module 450G exemplified in this embodiment, a first electrode 421G and a second electrode 422 of the light-emitting element 420G also serve as the reflective film and the semi-transmissive and semi-reflective film, respectively. Note that a direction of an image displayed in the display portion 401 is determined in accordance with a direction in which light emitted from the light-emitting element 420G is extracted.

In addition, a light-blocking film 442 is formed so as to surround the color filter 441G. The light-blocking film 442 prevents a phenomenon in which the display panel 400 reflects outside light and has an effect of increasing the contrast of images displayed in the display portion 401. Note that the color filter 441G and the light-blocking film 442 are formed on the second substrate 440.

The insulating layer 416 is a layer having insulating properties for planarizing a step due to the structure of the transistor 411 and the like or for suppressing impurity dispersion to the transistor 411 and the like. The insulating layer 416 can be a single layer or a stacked layer. The partition 418 is an insulating layer having an opening; the light-emitting element 420G is formed in the opening of the partition 418.

The light-emitting element 420G includes the first electrode 421G, the second electrode 422, and a layer 423 containing a light-emitting organic compound.

### <Structure of Transistor>

Top-gate transistors are used in the display panel 400 exemplified in FIG. 15A. Various types of transistors can be used for the source side driver circuit portion 403s, the gate side driver circuit portion 403g, and the sup-pixels. Note that various semiconductors can be used for a region where channels of these transistors are formed. Specifically, as well as amorphous silicon, polysilicon, or single crystal silicon, an oxide semiconductor or the like can be used.

When a single crystal semiconductor is used for a region where a channel of a transistor is formed, the size of the transistor can be reduced, which results in higher resolution pixels in a display portion.

As a single crystal semiconductor used for forming a semiconductor layer, a semiconductor substrate, typical examples of which include a single crystal semiconductor substrate formed using elements belonging to Group 14, such as a single crystal silicon substrate, a single crystal germanium substrate, or a single crystal silicon germanium substrate, and a compound semiconductor substrate (e.g., a SiC substrate and a GaN substrate), can be used. Preferred one is a silicon on insulator (SOI) substrate in which a single crystal semiconductor layer is provided on an insulating surface.

An SOI substrate can be fabricated by the following method: after oxygen ions are implanted in a mirror-polished wafer, the wafer is heated at high temperatures to form an oxidized layer at a predetermined depth from a surface of the wafer and eliminate defects generated in a surface layer. Alternatively, an SOI substrate can be fabricated by the method in which the semiconductor substrate is separated by utilizing the growth of microvoids formed by hydrogen ion irradiation (this growth is caused by heat treatment). Alternatively, an SOI substrate can be fabricated by the method in which a single crystal semiconductor layer is formed on an insulating surface by crystal growth.

In this embodiment, ions are added through one surface of a single crystal semiconductor substrate, an embrittlement layer is formed at a predetermined depth from the one surface of the single crystal semiconductor substrate, and an insulating layer is formed over the one surface of the single crystal semiconductor substrate or over the first substrate 410. Next, heat treatment is performed in the state in which the single crystal semiconductor substrate provided with the embrittlement layer and the first substrate 410 are bonded to each other with the insulating layer interposed therebetween, so that a crack is generated in the embrittlement layer to separate the single crystal semiconductor substrate along the embrittlement layer. Thus, a single crystal semiconductor layer, which is separated from the single crystal semiconductor substrate, is formed as a semiconductor layer over the first substrate 410. Note that a glass substrate can be used as the first substrate 410.

Further, regions electrically insulated from each other may be formed in the semiconductor substrate so that the transistors 411 and 412 may be formed using the regions electrically insulated from each other.

When a channel formation region is formed using a single crystal semiconductor, variations in electrical characteristics, such as threshold voltage, between transistors due to bonding defects at grain boundaries can be reduced. Thus, in the panel of one embodiment of the present invention, the light-emitting elements can be operated normally without placing a circuit for compensating threshold voltage in each pixel. The number of circuit elements per pixel can therefore be reduced, increasing the flexibility in layout. Thus, a high-definition display panel can be achieved. For example, a structure in which a matrix of a plurality of pixels is included, specifically 300 or more pixels per inch (i.e., the horizontal resolution is 300 or more pixels per inch (ppi)), preferably 400 or more pixels per inch (i.e., the horizontal resolution is 400 or more ppi), can be achieved.

Moreover, a transistor whose channel formation region is formed using a single crystal semiconductor can be downsized while keeping high current drive capability. The use of the downsized transistor leads to a reduction in the area of a circuit portion that does not contribute to display, which results in an increase in the display area in the display portion and a reduction in the frame size of the display panel.

### <Structure of Pixel>

The structure of the pixel 402 included in the display portion 401 is described with reference to FIG. 15C.

The pixel 402 exemplified in this embodiment includes the sub-pixel 402G. The sub-pixel 402G includes the light-emitting element 420G; the light-emitting element 420G includes the first electrode 421G also serving as a reflective film, the second electrode 422 also serving as a semi-transmissive and semi-reflective film, a layer 423a containing a light-emitting organic compound, a layer 423b containing a light-emitting organic compound, and an intermediate layer 424. Further, the pixel 402 includes the color filter 441G on the second electrode 422 side so that the color filter 441G may overlap with the light-emitting element 420G.

In addition, the pixel 402 includes a sub-pixel 402B emitting blue light B, the sub-pixel 402G emitting green light G, and a sub-pixel 402R emitting red light R. Each sub-pixel includes a driver transistor and a light-emitting module. Each light-emitting module includes a reflective film, a semi-transmissive and semi-reflective film, and a light-emitting element between the reflective film and the semi-transmissive and semi-reflective film.

When a microresonator is formed by the reflective film and the semi-transmissive and semi-reflective film and a light-emitting element is formed therebetween, light with a specific wavelength can be efficiently extracted through the semi-transmissive and semi-reflective film. Specifically, the optical path length of the microresonator is n/2 times (n is a natural number) the wavelength of extracted light; thus, light extraction efficiency can be enhanced. The wavelength of extracted light depends on the distance between the reflective film and the semi-transmissive and semi-reflective film, and the distance can be adjusted by forming an optical adjustment layer between the films.

A conductive film having light-transmitting properties to visible light or a layer containing a light-emitting organic compound can be employed for a material that can be used for the optical adjustment layer. For example, the thickness of the optical adjustment layer may be adjusted using a charge generation region. Alternatively, a region containing a substance having a high hole-transport property and an acceptor substance is preferably used for the optical adjustment layer because an increase in driving voltage can be suppressed even when the optical adjustment layer is thick.

As the structure of the light-emitting element, the light-emitting element 420G is provided between the first electrode 421G also serving as a reflective film and the second electrode 422 also serving as a semi-transmissive and semi-reflective film. The light-emitting element 420G includes the layer 423a containing a light-emitting organic compound, the layer 423b containing a light-emitting organic compound, and the intermediate layer 424.

As for a structure example of a light-emitting element, the structure described in Embodiment 10 can be used.

The light-emitting modules exemplified in this embodiment each have a structure in which the second electrode 422 provided in the light-emitting module also serves as a semi-transmissive and semi-reflective film. Specifically, the second electrode 422 shared by the light-emitting elements 420B, 420G, and 420R also serves as a semi-transmissive and semi-reflective film of the light-emitting modules 450B, 450G, and 450R.

In addition, the first electrodes of the light-emitting elements which are provided in the respective light-emitting modules and are electrically separated from each other also serve as reflective films. Specifically, a first electrode 421B provided in the light-emitting element 420B also serves as a reflective film of the light-emitting module 450B, the first electrode 421G provided in the light-emitting element 420G also serves as a reflective film of the light-emitting module 450G, and a first electrode 421R provided in the light-emitting element 420R also serves as a reflective film of the light-emitting module 450R.

The first electrode also serving as a reflective film of a light-emitting module has a stacked-layer structure in which an optical adjustment layer is stacked over the reflective film. The optical adjustment layer is preferably formed of a conductive film having light-transmitting properties with respect to visible light, and the reflective film is preferably formed of a conductive metal film having high reflectivity with respect to visible light.

The thickness of the optical adjustment layer is adjusted in accordance with a wavelength of light extracted from a light-emitting module.

For example, the first light-emitting module 450B includes a color filter 441B which transmits blue light, the first electrode 421B also serving as a reflective film, and the second electrode 422 also serving as a semi-transmissive and semi-reflective film; the optical path length between the first electrode 421B and the second electrode 422 is adjusted to i/2 times (i is a natural number) a length greater than or equal to 400 nm and less than 500 nm.

Further, the second light-emitting module 450G includes the color filter 441G which transmits green light, a reflective film, and a semi-transmissive and semi-reflective film; the optical path length between the reflective film and the semi-transmissive and semi-reflective film is adjusted to j/2 times (j is a natural number) a length greater than or equal to 500 nm and less than 600 nm.

Further, the third light-emitting module 450R includes a color filter 441R which transmits red light, a reflective film, and a semi-transmissive and semi-reflective film; the optical path length between the reflective film and the semi-transmissive and semi-reflective film is adjusted to k/2 times (k is a natural number) a length greater than or equal to 600 nm and less than 800 nm.

In such a light-emitting module, light emitted from the light-emitting elements interfere with each other between the reflective film and the semi-transmissive and semi-reflective film, light having a specific wavelength among light having a wavelength of greater than or equal to 400 nm and less than 800 nm is strengthened, and the color filter absorbs unnecessary light.

Note that the first light-emitting module 450B, the second light-emitting module 450G, and the third light-emitting module 450R each include the layer 423a containing a light-emitting organic compound, the layer 423b containing a light-emitting organic compound, and the intermediate layer 424. In addition, one of the pair of electrodes of the light-emitting element also serves as a reflective film and the other thereof also serves as a semi-transmissive and semi-reflective film.

In the light-emitting modules with such a structure, each layer containing a light-emitting organic compound in the plurality of light-emitting modules can be formed in one process. Further, the pair of electrodes also serves as the reflective film and the semi-transmissive and semi-reflective film.

### <Structure of Partition>

The partition 418 is formed to cover end portions of the first electrodes 421B, 421G, and 421R.

The partition 418 has a curved surface with curvature at a lower end portion thereof. As a material of the partition 418, negative or positive photosensitive resin can be used.

Note that using a material absorbing visible light for the partition produces an effect of suppressing light leakage into adjacent light-emitting elements (also called cross talk).

In addition, in such a structure that images are displayed by extracting light emitted from the light-emitting module from the first substrate 410 side which is provided with a semi-transmissive and semi-reflective film, the partition formed using a material absorbing visible light absorbs outside light which is reflected by the reflective film on the first substrate 410, thereby suppressing the reflection.

### <Sealing Structure>

The display panel 400 exemplified in this embodiment has a structure in which the light-emitting element is sealed in a space enclosed by the first substrate 410, the second substrate 440, and the sealant 405.

The space can be filled with an inert gas (e.g., nitrogen or argon) or resin. An absorbent of impurity (typically, water and/or oxygen) such as a dry agent may be provided.

The sealant 405 and the second substrate 440 are desirably formed using a material which transmits impurities in the air (such as water and/or oxygen) as little as possible. An epoxy-based resin, glass frit, or the like can be used for the sealant 405.

Examples of the second substrate 440 include a glass substrate; a quartz substrate; a plastic substrate formed of polyvinyl fluoride (PVF), polyester, an acrylic resin, or the like; a substrate of fiberglass-reinforced plastics (FRP); and the like.

### Modification Example

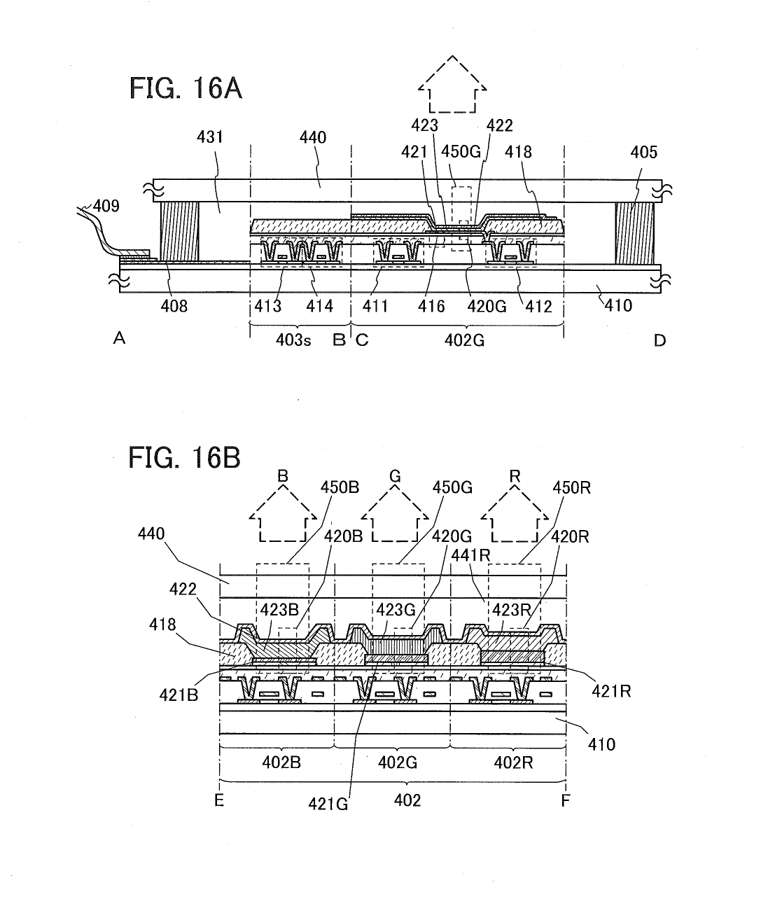

FIGS. 16A and 16B show a modification example of this embodiment. FIG. 16A is a side view of a structure including a cross section taken along line A-B and C-D in FIG. 15A, and FIG. 16B is a side view of a structure of a pixel including a cross section taken along line E-F in FIG. 15A.

A display panel shown in FIGS. 16A and 16B is a modification example of the display panel shown in FIGS. 15A to 15C and has a pixel structure different from that in the display panel shown in FIGS. 15A to 15C. Specifically, the display panel shown in FIGS. 16A and 16B is different from the display panel shown in FIGS. 15A to 15C in that the color filter is not provided and in that sub-pixels of different emission colors include layers containing different light-emitting organic compounds. A modification example of a structure of the pixel 402 included in the display portion 401 is described with reference to FIG. 16B.

The pixel 402 described as the modification example in this embodiment includes the sub-pixel 402B emitting blue light B, the sub-pixel 402G emitting green light G and the sub-pixel 402R emitting red light R. Each sub-pixel includes a driver transistor and a light-emitting module. Each light-emitting module includes a reflective film, a semi-transmissive and semi-reflective film, and a light-emitting element between the reflective film and the semi-transmissive and semi-reflective film.

The sub-pixel 402B includes the first electrode 421B also serving as the reflective film, the second electrode 422 also serving as the semi-transmissive and semi-reflective film, and a layer 423B containing a light-emitting organic compound that emits light including blue light. Further, the optical path length in the micro resonator is adjusted such that blue light with a spectral line half-width of less than or equal to 60 nm is emitted.

The sub-pixel 402G includes the first electrode 421G also serving as the reflective film, the second electrode 422 also serving as the semi-transmissive and semi-reflective film, and a layer 423G containing a light-emitting organic compound that emits light including green light. Further, the optical path length in the micro resonator is adjusted such that green light with a spectral line half-width of less than or equal to 60 nm is emitted.

The sub-pixel 402R includes the first electrode 421R also serving as the reflective film, the second electrode 422 also serving as the semi-transmissive and semi-reflective film, and a layer 423R containing a light-emitting organic compound that emits light including red light. Further, the optical path length in the micro resonator is adjusted such that red light with a spectral line half-width of less than or equal to 60 nm is emitted.

Note that materials described in Embodiment 10 can be used for the layers containing the respective light-emitting organic compounds.

Note that this embodiment can be combined with any of the other embodiments and example in this specification as appropriate.

### Embodiment 13

In this embodiment, examples of a structure of a display panel which can be manufactured using a film formation apparatus of one embodiment of the present invention will be described.

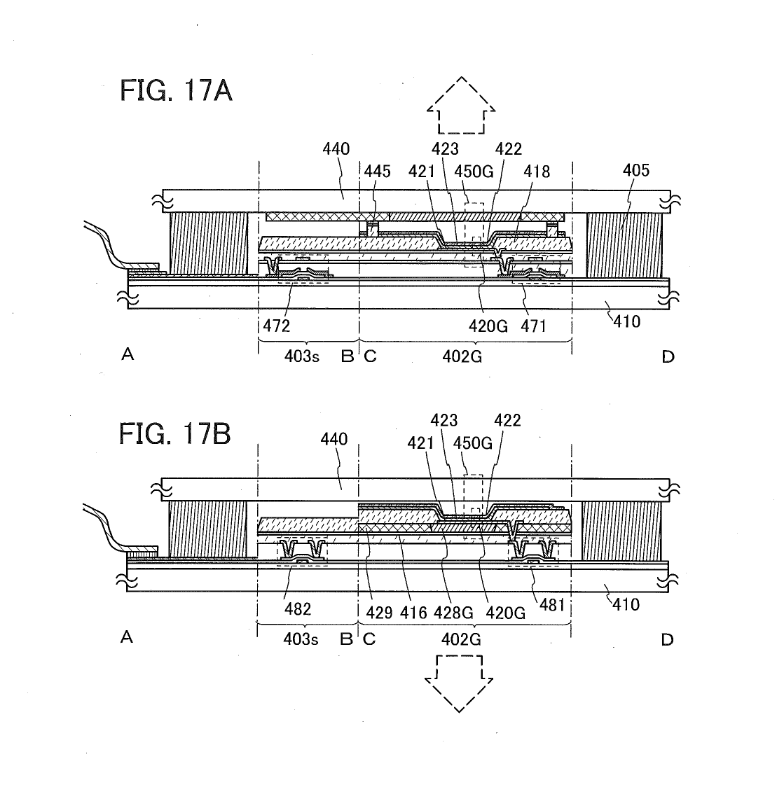

FIG. 17A is a side view of a structure including a cross section taken along line A-B and C-D in FIG. 15A, and FIG. 17B is a side view of a structure including a cross section taken along line A-B and C-D in FIG. 15A.

Although a structure of a top surface of a display panel exemplified in FIG. 17A or FIG. 17B is the same as that of the display panel exemplified in Embodiment 12, a structure of a side surface of the display panel exemplified in FIG. 17A or FIG. 17B is different from that of the display panel exemplified in Embodiment 12. Note that portions having the same structure as those described in Embodiment 12 are denoted by the same reference numerals, and the description of Embodiment 12 is applied thereto.

### Structure Example 1 of Display Panel

In the display panel exemplified in FIG. 17A, a display portion including the sub-pixel 402G and the source side driver circuit portion 403s are provided over the first substrate 410. A transistor 471 is provided in the sub-pixel 402G, and a transistor 472 is provided in the source side driver circuit portion 403s. Both of the transistors 471 and 472 are bottom-gate transistors.

A second gate electrode (also referred to as a back gate) may be provided to overlap with a semiconductor of a region in the transistor where a channel is formed. The characteristics (e.g., threshold voltage) of the transistor provided with the second gate electrode can be controlled by a potential to be applied to the second gate electrode.

A pair of spacers 445 is provided over the partition 418, thereby controlling a space between the first substrate 410 and the second substrate 440. Thus, it is possible to prevent a problem of disfigurement in which patterns (also called Newton's rings) derived from optical interference between the first substrate 410 and the second substrate 440 are observed. Further, it is possible to prevent optical crosstalk by providing the pair of spacers 445 such that light leakage from the adjacent sub-pixel is prevented.

An example of a semiconductor which is preferably used for the region in the transistor where a channel is formed which is exemplified in this embodiment is described below.

An oxide semiconductor has a high energy gap of 3.0 eV or more. A transistor including an oxide semiconductor layer obtained by processing of an oxide semiconductor in an appropriate condition and a sufficient reduction in carrier density of the oxide semiconductor can have much lower leakage current between a source and a drain in an off state (off-state current) than a conventional transistor including silicon.

An oxide semiconductor containing at least indium (In) or zinc (Zn) is preferably used. In particular, In and Zn are preferably contained. As a stabilizer for reducing variation in electric characteristics of a transistor including the oxide semiconductor, gallium (Ga) is preferably additionally contained. Tin (Sn) is preferably contained as a stabilizer. In addition, as a stabilizer, one or more selected from hafnium (Hf), zirconium (Zr), titanium (Ti), scandium (Sc), yttrium (Y), and a lanthanoid element (such as cerium (Ce), neodymium (Nd), or gadolinium (Gd), for example) is preferably contained.

As the oxide semiconductor, for example, any of the following can be used: indium oxide; tin oxide; zinc oxide; a two-component metal oxide such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide; a three-component metal oxide such as an In—Ga—Zn-based oxide (also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—Zr—Zn-based oxide, an In—Ti—Zn-based oxide, an In—Sc—Zn-based oxide, an In—Y—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide; and a four-component metal oxide such as an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide.

Here, an “In—Ga—Zn-based oxide” means an oxide containing In, Ga, and Zn as its main components and there is no particular limitation on the ratio of In:Ga:Zn. The In—Ga—Zn-based oxide may contain a metal element other than the In, Ga, and Zn.

A material represented by InMO₃(ZnO)ₘ (m>0, m is not an integer) may be used as the oxide semiconductor. Note that M represents one or more metal elements selected from Ga, Fe, Mn, and Co, or the above-described element as a stabilizer. Alternatively, a material represented by In₂SnO₅(ZnO)ₙ (n>0, n is an integer) may be used as the oxide semiconductor.

For example, an In—Ga—Zn-based oxide with an atomic ratio of In:Ga:Zn=1:1:1, In:Ga:Zn=3:1:2, or In:Ga:Zn=2:1:3, or any of oxides whose composition is in the neighborhood of the above compositions is preferably used.

A structure of an oxide semiconductor film is described below.

An oxide semiconductor film is classified roughly into a single-crystal oxide semiconductor film and a non-single-crystal oxide semiconductor film. The non-single-crystal oxide semiconductor film includes any of an amorphous oxide semiconductor film, a microcrystalline oxide semiconductor film, a polycrystalline oxide semiconductor film, a c-axis aligned crystalline oxide semiconductor (CAAC-OS) film, and the like.

The amorphous oxide semiconductor film has disordered atomic arrangement and no crystalline component. A typical example thereof is an oxide semiconductor film in which no crystal part exists even in a microscopic region, and the whole of the film is amorphous.

The microcrystalline oxide semiconductor film includes a microcrystal (also referred to as nanocrystal) with a size greater than or equal to 1 nm and less than 10 nm, for example. Thus, the microcrystalline oxide semiconductor film has a higher degree of atomic order than the amorphous oxide semiconductor film. Hence, the density of defect states of the microcrystalline oxide semiconductor film is lower than that of the amorphous oxide semiconductor film.

The CAAC-OS film is one of oxide semiconductor films including a plurality of crystal parts, and most of the crystal parts each fit inside a cube whose one side is less than 100 nm. Thus, there is a case where a crystal part included in the CAAC-OS film fits inside a cube whose one side is less than 10 nm, less than 5 nm, or less than 3 nm. The density of defect states of the CAAC-OS film is lower than that of the microcrystalline oxide semiconductor film. The CAAC-OS film is described in detail below.

In a transmission electron microscope (TEM) image of the CAAC-OS film, a boundary between crystal parts, that is, a grain boundary is not clearly observed. Thus, in the CAAC-OS film, a reduction in electron mobility due to the grain boundary is less likely to occur.

According to the TEM image of the CAAC-OS film observed in a direction substantially parallel to a sample surface (cross-sectional TEM image), metal atoms are arranged in a layered manner in the crystal parts. Each metal atom layer has a morphology reflected by a surface over which the CAAC-OS film is formed (hereinafter, a surface over which the CAAC-OS film is formed is referred to as a formation surface) or a top surface of the CAAC-OS film, and is arranged in parallel to the formation surface or the top surface of the CAAC-OS film.

On the other hand, according to the TEM image of the CAAC-OS film observed in a direction substantially perpendicular to the sample surface (plan TEM image), metal atoms are arranged in a triangular or hexagonal configuration in the crystal parts. However, there is no regularity of arrangement of metal atoms between different crystal parts.

From the results of the cross-sectional TEM image and the plan TEM image, alignment is found in the crystal parts in the CAAC-OS film.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears frequently when 29 is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal oxide semiconductor film of InGaZnO₄, six peaks appear. The six peaks are derived from crystal planes equivalent to the (110) plane. On the other hand, in the case of a CAAC-OS film, a peak is not clearly observed even when 0 scan is performed with 2θ fixed at around 56°.

According to the above results, in the CAAC-OS film having c-axis alignment, while the directions of a-axes and b-axes are different between crystal parts, the c-axes are aligned in a direction parallel to a normal vector of a formation surface or a normal vector of a top surface. Thus, each metal atom layer arranged in a layered manner observed in the cross-sectional TEM image corresponds to a plane parallel to the a-b plane of the crystal.

Note that the crystal part is formed concurrently with deposition of the CAAC-OS film or is formed through crystallization treatment such as heat treatment. As described above, the c-axis of the crystal is aligned in a direction parallel to a normal vector of a formation surface or a normal vector of a top surface. Thus, for example, in the case where a shape of the CAAC-OS film is changed by etching or the like, the c-axis might not be necessarily parallel to a normal vector of a formation surface or a normal vector of a top surface of the CAAC-OS film.

Further, the degree of crystallinity in the CAAC-OS film is not necessarily uniform. For example, in the case where crystal growth leading to the CAAC-OS film occurs from the vicinity of the top surface of the film, the degree of the crystallinity in the vicinity of the top surface is higher than that in the vicinity of the formation surface in some cases. Further, when an impurity is added to the CAAC-OS film, the crystallinity in a region to which the impurity is added is changed, and the degree of crystallinity in the CAAC-OS film varies depending on regions.

Note that when the CAAC-OS film with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC-OS film. It is preferable that in the CAAC-OS film, a peak of 2θ appear at around 31° and a peak of 2θ do not appear at around 36°.

In a transistor using the CAAC-OS film, change in electric characteristics due to irradiation with visible light or ultraviolet light is small. Thus, the transistor has high reliability.

Note that an oxide semiconductor film may be a stacked film including two or more films of an amorphous oxide semiconductor film, a microcrystalline oxide semiconductor film, and a CAAC-OS film, for example.

In this specification, a term “parallel” indicates that the angle formed between two straight lines is greater than or equal to −10° and less than or equal to 10°, and accordingly also includes the case where the angle is greater than or equal to −5° and less than or equal to 5°. In addition, a term “perpendicular” indicates that the angle formed between two straight lines is greater than or equal to 80° and less than or equal to 100°, and accordingly includes the case where the angle is greater than or equal to 85° and less than or equal to 95°.

In this specification, the trigonal and rhombohedral crystal systems are included in the hexagonal crystal system.

The above is the description of the oxide semiconductor film.

After formation of the oxide semiconductor film, it is preferable that dehydration treatment (dehydrogenation treatment) be performed to remove hydrogen or moisture from the oxide semiconductor film so that the oxide semiconductor film is highly purified to contain impurities as little as possible, and that oxygen be added to the oxide semiconductor film to fill oxygen vacancies increased by the dehydration treatment (dehydrogenation treatment). In this specification and the like, supplying oxygen to an oxide semiconductor film may be expressed as oxygen adding treatment, and treatment for making the oxygen content of an oxide semiconductor film be in excess of that in the stoichiometric composition may be expressed as treatment for making an oxygen-excess state.

In this manner, hydrogen or moisture is removed from the oxide semiconductor film by dehydration treatment (dehydrogenation treatment) and oxygen vacancies therein are filled by oxygen adding treatment, whereby the oxide semiconductor film can be turned into an i-type (intrinsic) or substantially i-type oxide semiconductor film. The oxide semiconductor film formed in such a manner includes extremely few (close to zero) carriers derived from a donor, and the carrier concentration thereof is lower than 1×10¹⁴/cm³, preferably lower than 1×10¹²/cm³, further preferably lower than 1×10¹¹/cm³, still further preferably lower than 1.45×10¹⁰/cm³.

The transistor including the oxide semiconductor layer which is highly purified by sufficiently reducing the hydrogen concentration, and in which defect levels in the energy gap due to oxygen vacancies are reduced by sufficiently supplying oxygen can achieve excellent off-state current characteristics. For example, the off-state current (per unit channel width (1 μm) here) at room temperature (25° C.) is 100 zA (1 zA (zeptoampere) is 1×10⁻²¹ A) or less, preferably 10 zA or less. The off-state current at 85° C. is 100 zA (1×10⁻¹⁹ A) or less, preferably 10 zA (1×10⁻²⁰ A) or less. In this manner, the transistor which has extremely favorable off-state current characteristics can be obtained with the use of an i-type (intrinsic) or substantially i-type oxide semiconductor layer.

### Structure Example 2 of Display Panel

In the display panel exemplified in FIG. 17B, a bottom-gate transistor is used. A light-emitting module provided for a pixel in the display portion has such a structure as to emit light to the first substrate 410 side.

Specifically, the first electrode 421G of the light-emitting element 420G in the light-emitting module 450G also serves as a semi-transmissive and semi-reflective film, and the second electrode 422 also serves as a reflective film. Thus, light emitted from the light-emitting element 420G is extracted from the first substrate 410 through a color filter 428G provided between the first electrode 421G and the first substrate 410. In other words, the light-emitting element 420G in the light-emitting module 450G can be referred to as a bottom-emission light-emitting element.

The color filter 428G is formed over the first substrate 410 over which a transistor 481 is provided. A light-blocking film 429 is formed to surround the color filter 428G.

Note that this embodiment can be combined with any of the other embodiments and example in this specification as appropriate.

### Example

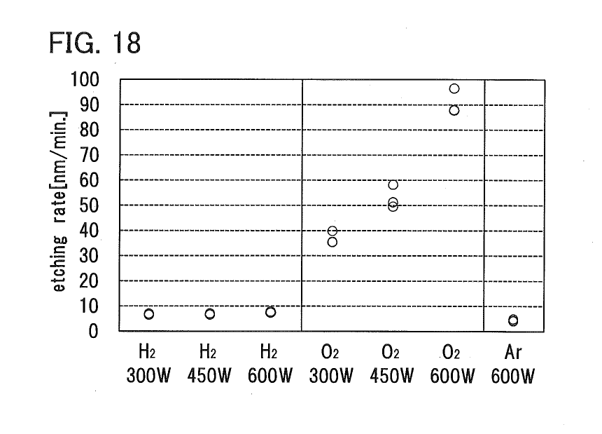

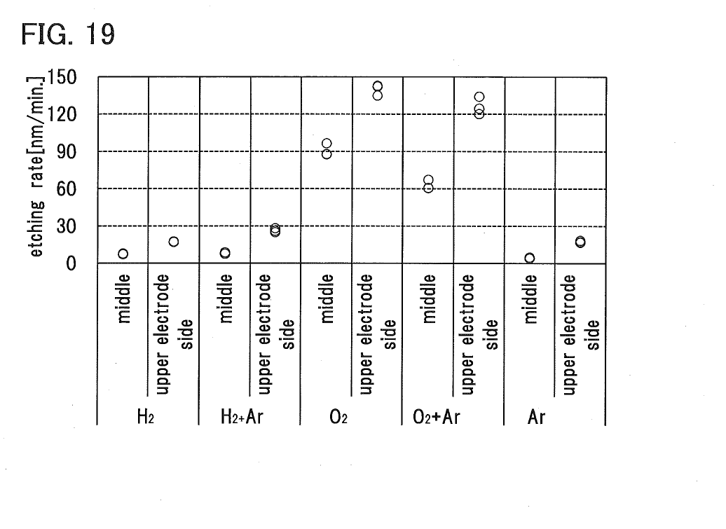

Results of removal of a film formation material with use of a removal chamber which is applicable to a film formation apparatus of one embodiment of the present invention will be described below with reference to FIG. 18 and FIG. 19.

### <Structure of Removal Chamber>

In this example, a removal chamber provided with a parallel plate plasma source including an upper electrode and a lower electrode was used. A high-frequency power source with a frequency of 13.56 MHz was connected to the upper electrode via a matching box. The lower electrode, which also serves as a shower plate for gas introduction, was grounded. A shadow mask stage was placed between the upper electrode and the lower electrode.

The distance between the upper electrode and the lower electrode was set to 50 mm. The distance from the upper electrode to a sample can be adjusted by changing the height of the shadow mask stage. In this example, the distance from the upper electrode to the sample was set to 30 mm or 0 mm. The shadow mask stage was formed using alumina.

### <Sample and Measurement>

As a sample for measurement of removal speed, a silicon substrate on which 9-[4-(10-phenyl-9-anthracenyl)phenyl]-9H-carbazole (abbreviation: CzPA) was evaporated to a thickness of 140 nm and which was fixed to an aluminum plate was used. Note that CzPA is a film formation material which can be used for a light-emitting element.

The thickness of CzPA before and after irradiation with plasma was measured with an ellipsometer (PZ2000 manufactured by Royal Philips Electronics). The difference in thickness was divided by the time for irradiation with plasma, whereby the removal speed was calculated. Note that three points on diagonal lines of a 5-inch square were subjected to measurement.

### <Result 1>

FIG. 18 shows the dependence of the removal speed (also referred to as etching rate) on the kind of gas used for processing and on the output of the high-frequency power source. As conditions for the removal, the gas flow rate was set to 200 sccm, the pressure was set to 5 Pa, and the distance from the upper electrode to the sample was set to 30 mm.

In the case where hydrogen was used, the medians of the removal speeds were 6.6 nm/min, 6.9 nm/min, and 7.4 nm/min when the outputs of the high-frequency power source were 300 W, 450 W, and 600 W, respectively.

In the case where oxygen was used, the medians of the removal speeds were 35.6 nm/min, 51.3 nm/min, and 88.0 nm/min when the outputs of the high-frequency power source were 300 W, 450 W, and 600 W, respectively.

In the case where argon was used, the median of the removal speed was 4.4 nm/min when the output of the high-frequency power source was 600 W.

Oxygen was superior to the other gases in removal speed.

### <Result 2>

FIG. 19 shows the dependence of the removal speed on the kind of gas used for processing and on the distance from the upper electrode to the sample. The distance from the upper electrode to the sample was set to 30 mm or 0 mm. As conditions for the removal, the gas flow rate was set to 200 sccm (in the case where two kinds of gases were mixed, the flow rate of each gas was set to 100 sccm), the pressure was set to 5 Pa, and the output of the high-frequency power source was set to 600 W.

In the case where hydrogen was used, the medians of the removal speeds were 7.4 nm/min and 17.3 nm/min when the distances from the upper electrode to the sample were 30 mm and 0 mm, respectively.

In the case where a mixed gas of hydrogen and argon was used, the medians of the removal speeds were 7.8 nm/min and 26.2 nm/min when the distances from the upper electrode to the sample were 30 mm and 0 mm, respectively.

In the case where oxygen was used, the medians of the removal speeds were 88.0 nm/min and 142.4 nm/min when the distances from the upper electrode to the sample were 30 mm and 0 mm, respectively.

In the case where a mixed gas of oxygen and argon was used, the medians of the removal speeds were 60.7 nm/min and 124.7 nm/min when the distances from the upper electrode to the sample were 30 mm and 0 mm, respectively.

In the case where argon was used, the medians of the removal speeds were 4.4 nm/min and 17.5 nm/min when the distances from the upper electrode to the sample were 30 mm and 0 mm, respectively.

The mixed gas of hydrogen and argon was superior to hydrogen in removal speed.

In the case where hydrogen was used, the case where the distance from the upper electrode to the sample was set to 0 mm was superior in removal speed to the case where the distance from the upper electrode to the sample was set to 30 mm. This result indicates that when the shadow mask is placed in a region where ions are greatly accelerated by self-bias voltage, the film formation material attached to the shadow mask can be removed at higher speed.

This application is based on Japanese Patent Application serial no. 2012-108221 filed with Japan Patent Office on May 10, 2012 and Japanese Patent Application serial no. 2012-124594 filed with Japan Patent Office on May 31, 2012, the entire contents of which are hereby incorporated by reference.

1-13. (canceled)

14. A method for forming a film with use of a film formation apparatus, the film formation apparatus comprising:
a removal chamber;
a film formation chamber;
an evaporation source in the film formation chamber;
a plasma source in the removal chamber;
a shadow mask stage between an upper electrode and a lower electrode of the plasma source; and
a shadow mask transfer mechanism configured to transfer an object and a shadow mask covering part of the object through a region where the evaporation source is configured to eject a film formation material, the object and the shadow mask being overlapped with each other,
the method comprising the steps of:
a first step of overlapping an object with an opening of a shadow mask;
a second step of transferring the shadow mask whose opening is overlapped with the object and depositing a film formation material ejected by the evaporation source on the object;
a third step of carrying out the shadow mask to the removal chamber and irradiating the shadow mask with plasma from the plasma source, the shadow mask being held on the upper electrode side by the shadow mask stage; and
a fourth step of carrying in the shadow mask to the film formation chamber;
overlapping an object with an opening of a shadow mask;
transferring the shadow mask whose opening is overlapped with the object so that a film formation material ejected by the evaporation source is deposited on the object;
carrying out the shadow mask to the removal chamber;
irradiating the shadow mask with plasma from the plasma source in the removal chamber, the shadow mask being held on the upper electrode side by the shadow mask stage, and
carrying in the shadow mask to the film formation chamber.

15. The method for forming a film with use of a film formation apparatus according to claim 14,
wherein a distance in which the shadow mask is transferred through the removal chamber is shorter than a distance in which the shadow mask is transferred through the film formation chamber.

16. The method for forming a film with use of a film formation apparatus according to claim 14, further comprising:
a step of evacuating the removal chamber and adjusting a pressure inside the removal chamber at a time of generating plasma.

17. The method for forming a film with use of a film formation apparatus according to claim 14, the film formation apparatus comprising a first sluice valve and a second sluice valve,
wherein the first sluice valve and the second sluice valve are connected to the removal chamber and provided apart from each other,
wherein the shadow mask is carried out to the removal chamber through the first sluice valve, and
wherein the shadow mask is carried in to the film formation chamber through the second sluice valve.

18. The method for forming a film with use of a film formation apparatus according to claim 14,
wherein a gas used for plasma is selected from any one of argon, xenon, helium, hydrogen, oxygen, and carbon tetrafluoride.

19. The method for forming a film with use of a film formation apparatus according to claim 14, the film formation apparatus comprising an exhaust mechanism and a gas introduction mechanism,
the method further comprising:
a step of controlling a pressure inside the removal chamber by the exhaust mechanism, and
a step of adjusting an atmosphere inside the removal chamber by the gas introduction mechanism.

20. The method for forming a film with use of a film formation apparatus according to claim 14,
wherein the evaporation source is a linear evaporation source, and
wherein the film formation material ejected by the linear evaporation source is deposited on the object linearly.
